(19) United States
(12) Patent Application Publication
(10) Pub. No.: US 2008/0073703 A1
(43) Pub. Date: Mar. 27, 2008

(54) Nonvolatile semiconductor memory device and method for fabricating the same

(76) Inventor: Kiyoshi Kurihara, Tokyo (JP)

Correspondence Address: MCDERMOTT WILL & EMERY LLP, 600 13TH STREET, NW, WASHINGTON, DC, 20005-3096, US

(21) Appl. No.: 11/822,070

(22) Filed: Jul. 2, 2007

(30) Foreign Application Priority Data
Sep. 26, 2006 (JP) 2006-260466

(51) Int. Cl. H01L 29/792; H01L 21/336

(52) U.S. Cl. 257/324; 438/287; 257/E29.309; 257/E21.423

(57) ABSTRACT

A nonvolatile semiconductor memory device includes: diffusion-layer bit lines extending in the column direction in a substrate; an insulating film on the bit line formed on each of the diffusion-layer bit lines and extending in the column direction; a charge trapping layer formed on a region of the substrate positioned between the diffusion-layer bit lines as seen from a horizontal plane; a first gate electrode film formed on the charge trapping layer; and a second gate electrode film formed on the first gate electrode film and the insulating film on the bit line and extending in the row direction. The insulating film on the bit line is formed in a tapered shape, and in this film, the thickness of a buried oxide film provided at the center portion in the row direction is greater than the thickness of an implantation offset film provided at both ends.

### BACKGROUND OF THE INVENTION

(a) Fields of the Invention

The present invention relates to nonvolatile semiconductor memory devices such as MONOS (Metal Oxide Nitride Oxide Semiconductor) type devices having, for example, buried bit line structures, and to methods for fabricating such devices.

(b) Description of Related Art

One of conventionally-known nonvolatile semiconductor memory devices is a nonvolatile semiconductor memory device in which an impurity diffusion layer formed in a surface layer of a semiconductor substrate is used as a bit line (a buried bit line) and a word line is formed over the semiconductor substrate to intersect with the bit line with a gate insulating film interposed therebetween. In this device, the gate insulating film stores data by trapping charges.

In recent years, nonvolatile semiconductor memory devices have been required to attain size reduction, miniaturization, speed enhancement, and reliability improvement. With such requirement, a nonvolatile semiconductor memory device is employed which is provided with an oxide film on a bit line functioning as an insulating film for separating the bit line from a word line. Hereinafter, a conventional method for fabricating a nonvolatile semiconductor memory device with a buried bit line structure will be described with reference to the accompanying drawings. Note that the following figures accompanied with the reference character “A” are top views showing the conventional method for fabricating a nonvolatile semiconductor memory device, and the following figures accompanied with the reference character “B” or “C” are sectional views showing the conventional method for fabricating a nonvolatile semiconductor memory device.

FIGS. 75 to 80 are views showing the conventional method for fabricating a nonvolatile semiconductor memory device. Referring to FIGS. 75A to 75C, first, an ONO stacked film 14 composed of a first silicon oxide film 11, a silicon nitride film 12, and a second silicon oxide film 13 is formed on a semiconductor substrate 10. On the ONO stacked film 14, a first gate electrode film 15 and a first mask 16 provided with a groove extending in the column direction are sequentially formed.

Next, as shown in FIGS. 76A to 76C, using the first mask 16, the first gate electrode film 15 and the ONO stacked film 14 are etched to expose the semiconductor substrate 10, thereby forming an opening extending in the column direction. After ion implantation from the opening into the surface layer of the semiconductor substrate 10, the first mask 16 is removed. Subsequently, the whole of the semiconductor substrate 10 is annealed to activate the implanted impurities, thereby forming a buried bit line 17.

As shown in FIGS. 77A to 77C, the entire surface of the semiconductor substrate 10 is formed with a buried film 18 to fill the opening with the buried film 18.

Then, as shown in FIGS. 78A to 78C, the buried film 18 is removed to expose the first gate electrode film 15, thereby forming an oxide film 19 on the bit line.

As shown in FIGS. 79A to 79C, a second gate electrode film 20 is formed on the first gate electrode film 15 and the oxide film 19 on the bit line, and a second mask 21 provided with a groove extending in the row direction is formed on the second gate electrode film 20.

Finally, as shown in FIGS. 80A to 80C, using the second mask 21, portions of the first and second gate electrode films 15 and 20 are selectively etched to form a word line 22. The word line 22 is composed of the first gate electrode film 15 and the second gate electrode film 20 and extends in the row direction to three-dimensionally intersect with the buried bit line 17.

Thereafter, a metal interconnect formation process, a protective film formation process, and a bonding pad formation process are carried out using a well-known technique. However, description of these processes is omitted herein. By carrying out the processes shown above, the conventional nonvolatile semiconductor memory device can be fabricated.

### SUMMARY OF THE INVENTION

The conventional method for fabricating a nonvolatile semiconductor memory device described above, however, has the possibility of causing a problem as shown in FIG. 80D. FIG. 80D is an enlarged view of a side wall portion 23 of the oxide film 19 on the bit line shown in FIG. 80C. As shown in this figure, a sidewall-shaped residue 24 of the first gate electrode film 15 appears on the side wall portion 23 of the oxide film 19 on the bit line. This appearance is caused because the conventional nonvolatile semiconductor memory device has a shoulder shape resulting from the thickness difference between the oxide film 19 on the bit line and the ONO stacked film 14 and in addition the top end of the oxide film 19 on the bit line having the vertical shape makes it difficult to fully etch away the first gate electrode film 15 in the step shown in FIG. 80C. When this residue 24 of the first gate electrode film 15 appears, a potential problem of causing leakage between the adjacent word lines 22 will arise.

The present invention has been made in view of the problem described above, and its object is to provide a nonvolatile semiconductor memory device which can prevent appearance of a residue of a gate electrode film to suppress leakage caused between word lines, and to provide a fabrication method of such a device.

To attain the above object, a nonvolatile semiconductor memory device according to the present invention includes: a substrate; a plurality of diffusion-layer bit lines extending in the column direction in the substrate; a charge trapping layer formed on a region of the substrate positioned between the plurality of diffusion-layer bit lines as seen from a horizontal plane; an insulating film on the bit line formed on each of the plurality of diffusion-layer bit lines, penetrating the charge trapping layer, and having a smaller thickness at both ends in the row direction than at a center portion; and a gate electrode extending in the row direction over the charge trapping layer and the insulating film on the bit line and three-dimensionally intersecting with the plurality of diffusion-layer bit lines. For example, the insulating film on the bit line preferably has a tapered shape.

With this structure, the insulating film on the bit line formed in a tapered shape is provided to have a smaller thickness at the both ends in the row direction than at the center portion. This reduces the level difference between the top surface of the charge trapping layer and the both ends of the insulating film on the bit line. Therefore, a gate electrode formation film used in forming the gate electrode can be etched away relatively easily, so that a residue of the gate electrode formation film can be prevented from appearing after the etching. As a result of this, the nonvolatile semiconductor memory device according to the present invention can be designed to suppress leakage between the word lines.

Note that the insulating film on the bit line may be composed of: a first insulating film formed at the center portion thereof in the row direction; and an implantation offset film formed at both ends thereof in the row direction.

Alternatively, the insulating film on the bit line may be made of a single-layer insulating film.

A first method for fabricating a nonvolatile semiconductor memory device according to the present invention includes: the step (a) of sequentially forming, on a substrate, a charge trapping layer having an insulating property, a first gate electrode formation film made of a conductor, a buffer layer having an insulating property, and a bit line formation film having an insulating property; the step (b) of selectively etching away, using a first mask, the charge trapping layer, the first gate electrode formation film, the buffer layer, and the bit line formation film, thereby forming openings extending in the column direction and reaching the substrate; the step (c) of introducing, after removal of the first mask, an impurity from the openings to form in the substrate a plurality of diffusion-layer bit lines extending in the column direction; the step (d) of filling each of the openings with a first insulating film to form an insulating film on the bit line; the step (e) of etching away, after removal of the bit line formation film, the buffer layer and the insulating film on the bit line to expose the first gate electrode formation film, thereby making the thickness of the insulating film on the bit line smaller at both ends in the row direction than at the center portion; the step (f) of forming a second gate electrode formation film on the first gate electrode formation film and the insulating film on the bit line; and the step (g) of selectively etching away portions of the second and first gate electrode formation films using a second mask, thereby forming a gate electrode composed of the first and second gate electrode formation films and extending in the row direction.

With this method, in the step (e), the insulating film on the bit line is formed to have a smaller thickness at the both ends in the row direction than at the center portion. Thereby, the level difference can be reduced between the insulating film on the bit line and the top surface of the charge trapping layer. Therefore, in the step (g), the gate electrode formation film can be etched away relatively easily, so that appearance of a residue of the gate electrode formation film can be prevented. Accordingly, with the first method for fabricating a nonvolatile semiconductor memory device according to the present invention, the nonvolatile semiconductor memory device can be fabricated which is designed to suppress leakage between the word lines.

Next, a second method for fabricating a nonvolatile semiconductor memory device according to the present invention includes: the step (a) of sequentially forming, on a substrate, a charge trapping layer, a sacrifice silicon nitride film, a sacrifice silicon oxide film, and a bit line formation film; the step (b) of selectively etching away, using a first mask, the charge trapping layer, the sacrifice silicon nitride film, the sacrifice silicon oxide film, and the bit line formation film, thereby forming openings extending in the column direction and reaching the substrate; the step (c) of introducing, after removal of the first mask, an impurity from the openings to form in the substrate a plurality of diffusion-layer bit lines extending in the column direction; the step (d) of filling each of the openings with a first insulating film to form an insulating film on the bit line; the step (e) of etching away, after removal of the bit line formation film, the sacrifice silicon oxide film and the insulating film on the bit line to expose the sacrifice silicon nitride film, thereby making the thickness of the insulating film on the bit line smaller at both ends in the row direction than at the center portion; the step (f) of forming, after removal of the sacrifice silicon nitride film, a gate electrode formation film on the charge trapping layer and the insulating film on the bit line; and the step (g) of selectively etching away the gate electrode formation film using a second mask to form, on the charge trapping layer and the insulating film on the bit line, a gate electrode extending in the row direction.

With this method, in the step (g), the gate electrode functioning as the word line is made of a single gate-electrode-formation film. For the nonvolatile semiconductor memory device, if the word line is made of multiple gate-electrode-formation films, the interface between the gate electrode films may be naturally oxidized to increase the resistance of the resulting word line. However, with the second fabrication method of the present invention, the gate electrode is made of a single film, so that the word line with a relatively low resistance can be formed. Furthermore, as in the case of the first fabrication method of the present invention, the nonvolatile semiconductor memory device can be fabricated which can be designed to suppress leakage between the word lines.

A third method for fabricating a nonvolatile semiconductor memory device according to the present invention includes: the step (a) of sequentially forming a charge trapping layer and a bit line formation film on a substrate, the charge trapping layer being made by sequentially stacking, from bottom to top, a first silicon oxide film, a silicon nitride film, and a sacrifice silicon oxide film; the step (b) of selectively etching away, using a first mask, the charge trapping layer and the bit line formation film to form openings extending in the column direction and reaching the substrate; the step (c) of introducing, after removal of the first mask, an impurity from the openings to form in the substrate a plurality of diffusion-layer bit lines extending in the column direction; the step (d) of filling each of the openings with a first insulating film to form an insulating film on the bit line; the step (e) of etching away, after removal of the bit line formation film, the sacrifice silicon oxide film and the insulating film on the bit line to expose the silicon nitride film, thereby making the thickness of the insulating film on the bit line smaller at both ends in the row direction than at the center portion; the step (f) of forming a second silicon oxide film extending over the top of the silicon nitride film and the top of each said insulating film on the bit line; the step (g) of forming a gate electrode formation film on the second silicon oxide film; and the step (h) of selectively etching the gate electrode formation film using a second mask to form, on the second silicon oxide film, a gate electrode extending in the row direction.

With this method, in the step (e), the insulating film on the bit line is formed to have a smaller thickness at the both ends than at the center portion. Thereby, in the step (f), the second silicon oxide film is also formed to have a similar contour to the insulating film on the bit line, so that the formed second silicon oxide film has a relatively small level difference. Therefore, as in the case of the first fabrication method of the present invention, in the step (h), the gate electrode formation film can be etched away relatively easily to prevent appearance of a residue of the gate electrode formation film. Accordingly, with the third fabrication method of the present invention, the nonvolatile semiconductor memory device can be fabricated which is designed to suppress leakage between the word lines.

### BRIEF DESCRIPTION OF THE DRAWINGS

FIGS. 1A to 1C are views showing the structure of a nonvolatile semiconductor memory device according to a first embodiment of the present invention.

FIGS. 2A to 2C are views showing a first method for fabricating a nonvolatile semiconductor memory device according to the first embodiment of the present invention.

FIGS. 3A to 3C are views showing the first method for fabricating a nonvolatile semiconductor memory device according to the first embodiment.

FIGS. 4A to 4C are views showing the first method for fabricating a nonvolatile semiconductor memory device according to the first embodiment.

FIGS. 5A to 5C are views showing the first method for fabricating a nonvolatile semiconductor memory device according to the first embodiment.

FIGS. 6A to 6C are views showing the first method for fabricating a nonvolatile semiconductor memory device according to the first embodiment.

FIGS. 7A to 7C are views showing the first method for fabricating a nonvolatile semiconductor memory device according to the first embodiment.

FIGS. 8A to 8C are views showing the first method for fabricating a nonvolatile semiconductor memory device according to the first embodiment.

FIGS. 9A to 9C are views showing the first method for fabricating a nonvolatile semiconductor memory device according to the first embodiment.

FIGS. 10A to 10C are views showing the first method for fabricating a nonvolatile semiconductor memory device according to the first embodiment.

FIGS. 11A to 11C are views showing the first method for fabricating a nonvolatile semiconductor memory device according to the first embodiment.

FIGS. 12A to 12C are views showing a second method for fabricating a nonvolatile semiconductor memory device according to the first embodiment of the present invention.

FIGS. 13A to 13C are views showing the second method for fabricating a nonvolatile semiconductor memory device according to the first embodiment.

FIGS. 14A to 14C are views showing the second method for fabricating a nonvolatile semiconductor memory device according to the first embodiment.

FIGS. 15A to 15C are views showing the second method for fabricating a nonvolatile semiconductor memory device according to the first embodiment.

FIGS. 16A to 16C are views showing the second method for fabricating a nonvolatile semiconductor memory device according to the first embodiment.

FIGS. 17A to 17C are views showing the second method for fabricating a nonvolatile semiconductor memory device according to the first embodiment.

FIGS. 18A to 18C are views showing the second method for fabricating a nonvolatile semiconductor memory device according to the first embodiment.

FIGS. 19A to 19C are views showing the second method for fabricating a nonvolatile semiconductor memory device according to the first embodiment.

FIGS. 20A to 20C are views showing the second method for fabricating a nonvolatile semiconductor memory device according to the first embodiment.

FIGS. 21A to 21C are views showing the structure of a nonvolatile semiconductor memory device according to a second embodiment of the present invention.

FIGS. 22A to 22C are views showing a method for fabricating a nonvolatile semiconductor memory device according to the second embodiment of the present invention.

FIGS. 23A to 23C are views showing the method for fabricating a nonvolatile semiconductor memory device according to the second embodiment.

FIGS. 24A to 24C are views showing the method for fabricating a nonvolatile semiconductor memory device according to the second embodiment.

FIGS. 25A to 25C are views showing the method for fabricating a nonvolatile semiconductor memory device according to the second embodiment.

FIGS. 26A to 26C are views showing the method for fabricating a nonvolatile semiconductor memory device according to the second embodiment.

FIGS. 27A to 27C are views showing the method for fabricating a nonvolatile semiconductor memory device according to the second embodiment.

FIGS. 28A to 28C are views showing the method for fabricating a nonvolatile semiconductor memory device according to the second embodiment.

FIGS. 29A to 29C are views showing the method for fabricating a nonvolatile semiconductor memory device according to the second embodiment.

FIGS. 30A to 30C are views showing the method for fabricating a nonvolatile semiconductor memory device according to the second embodiment.

FIGS. 31A to 31C are views showing the structure of a nonvolatile semiconductor memory device according to a third embodiment of the present invention.

FIGS. 32A to 32C are views showing a method for fabricating a nonvolatile semiconductor memory device according to the third embodiment of the present invention.

FIGS. 33A to 33C are views showing the method for fabricating a nonvolatile semiconductor memory device according to the third embodiment.

FIGS. 34A to 34C are views showing the method for fabricating a nonvolatile semiconductor memory device according to the third embodiment.

FIGS. 35A to 35C are views showing the method for fabricating a nonvolatile semiconductor memory device according to the third embodiment.

FIGS. 36A to 36C are views showing the method for fabricating a nonvolatile semiconductor memory device according to the third embodiment.

FIGS. 37A to 37C are views showing the method for fabricating a nonvolatile semiconductor memory device according to the third embodiment.

FIGS. 38A to 38C are views showing the method for fabricating a nonvolatile semiconductor memory device according to the third embodiment.

FIGS. 39A to 39C are views showing the method for fabricating a nonvolatile semiconductor memory device according to the third embodiment.

FIGS. 40A to 40C are views showing the method for fabricating a nonvolatile semiconductor memory device according to the third embodiment.

FIGS. 41A to 41C are views showing the method for fabricating a nonvolatile semiconductor memory device according to the third embodiment.

FIGS. 42A to 42C are views showing the structure of a nonvolatile semiconductor memory device according to a fourth embodiment of the present invention.

FIGS. 43A to 43C are views showing a first method for fabricating a nonvolatile semiconductor memory device according to the fourth embodiment of the present invention.

FIGS. 44A to 44C are views showing the first method for fabricating a nonvolatile semiconductor memory device according to the fourth embodiment.

FIGS. 45A to 45C are views showing the first method for fabricating a nonvolatile semiconductor memory device according to the fourth embodiment.

FIGS. 46A to 46C are views showing the first method for fabricating a nonvolatile semiconductor memory device according to the fourth embodiment.

FIGS. 47A to 47C are views showing the first method for fabricating a nonvolatile semiconductor memory device according to the fourth embodiment.

FIGS. 48A to 48C are views showing the first method for fabricating a nonvolatile semiconductor memory device according to the fourth embodiment.

FIGS. 49A to 49C are views showing the first method for fabricating a nonvolatile semiconductor memory device according to the fourth embodiment.

FIGS. 50A to 50C are views showing the first method for fabricating a nonvolatile semiconductor memory device according to the fourth embodiment.

FIGS. 51A to 51C are views showing the first method for fabricating a nonvolatile semiconductor memory device according to the fourth embodiment.

FIGS. 52A to 52C are views showing the first method for fabricating a nonvolatile semiconductor memory device according to the fourth embodiment.

FIGS. 53A to 53C are views showing the first method for fabricating a nonvolatile semiconductor memory device according to the fourth embodiment.

FIGS. 54A to 54C are views showing a second method for fabricating a nonvolatile semiconductor memory device according to the fourth embodiment of the present invention.

FIGS. 55A to 55C are views showing the second method for fabricating a nonvolatile semiconductor memory device according to the fourth embodiment.

FIGS. 56A to 56C are views showing the second method for fabricating a nonvolatile semiconductor memory device according to the fourth embodiment.

FIGS. 57A to 57C are views showing the second method for fabricating a nonvolatile semiconductor memory device according to the fourth embodiment.

FIGS. 58A to 58C are views showing the second method for fabricating a nonvolatile semiconductor memory device according to the fourth embodiment.

FIGS. 59A to 59C are views showing the second method for fabricating a nonvolatile semiconductor memory device according to the fourth embodiment.

FIGS. 60A to 60C are views showing the second method for fabricating a nonvolatile semiconductor memory device according to the fourth embodiment.

FIGS. 61A to 61C are views showing the second method for fabricating a nonvolatile semiconductor memory device according to the fourth embodiment.

FIGS. 62A to 62C are views showing the second method for fabricating a nonvolatile semiconductor memory device according to the fourth embodiment.

FIGS. 63A to 63C are views showing the second method for fabricating a nonvolatile semiconductor memory device according to the fourth embodiment.

FIGS. 64A to 64C are views showing the second method for fabricating a nonvolatile semiconductor memory device according to the fourth embodiment.

FIGS. 65A to 65C are views showing the structure of a nonvolatile semiconductor memory device according to a fifth embodiment of the present invention.

FIGS. 66A to 66C are views showing a method for fabricating a nonvolatile semiconductor memory device according to the fifth embodiment of the present invention.

FIGS. 67A to 67C are views showing the method for fabricating a nonvolatile semiconductor memory device according to the fifth embodiment.

FIGS. 68A to 68C are views showing the method for fabricating a nonvolatile semiconductor memory device according to the fifth embodiment.

FIGS. 69A to 69C are views showing the method for fabricating a nonvolatile semiconductor memory device according to the fifth embodiment.

FIGS. 70A to 70C are views showing the method for fabricating a nonvolatile semiconductor memory device according to the fifth embodiment.

FIGS. 71A to 71C are views showing the method for fabricating a nonvolatile semiconductor memory device according to the fifth embodiment.

FIGS. 72A to 72C are views showing the method for fabricating a nonvolatile semiconductor memory device according to the fifth embodiment.

FIGS. 73A to 73C are views showing the method for fabricating a nonvolatile semiconductor memory device according to the fifth embodiment.

FIGS. 74A to 74C are views showing the method for fabricating a nonvolatile semiconductor memory device according to the fifth embodiment.

FIGS. 75A to 75C are views showing a conventional method for fabricating a nonvolatile semiconductor memory device.

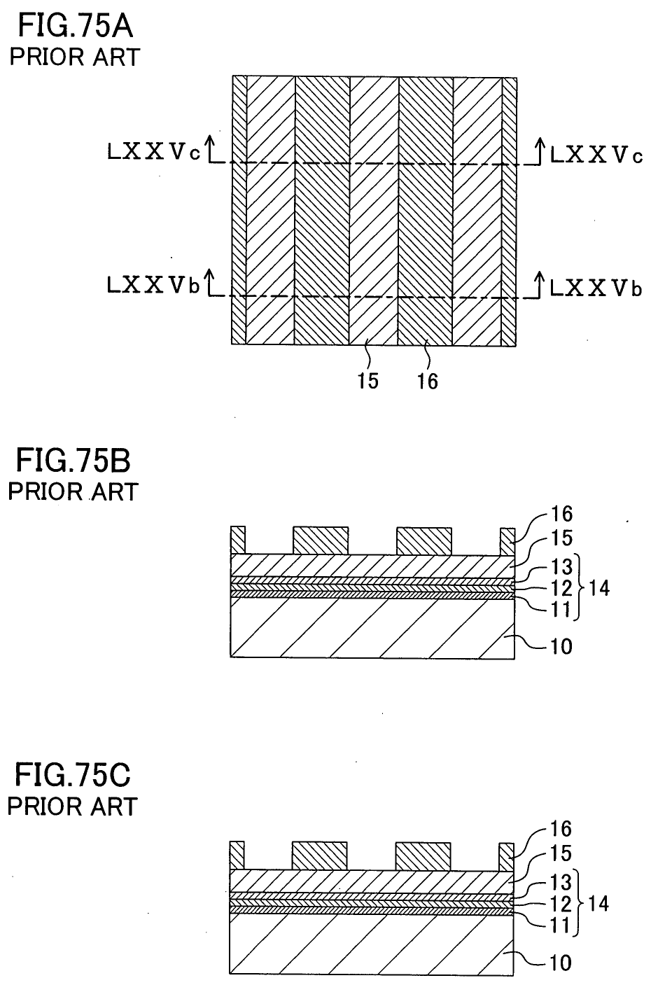

FIGS. 76A to 76C are views showing the conventional method for fabricating a nonvolatile semiconductor memory device.

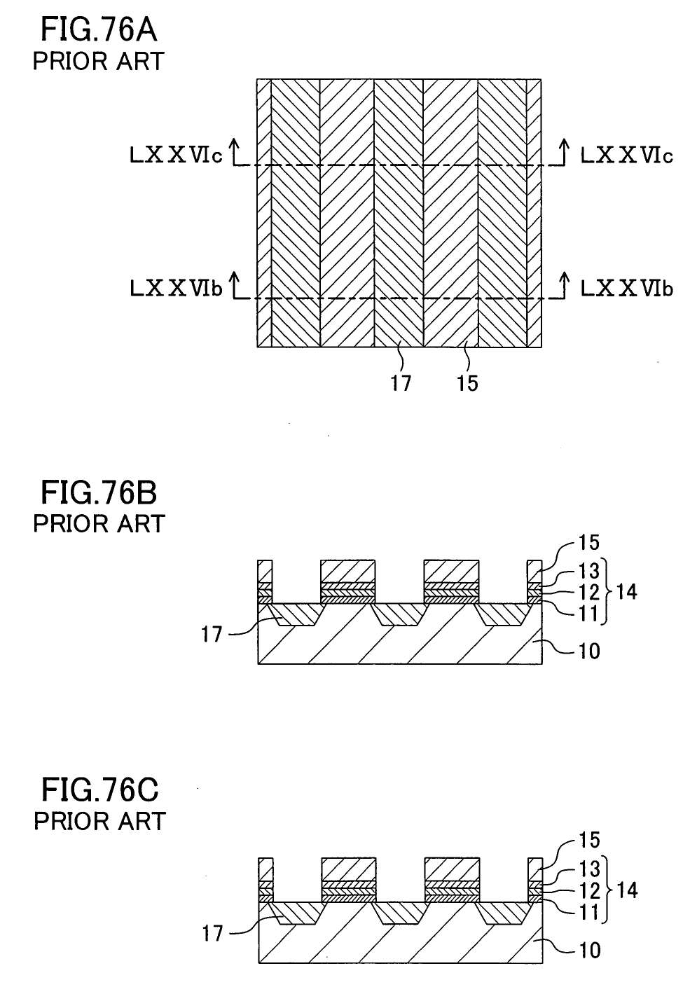

FIGS. 77A to 77C are views showing the conventional method for fabricating a nonvolatile semiconductor memory device.

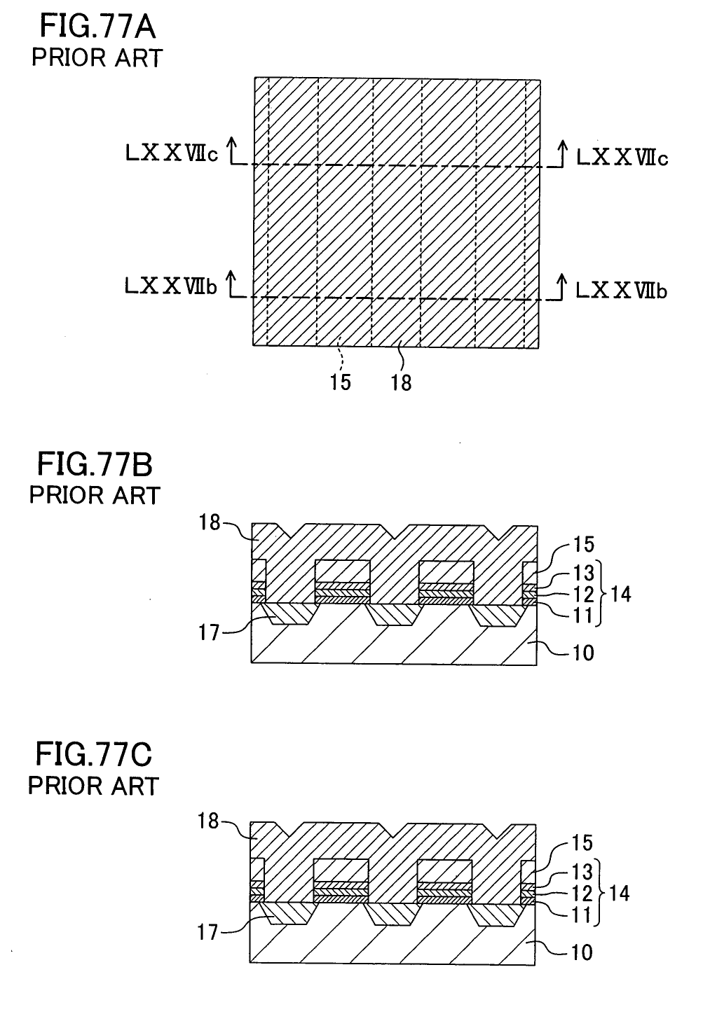

FIGS. 78A to 78C are views showing the conventional method for fabricating a nonvolatile semiconductor memory device.

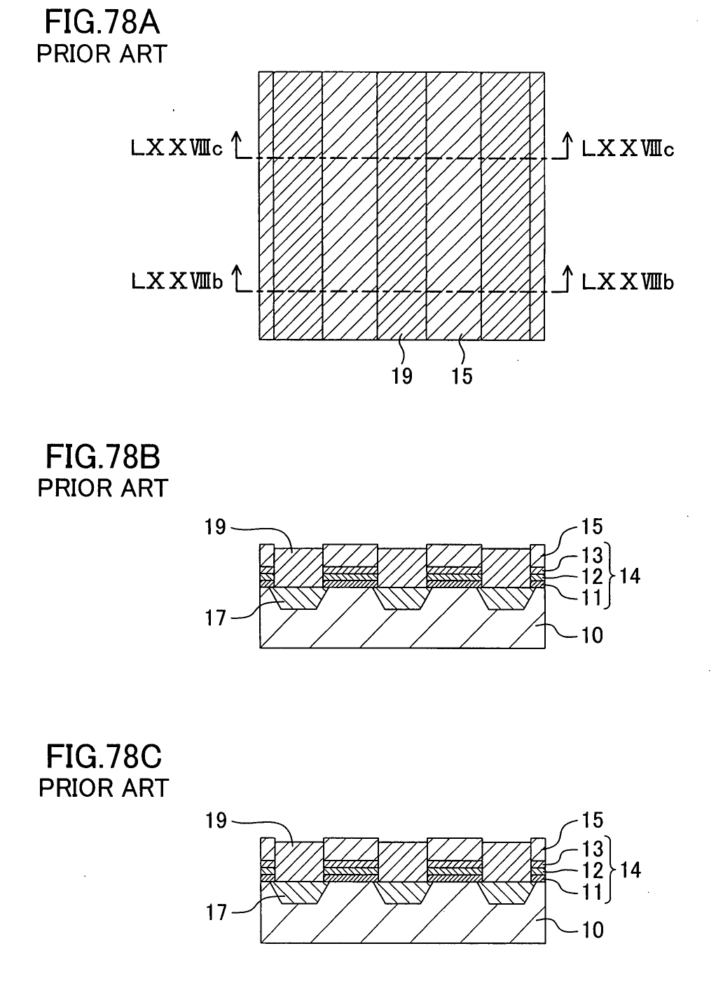

FIGS. 79A to 79C are views showing the conventional method for fabricating a nonvolatile semiconductor memory device.

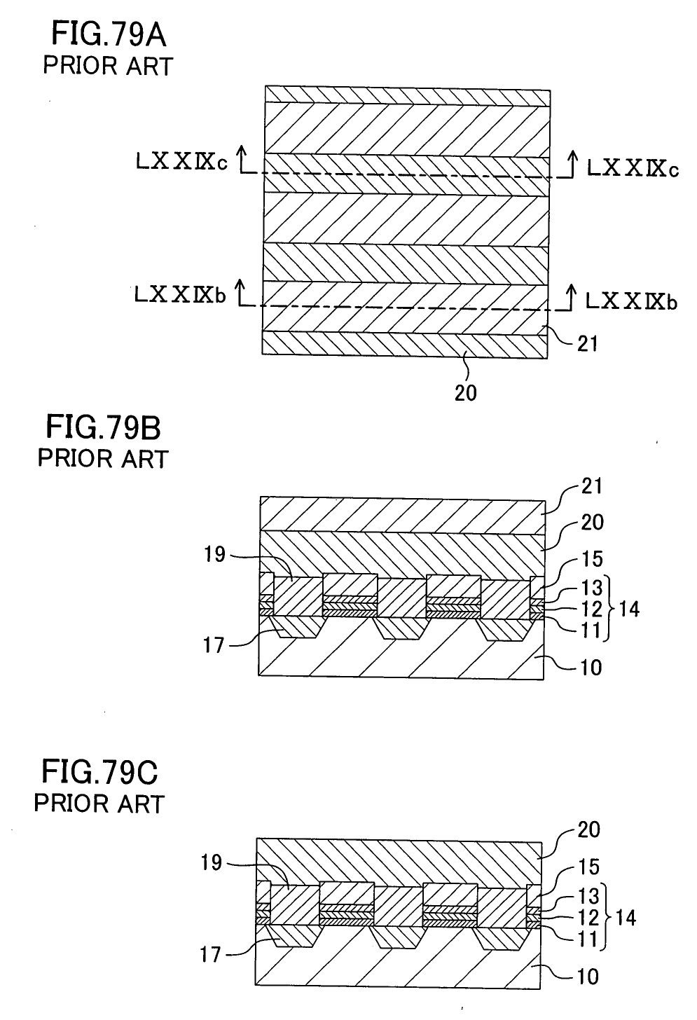

FIGS. 80A to 80D are views showing the conventional method for fabricating a nonvolatile semiconductor memory device.

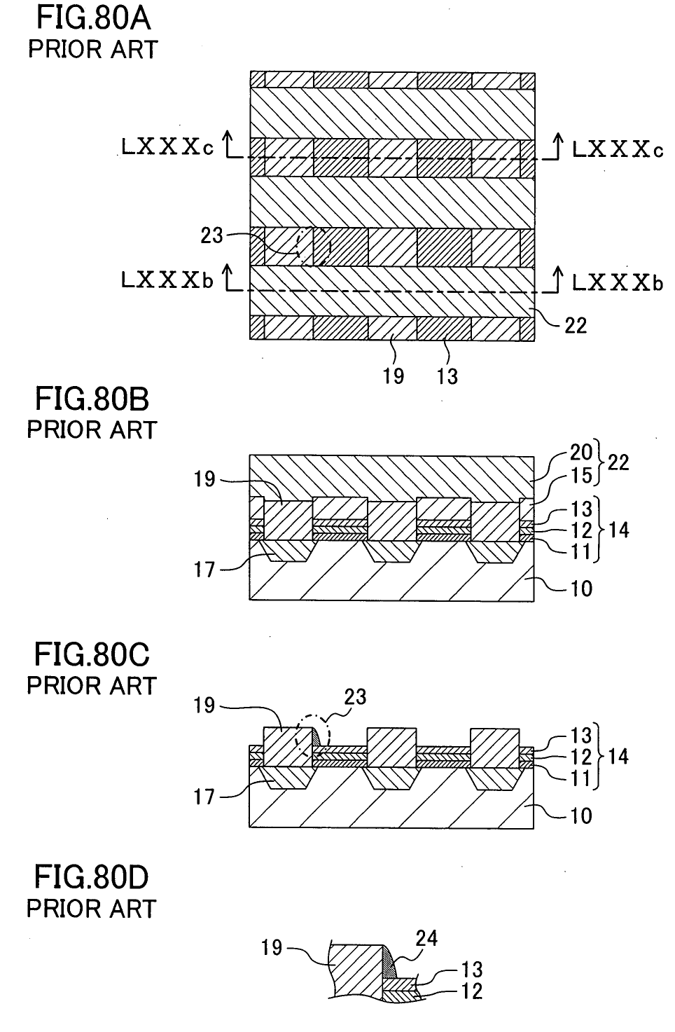

### DETAILED DESCRIPTION OF THE PREFERRED EMBODIMENTS

### First Embodiment

A nonvolatile semiconductor memory device and its fabrication method according to a first embodiment of the present invention will be described below with reference to the accompanying drawings.

### —Structure of Nonvolatile Semiconductor Memory Device—

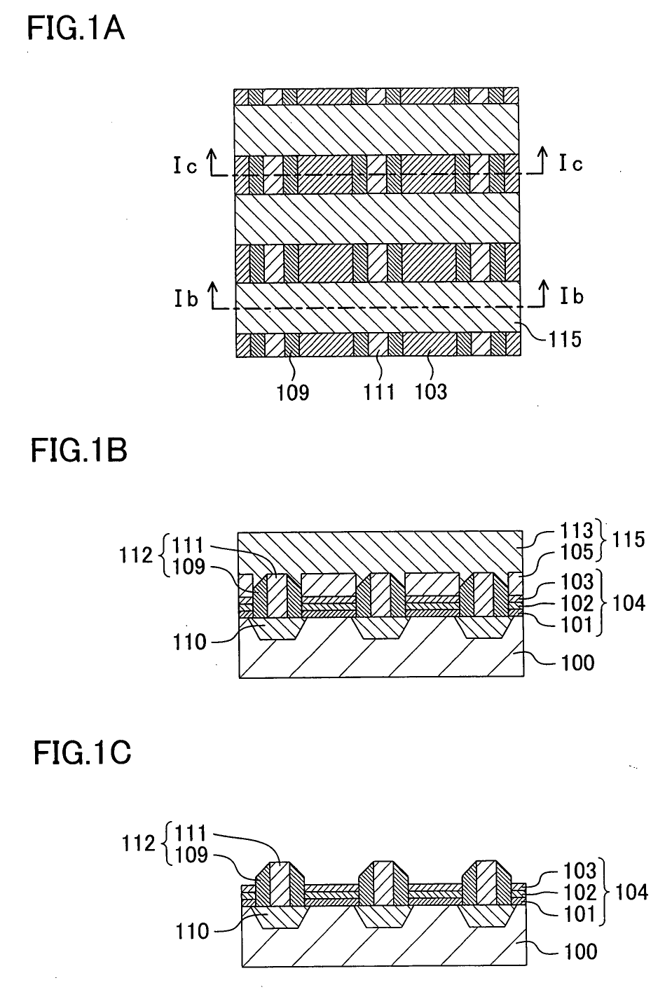

First, the structure of the nonvolatile semiconductor memory device according to the first embodiment will be described in detail using FIGS. 1A to 1C. FIG. 1A is a top view showing the structure of the nonvolatile semiconductor memory device according to the first embodiment. FIG. 1B is a sectional view taken along the line Ib-Ib shown in FIG. 1A, and FIG. 1C is a sectional view taken along the line Ic-Ic shown in FIG. 1A.

Referring to FIGS. 1A to 1C, the nonvolatile semiconductor memory device according to the first embodiment includes: a semiconductor substrate 100; a plurality of bit lines 110 formed of diffusion layers, respectively (referred to as “diffusion-layer bit lines 110”); an insulating film 112 on the bit line; a charge trapping layer 104; a first gate electrode film 105; and a second gate electrode film 113. The diffusion-layer bit lines 110 extend in the column direction in the semiconductor substrate 100. The insulating film 112 on the bit line is formed on each of the diffusion-layer bit lines 110, and extends in the column direction. The charge trapping layer 104 is formed on a region of the semiconductor substrate 100 positioned between the diffusion-layer bit lines 110 as seen from a horizontal plane. The first gate electrode film 105 is formed on the charge trapping layer 104. The second gate electrode film 113 is formed on the first gate electrode film 105 and the insulating film 112 on the bit line, and extends in the row direction. The charge trapping layer 104 has a multilayer structure made by sequentially stacking, from bottom to top, a first silicon oxide film 101, a silicon nitride film 102, and a second silicon oxide film 103.

In this structure, the insulating film 112 on the bit line is composed of: a buried oxide film 111 of HDP (High Density Plasma) or the like formed at the center portion thereof in the row direction; and an offset film 109 for implantation (referred to as “an implantation offset film 109”) which has a thickness of, for example, 15 nm, is formed at both ends thereof in the row direction, and is made of HTO (High Temperature Oxide) or the like. The insulating film 112 on the bit line is formed in a tapered shape in which the buried oxide film 111 has a greater thickness than the implantation offset film 109. The first and second gate electrode films 105 and 113 constitute the word line 115.

As described above, in the nonvolatile semiconductor memory device of the first embodiment, each memory cell transistor has: a portion of the charge trapping layer 104; respective portions of the diffusion-layer bit lines 110 located below the both sides of the portion of the charge trapping layer 104; and a portion of the word line 115 located on the portion of the charge trapping layer 104, and the memory cell transistors are arranged in rows and columns.

In the nonvolatile semiconductor memory device of the first embodiment, in the state in which a high voltage is applied to a selected word line 115, a voltage is applied to an associated diffusion-layer bit line 110. Thereby, charge is retained in the silicon nitride film 102 to write information therein.

### —Method for Fabricating Nonvolatile Semiconductor Memory Device—

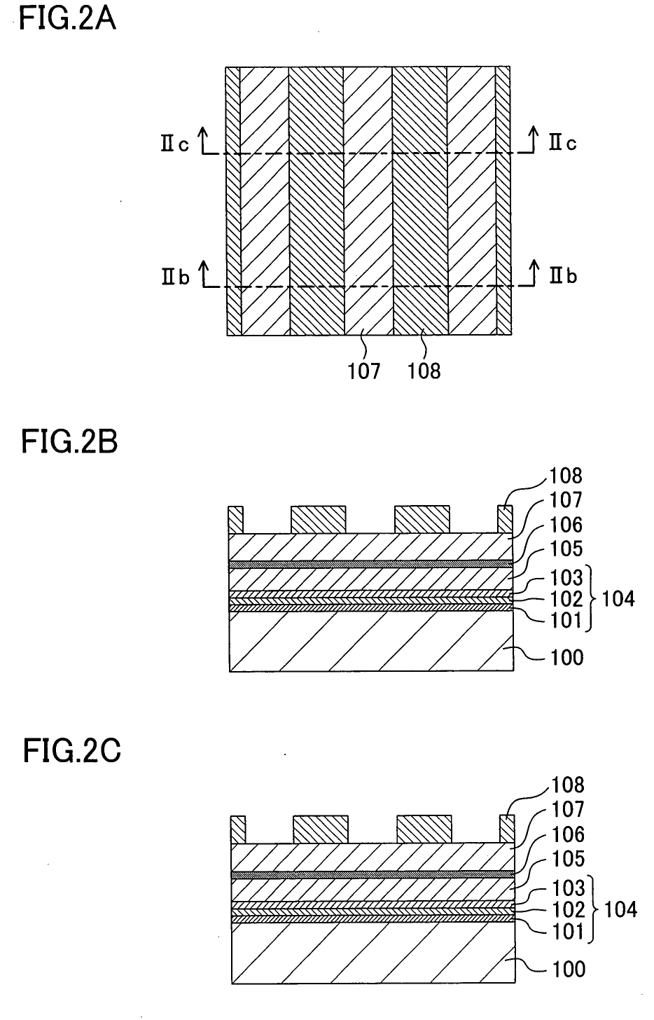

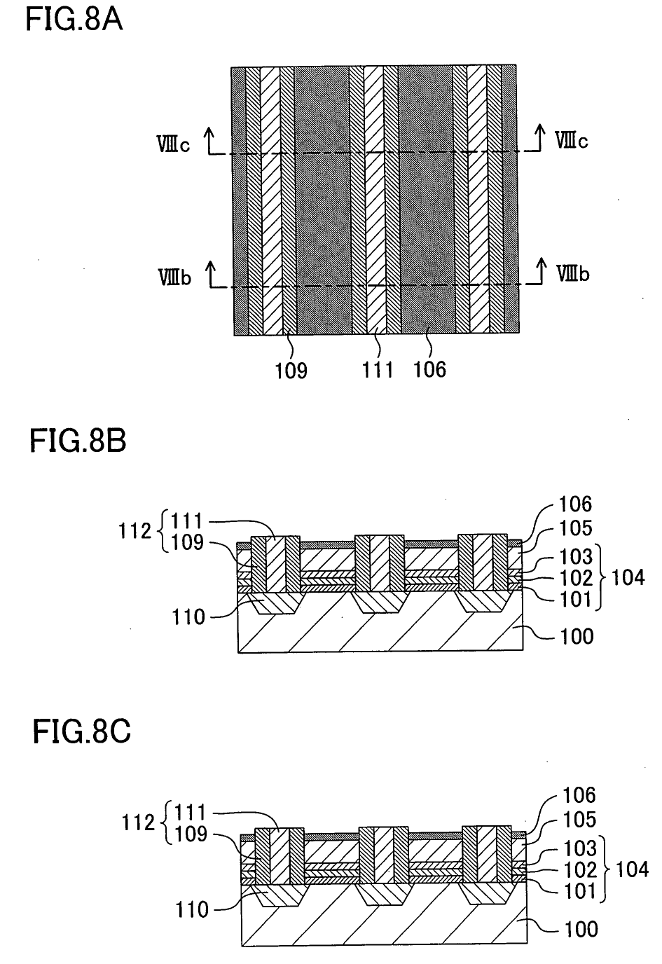

First, a first method for fabricating a nonvolatile semiconductor memory device according to the first embodiment will be described with reference to FIGS. 2 to 11. Note that the following figures accompanied with the reference character “A” are top views showing the first fabrication method of the first embodiment, and the following figures accompanied with the reference character “B” or “C” are sectional views showing the first fabrication method of the first embodiment.

Referring to FIGS. 2A to 2C, first, on the semiconductor substrate 100, the first silicon oxide film 101 with a thickness of, for example, 7 nm is formed by a thermal oxidation method. Thereafter, the silicon nitride film 102 with a thickness of, for example, 10 nm and the second silicon oxide film 103 with a thickness of, for example, 10 nm are sequentially deposited by a low pressure CVD (Chemical Vapor Deposition) method to form the charge trapping layer 104 composed of the first silicon oxide film 101, the silicon nitride film 102, and the second silicon oxide film 103. Next, the first gate electrode film 105 of polycrystalline silicon or the like, a buffer layer 106 of a TEOS (Tetra Ethyl Ortho Silicate) film or the like, and a bit line formation film 107 of SiN (a silicon nitride film) or the like are sequentially formed on the charge trapping layer 104. The first gate electrode film 105 is formed by a low pressure CVD (Chemical Vapor Deposition) method to have a thickness of, for example, 50 nm, and the buffer layer 106 is formed by a CVD method to have a thickness of, for example, 10 nm. The bit line formation film 107 is formed by a low pressure CVD method to have a thickness of, for example, 100 nm. After formation of the bit line formation film 107, by a lithography technique, a first mask 108 provided with a groove extending in the column direction is formed on the bit line formation film 107.

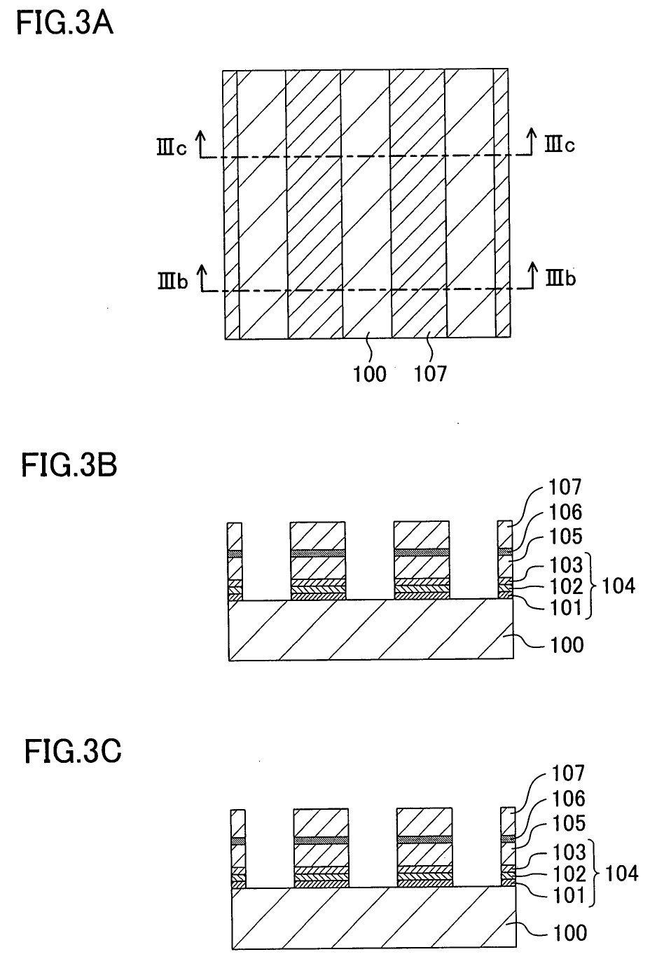

Subsequently, as shown in FIGS. 3A to 3C, using the first mask 108, the bit line formation film 107, the buffer layer 106, the first gate electrode film 105, and the charge trapping layer 104 are selectively etched away to form an opening extending in the column direction and reaching the semiconductor substrate 100. Thereafter, the first mask 108 is removed by ashing or the like.

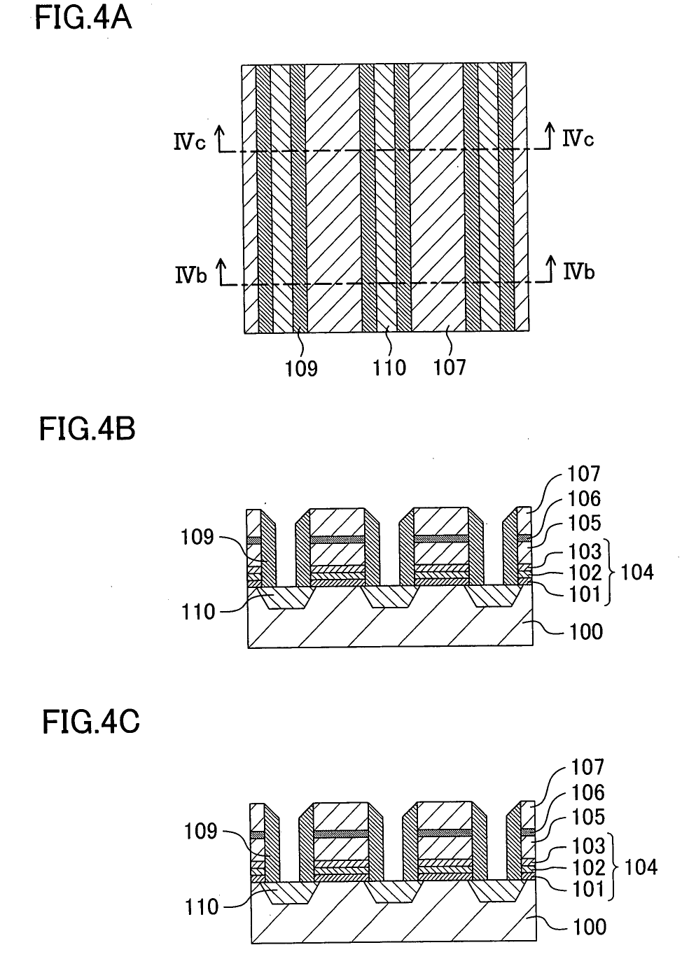

Next, as shown in FIGS. 4A to 4C, on an inner side surface of the opening, the implantation offset film 109 of HTO or the like having a thickness of, for example, 15 nm is formed by a CVD method. Then, from the opening into a predetermined region of the semiconductor substrate 100, boron ions are implanted as a pocket implantation on the condition of an acceleration voltage of 50 keV and a dose of 3×10¹³/cm², and arsenic ions are implanted as a source/drain implantation on the condition of an acceleration voltage of 20 keV and a dose of 2×10¹⁵/cm². Thereafter, for example, a thermal treatment at 900° C. for 60 minutes is performed thereon in a nitrogen atmosphere to form the diffusion-layer bit line 110 functioning as source and drain regions of the memory cell transistor. Note that the formed implantation offset film 109 enables adjustment of concentration profile of the diffusion-layer bit line.

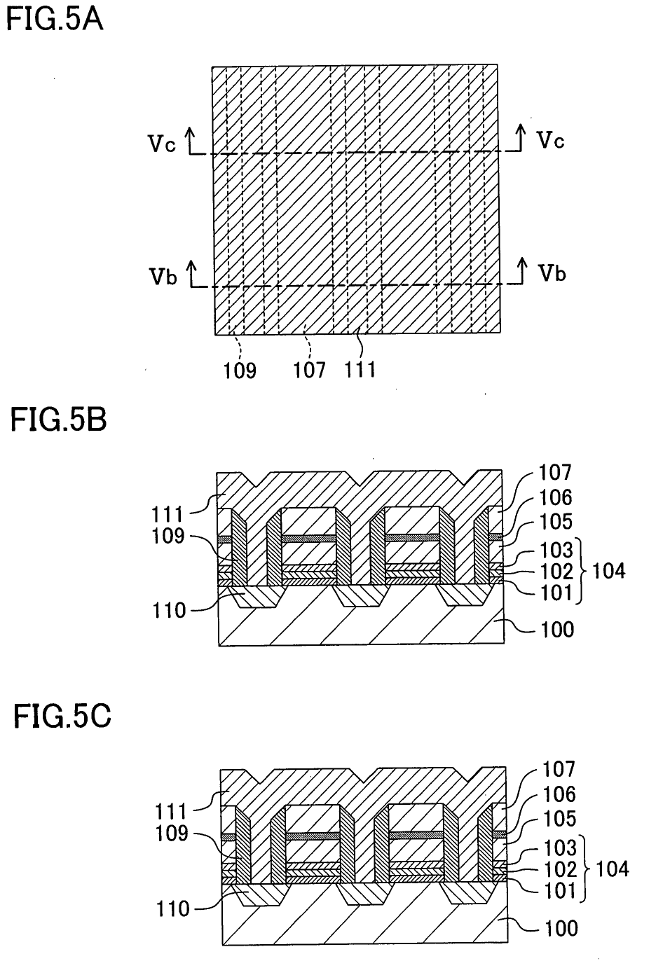

Subsequently, as shown in FIGS. 5A to 5C, the buried oxide film 111 of, for example, HDP is deposited over the entire surface of the semiconductor substrate 100 to fill the opening with the buried oxide film 111.

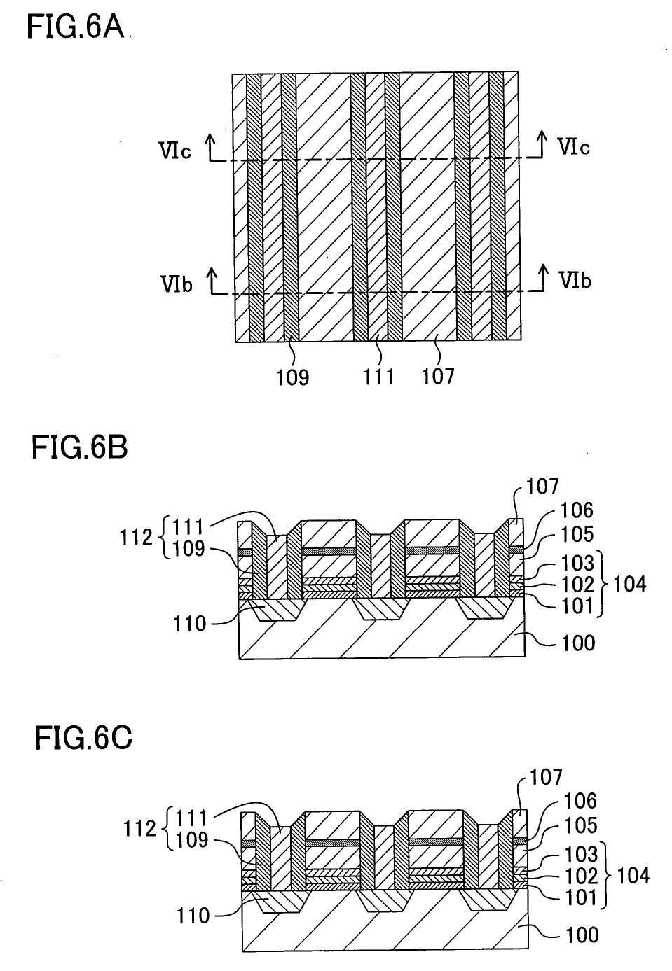

As shown in FIGS. 6A to 6C, by CMP(Chemical Mechanical Polishing), the buried oxide film 111 is polished to expose the bit line formation film 107, thereby forming the insulating film 112 on the bit line which is composed of the implantation offset film 109 and the buried oxide film 111. In this process, a publicly-known removal technique by overall etch back may be employed instead of CMP.

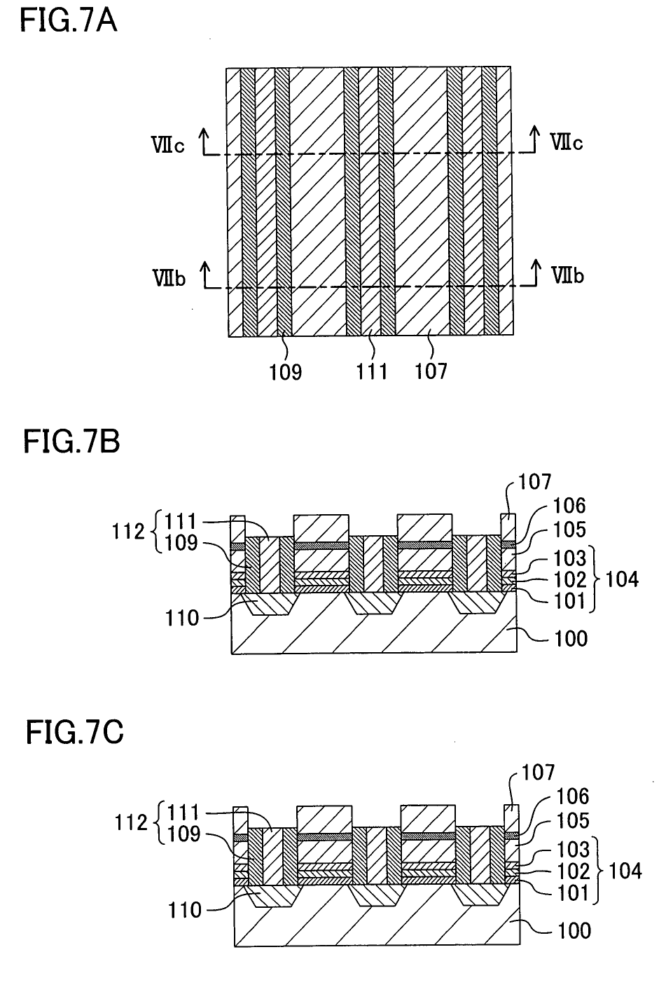

Next, as shown in FIGS. 7A to 7C, by performing wet etching with a BHF solution or the like, the implantation offset film 109 and the buried oxide film 111 are etched so that the top surface of the insulating film 112 on the bit line has a higher level than the top surface of the buffer layer 106 by, for example, 5 to 20 nm inclusive. In this etching, in the case of using a BHF solution, the etching rate of the implantation offset film 109 is relatively higher than that of the buried oxide film 111, and the etching rate ratio of the implantation offset film 109 to the buried oxide film 111 is 2.5. Instead of the wet etching, a publicly-known dry etching may be employed, and alternatively wet etching and dry etching may be employed in combination. In addition, it is sufficient that the implantation offset film 109 has a higher etching rate than the buried oxide film 111, and the etching rate ratio therebetween is not limited to 2.5.

Subsequently, as shown in FIGS. 5A to 8C, the bit line formation film 107 is removed.

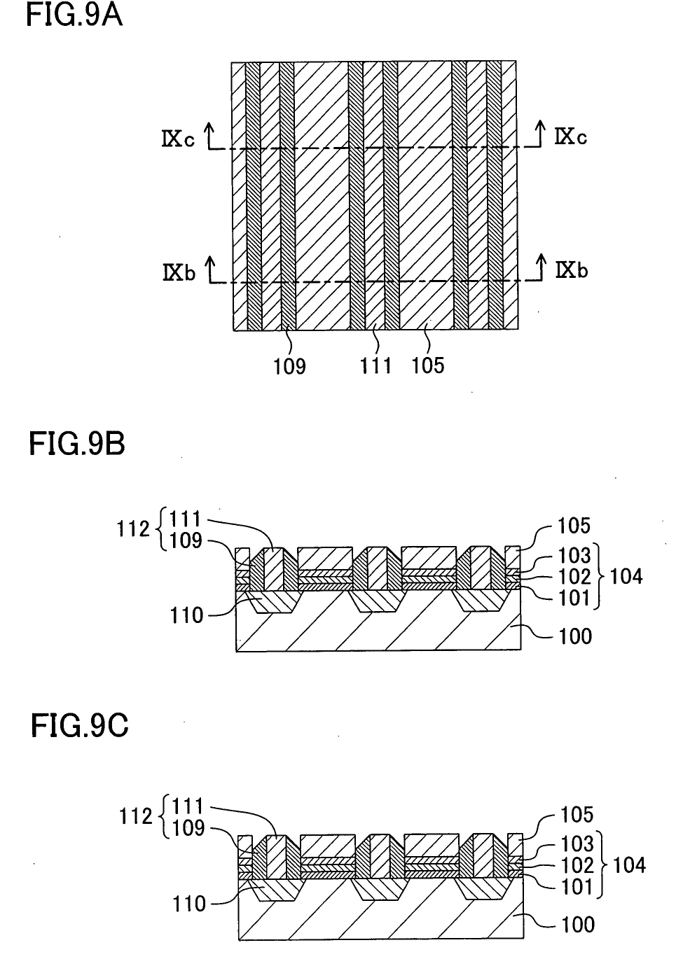

As shown in FIGS. 9A to 9C, by performing isotropic wet etching with a BHF solution or the like, the buffer layer 106 is removed to expose the first gate electrode film 105. During this process, the implantation offset film 109 and the buried oxide film 111 are also etched to form the tapered insulating film 112 on the bit line. With this process, the top surface of the first gate electrode film 105 has almost the same level as the top surface of the insulating film 112 on the bit line. This is because in the step shown in FIG. 7, the level of the top surface of the insulating film 112 on the bit line and the level of the top surface of the buffer layer 106 are adjusted so that the difference therebetween falls within the predetermined range.

In this process, in the case of employing a BHF solution, the etching rates of the buffer layer 106 and the implantation offset film 109 are relatively greater than the etching rate of the buried oxide film 111, and the etching rate ratios thereof to the buried oxide film 111 fall within a range of 2.5 to 3.5. Preferably, the wet etching used is isotropic etching. Thereby, in the step shown in FIG. 9, the implantation offset film 109 is etched not only from the top surface but also from the side surface, while the buried oxide film 111 resists being etched. Therefore, in the row direction, the insulating film 112 has a greater thickness at the center portion than at the both ends, whereby the tapered insulating film 112 on the bit line can be formed. If the etching used is an isotropic etching, dry etching may be used instead of wet etching, and alternatively wet etching and dry etching may be used in combination.

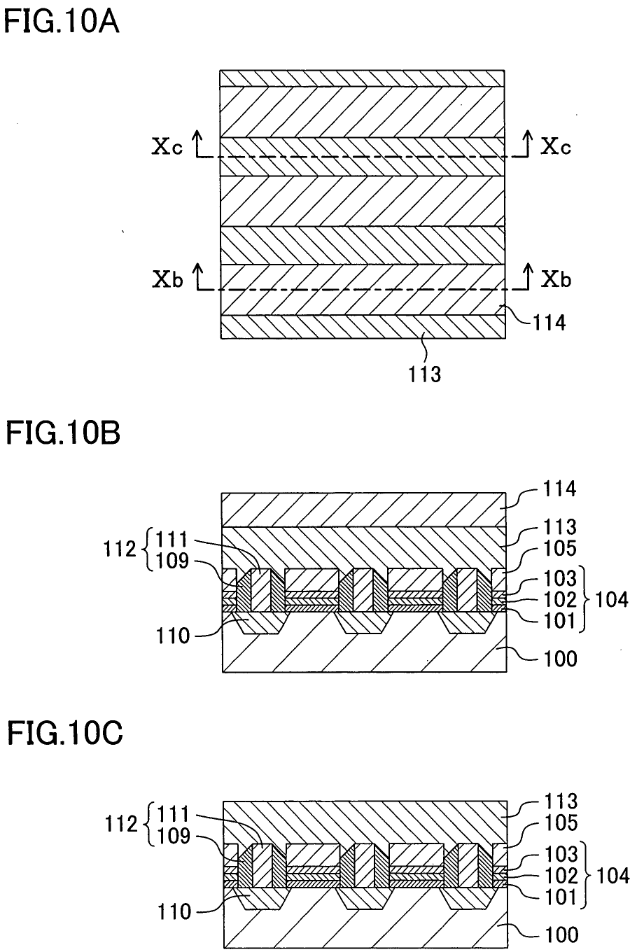

Next, as shown in FIGS. 10A to 10C, the second gate electrode film 113 made of polycrystalline silicon or the like is deposited over the entire surface of the semiconductor substrate 100. Thereafter, on the second gate electrode film 113, a second mask 114 provided with a groove extending in the row direction is formed by a lithography technique.

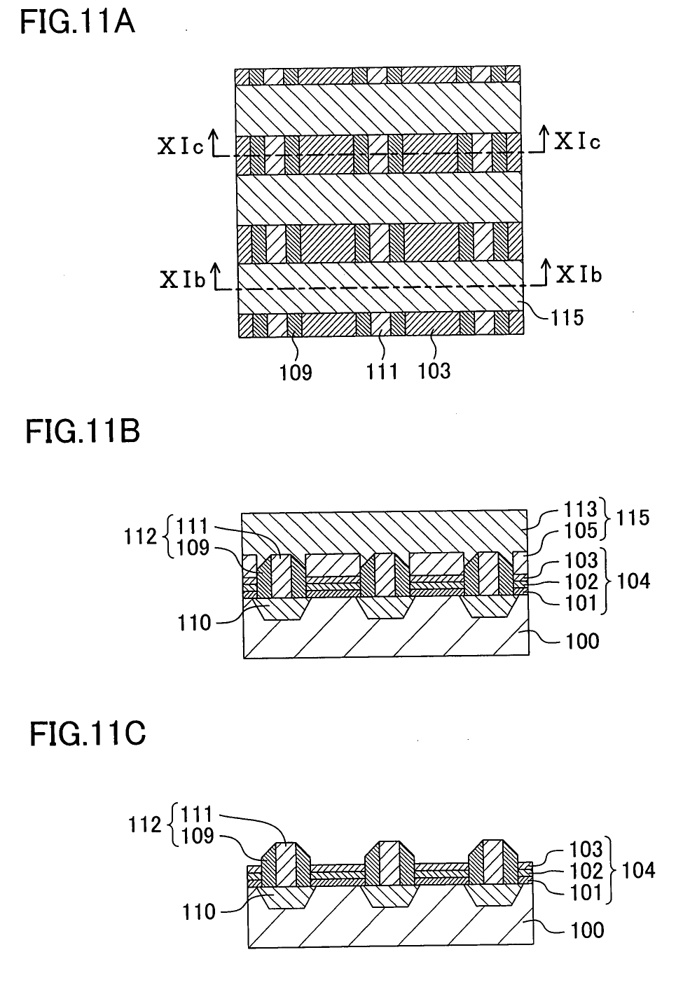

Finally, as shown in FIGS. 11A to 11C, portions of the first gate electrode film 105 and the second gate electrode film 113 are etched away using the second mask 114 to form the word line 115 composed of the first gate electrode film 105 and the second gate electrode film 113. Then, the second mask 114 is removed by ashing or the like.

In this structure, since the insulating film 112 on the bit line is formed in a tapered shape in the step shown in FIG. 9, the level difference is reduced between the both ends of the insulating film 112 in the row direction and the top surface of the charge trapping layer 104. Thus, the first gate electrode film 105 can be etched away relatively easily, so that a residue of the first gate electrode film 105 can be prevented from appearing after the etching.

Thereafter, a metal interconnect formation process, a protective film formation process, and a bonding pad formation process are carried out. However, their description is omitted herein. By the process steps described above, the nonvolatile semiconductor memory device according to the first embodiment can be fabricated.

As described above, in the first method for fabricating a nonvolatile semiconductor memory device according to the first embodiment, the insulating film 112 on the bit line is formed in a tapered shape as shown in FIG. 9. Therefore, appearance of a residue of the first gate electrode film 105 can be prevented. This enables fabrication of the nonvolatile semiconductor memory device which is designed to suppress leakage between the word lines. Moreover, by adjusting the level of the insulating film 112 on the bit line in the step shown in FIG. 7, the nonvolatile semiconductor memory device can be provided which has a small level difference, a good flatness, and a highly stable structure.

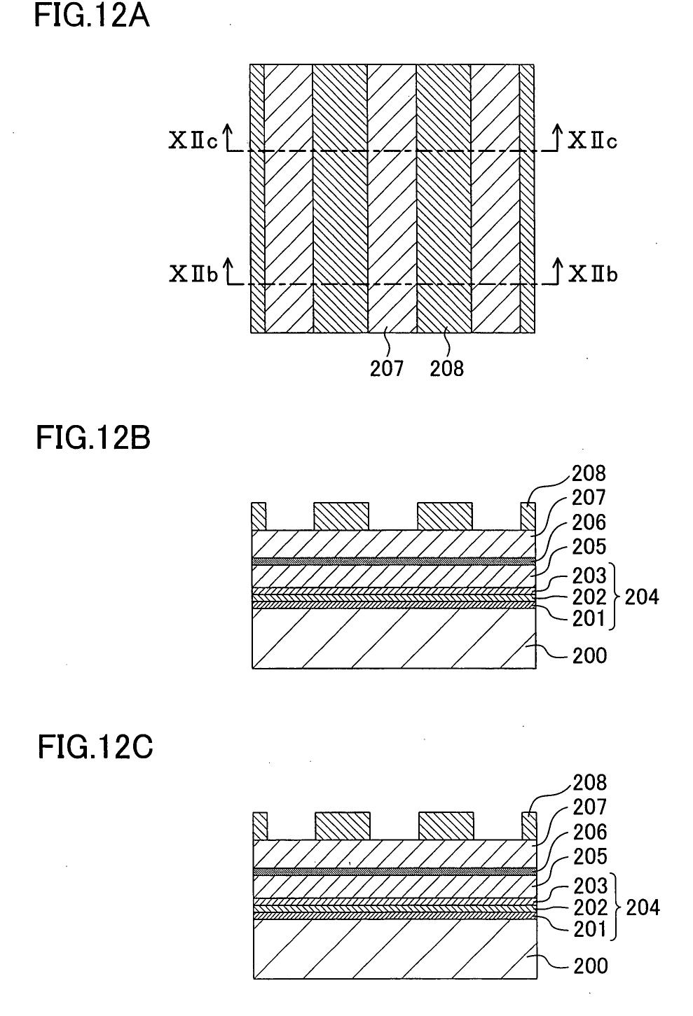

Next, a second method for fabricating a nonvolatile semiconductor memory device according to the first embodiment will be described with reference to FIGS. 12 to 20. In this description, the following figures accompanied with the reference character “A” are top views showing the second fabrication method of the first embodiment, and the following figures accompanied with the reference character “B” or “C” are sectional views showing the second fabrication method of the first embodiment. Since the process steps shown in FIGS. 12 to 16 are carried out in the same manner as the process steps of the above-mentioned first fabrication method of the first embodiment shown in FIGS. 2 to 6, they will be described briefly.

Referring to FIGS. 12A to 12C, first, on a semiconductor substrate 200, a first silicon oxide film 201, a silicon nitride film 202, and a second silicon oxide film 203 are sequentially deposited to form a charge trapping layer 204 composed of these three films. Thereafter, a first gate electrode film 205 of polycrystalline silicon or the like, a buffer layer 206 of a TEOS film or the like, a bit line formation film 207 of SiN or the like, and a third mask 208 provided with a groove extending in the column direction are sequentially formed on the charge trapping layer 204. As the formation method of the respective layers, the same method as the first fabrication method of the first embodiment can be employed.

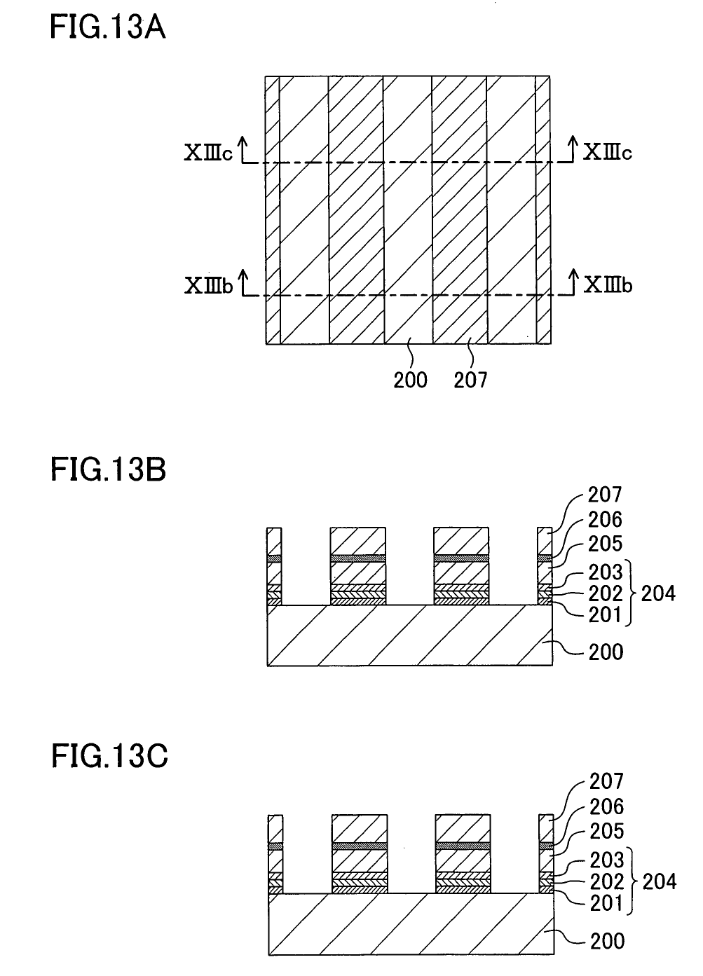

Next, as shown in FIGS. 13A to 13C, using the third mask 208, the bit line formation film 207, the buffer layer 206, the first gate electrode film 205, and the charge trapping layer 204 are selectively etched away to form an opening extending in the column direction and reaching the semiconductor substrate 200. Thereafter, the third mask 208 is removed by ashing or the like.

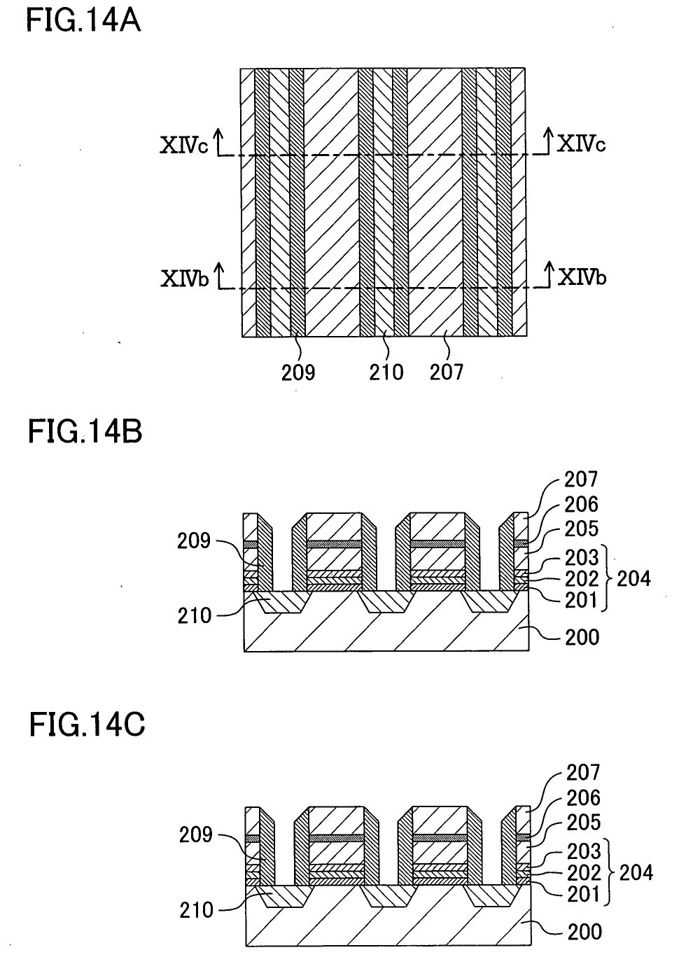

Subsequently, as shown in FIGS. 14A to 14C, an implantation offset film 209 is formed on an inner side surface of the opening. Then, from the opening into a predetermined region of the semiconductor substrate 200, boron ions are implanted as a pocket implantation on the condition of an acceleration voltage of 50 keV and a dose of 3×10¹³/cm², and arsenic ions are implanted as a source/drain implantation on the condition of an acceleration voltage of 20 keV and a dose of 2×10¹⁵/cm². Thereafter, for example, a thermal treatment at 900° C. for 60 minutes is performed thereon in a nitrogen atmosphere to form a diffusion-layer bit line 210 functioning as source and drain regions of the memory cell transistor.

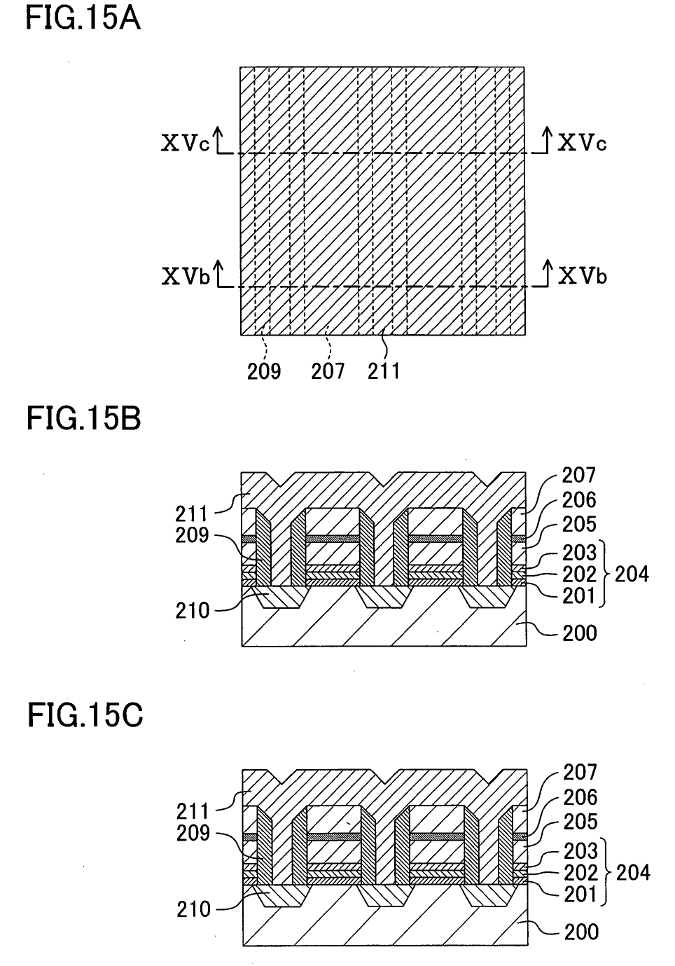

Next, as shown in FIGS. 15A to 15C, a buried oxide film 211 of, for example, HDP is deposited over the entire surface of the semiconductor substrate 200 to fill the opening with the buried oxide film 211.

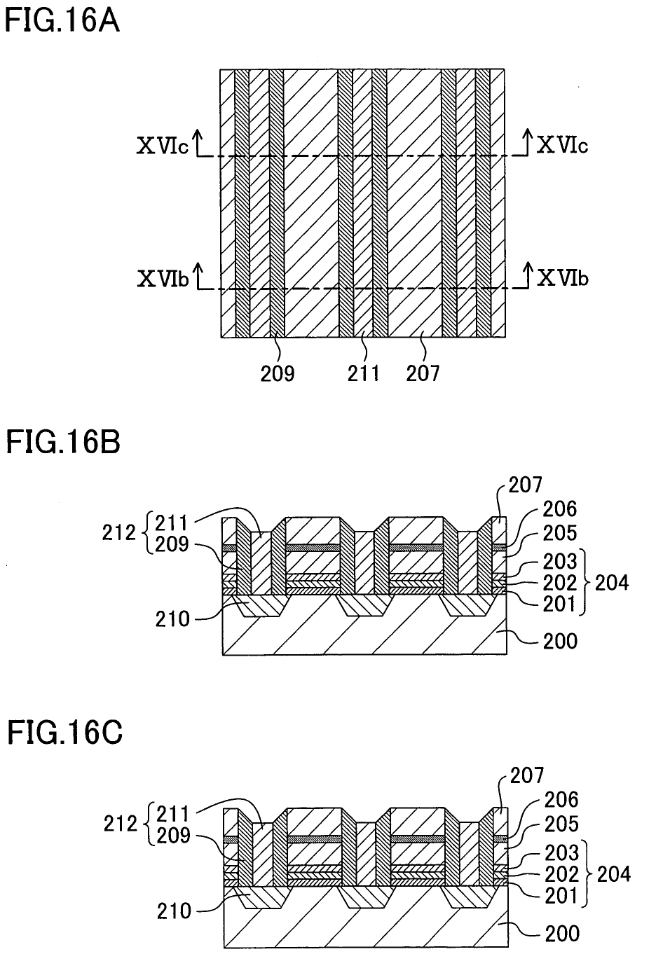

As shown in FIGS. 16A to 16C, the buried oxide film 211 is polished by CMP to expose the bit line formation film 207. Thereby, an insulating film 212 on the bit line is formed which is composed of the implantation offset film 209 and the buried oxide film 211.

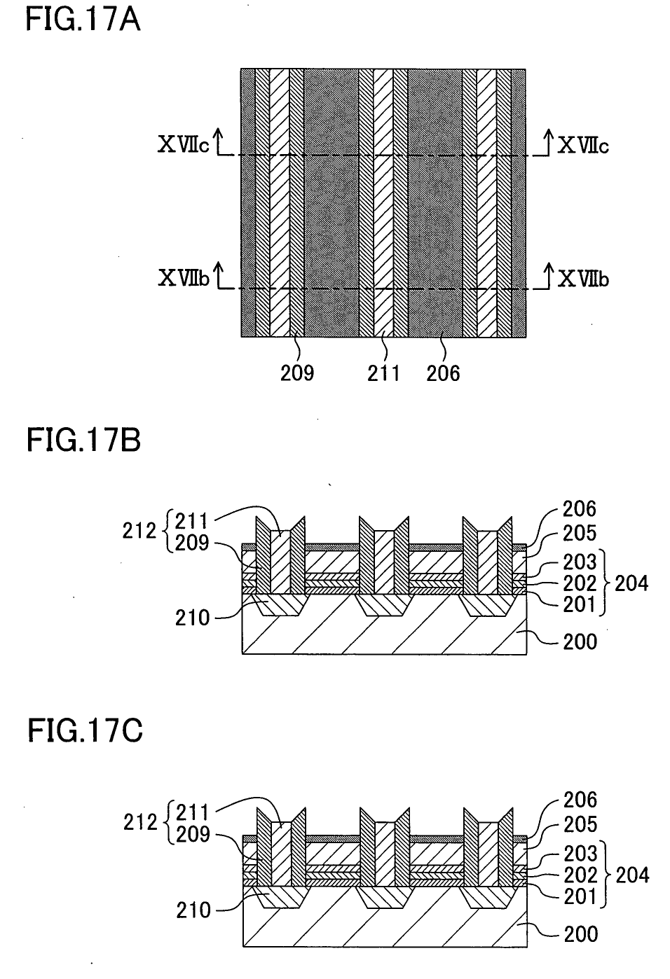

Next, as shown in FIGS. 17A to 17C, the bit line formation film 207 is removed.

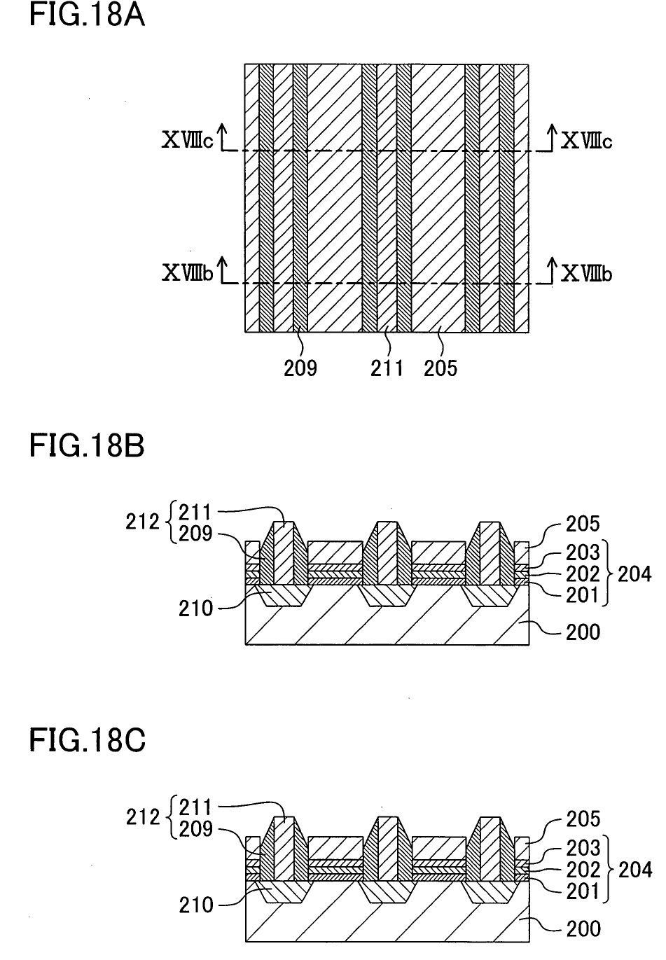

Subsequently, as shown in FIGS. 18A to 18C, by performing wet etching with, for example, a BHF solution, the buffer layer 206 is removed to expose the first gate electrode film 205. During this process, the implantation offset film 209 and the buried oxide film 211 are also etched to form the tapered insulating film 212 on the bit line.

In this process, in the case of employing a BHF solution, the etching rates of the buffer layer 206 and the implantation offset film 209 are relatively greater than the etching rate of the buried oxide film 211, and the etching rate ratios thereof to the buried oxide film 211 fall within a range of 2.5 to 3.5. Preferably, the wet etching used is isotropic etching. Thereby, in the step shown in FIG. 18, the implantation offset film 209 is etched not only from the top surface but also from the side surface, while the buried oxide film 211 resists being etched. Therefore, in the row direction, the insulating film 212 has a greater thickness at the center portion than at the both ends, whereby the tapered insulating film 212 on the bit line can be formed.

Furthermore, in the second fabrication method of the first embodiment, the level adjustment step carried out in the first fabrication method shown in FIG. 7 is eliminated, so that in the step shown in FIG. 17, the level difference becomes wider between the top surface of the implantation offset film 209 and the top surface of the buffer layer 206. This more significantly promotes, in the step shown in FIG. 18, etching from the side surface of the implantation offset film 209. As a result of this, the thickness difference between the center portion and the both ends in the row direction becomes wider than that of the first fabrication method, so that the insulating film 212 on the bit line having a more sharply tapered shape can be formed. If the etching used is an isotropic etching, dry etching may be used instead of wet etching, and alternatively wet etching and dry etching may be used in combination.

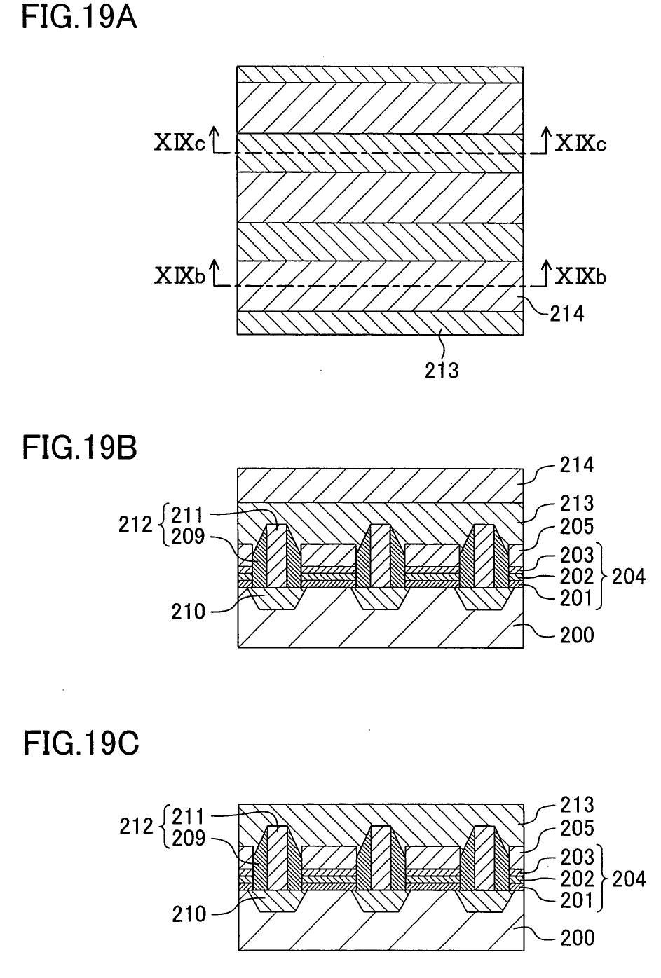

Subsequently, as shown in FIGS. 19A to 19C, a second gate electrode film 213 made of polycrystalline silicon or the like is deposited over the entire surface of the semiconductor substrate 200. Thereafter, on the second gate electrode film 213, a fourth mask 214 provided with a groove extending in the row direction is formed by a lithography technique.

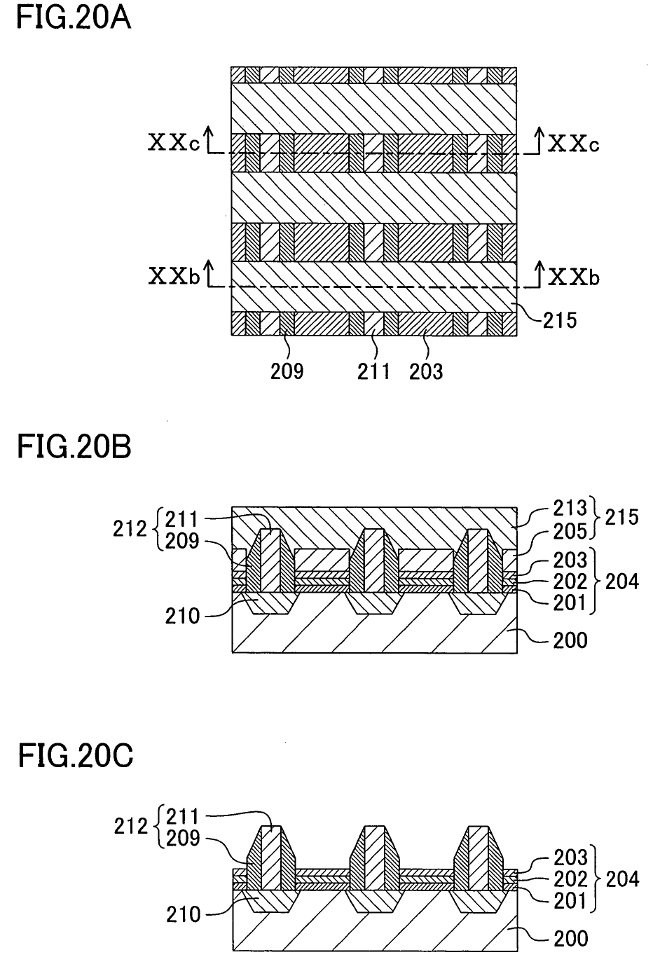

Finally, as shown in FIGS. 20A to 20C, portions of the first gate electrode film 205 and the second gate electrode film 213 are etched away using the fourth mask 214 to form a word line 215 composed of the first gate electrode film 205 and the second gate electrode film 213. Then, the fourth mask 214 is removed by ashing or the like.

In this structure, since the insulating film 212 on the bit line is formed in a sharply tapered shape in the step shown in FIG. 18, the first gate electrode film 205 can be etched away more easily than that in the first fabrication method of the first embodiment. Thus, with the second fabrication method of the first embodiment, the nonvolatile semiconductor memory device can be fabricated in which appearance of a residue of the first gate electrode film 205 is further prevented.

Thereafter, a metal interconnect formation process, a protective film formation process, and a bonding pad formation process are carried out. However, their description is omitted herein. By the process steps described above, the nonvolatile semiconductor memory device according to the first embodiment can be fabricated.

As described above, in the second method for fabricating a nonvolatile semiconductor memory device according to the first embodiment, the sharply-tapered insulating film 212 on the bit line is formed in the step shown in FIG. 18. Therefore, appearance of a residue of the first gate electrode film 205 can be prevented. This enables fabrication of the nonvolatile semiconductor memory device that is designed to suppress leakage between the word lines. Moreover, unlike the above-described first fabrication method of the first embodiment, the level adjustment step for the insulating film 212 on the bit line is eliminated. Thus, the nonvolatile semiconductor memory device can be fabricated relatively easily.

### Second Embodiment

Hereinafter, a nonvolatile semiconductor memory device and its fabrication method according to a second embodiment of the present invention will be described with reference to the accompanying drawings.

### —Structure of Nonvolatile Semiconductor Memory Device—

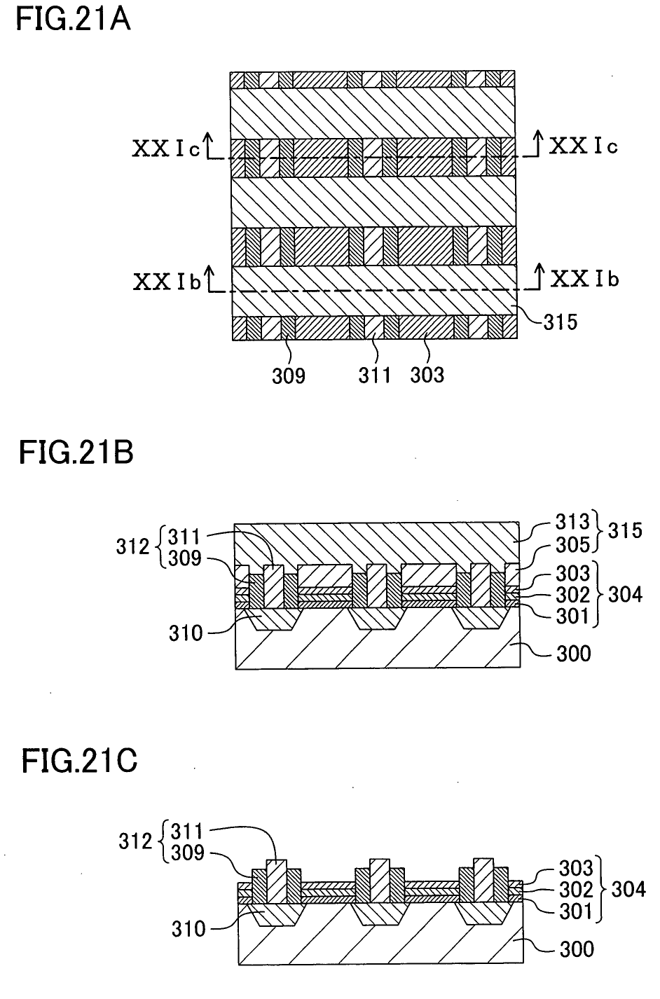

First, the structure of the nonvolatile semiconductor memory device according to the second embodiment will be described in detail using FIGS. 21A to 21C. FIG. 21A is a top view showing the structure of the nonvolatile semiconductor memory device according to the second embodiment. FIG. 21B is a sectional view taken along the line XXIb-XXIb shown in FIG. 21A, and FIG. 21C is a sectional view taken along the line XXIc-XXIc shown in FIG. 21A.

Referring to FIGS. 21A to 21C, the nonvolatile semiconductor memory device according to the second embodiment includes: a semiconductor substrate 300; a plurality of diffusion-layer bit lines 310; an insulating film 312 on the bit line; a charge trapping layer 304; a first gate electrode film 305; and a second gate electrode film 313. The diffusion-layer bit lines 310 extend in the column direction in the semiconductor substrate 300. The insulating film 312 on the bit line is formed on each of the diffusion-layer bit lines 310, and extends in the column direction. The charge trapping layer 304 is formed on a region of the semiconductor substrate 300 positioned between the diffusion-layer bit lines 310 as seen from a horizontal plane. The first gate electrode film 305 is formed on the charge trapping layer 304. The second gate electrode film 313 is formed on the first gate electrode film 305 and the insulating film 312 on the bit line, and extends in the row direction. The charge trapping layer 304 has a multilayer structure made by sequentially stacking, from bottom to top, a first silicon oxide film 301, a silicon nitride film 302, and a second silicon oxide film 303.

In this structure, the insulating film 312 on the bit line is composed of: a buried oxide film 311 of HDP (High Density Plasma) or the like formed at the center portion thereof in the row direction; and an implantation offset film 309 which has a thickness of, for example, 15 nm, is formed at both ends thereof in the row direction, and is made of HTO (High Temperature Oxide) or the like. The insulating film 312 on the bit line is formed to have a convex shape in which the buried oxide film 311 has a greater thickness than the implantation offset film 309. The top surface of the implantation offset film 309 is flat unlike the nonvolatile semiconductor memory device according to the first embodiment. The first and second gate electrode films 305 and 313 constitute a word line 315.

As described above, in the nonvolatile semiconductor memory device of the second embodiment, each memory cell transistor has: a portion of the charge trapping layer 304; respective portions of the diffusion-layer bit lines 310 located below the both sides of the portion of the charge trapping layer 304; and a portion of the word line 315 located on the portion of the charge trapping layer 304, and the memory cell transistors are arranged in rows and columns. Note that since operations of each memory are identical to those of the first embodiment described above, their description is omitted herein.

### —Method for Fabricating Nonvolatile Semiconductor Memory Device—

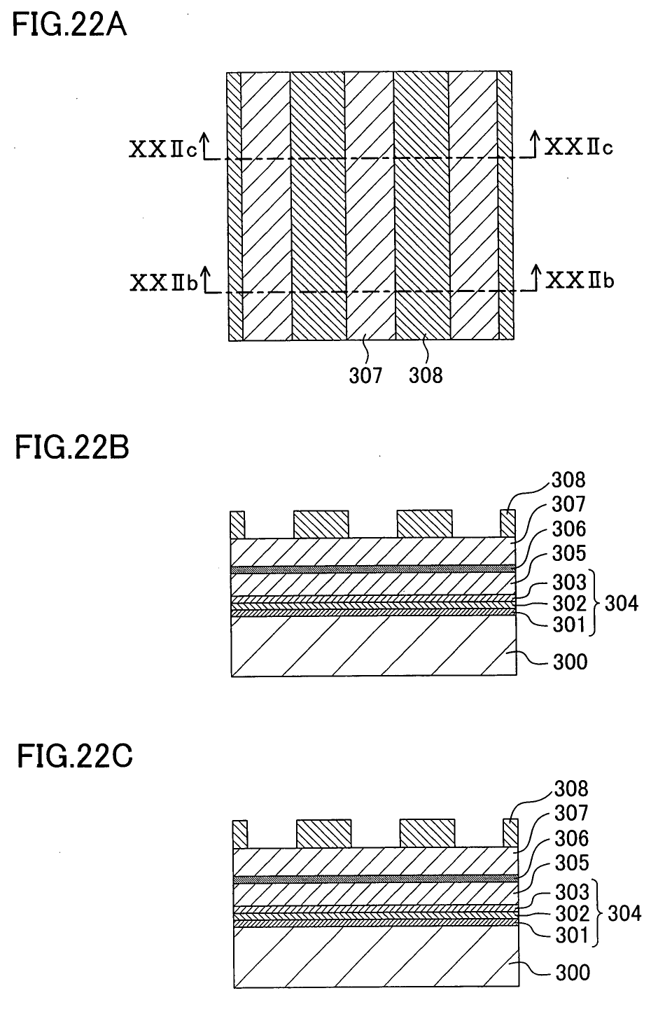

A method for fabricating a nonvolatile semiconductor memory device according to the second embodiment will be described with reference to FIGS. 22 to 30. In this description, the following figures accompanied with the reference character “A” are top views showing the fabrication method of the second embodiment, and the following figures accompanied with the reference character “B” or “C” are sectional views showing the fabrication method of the second embodiment. Since the process steps shown in FIGS. 22 to 26 are carried out in the same manner as the process steps of the above-mentioned first fabrication method of the first embodiment (FIGS. 2 to 6), their description will be simplified.

Referring to FIGS. 22A to 22C, first, on the semiconductor substrate 300, the first silicon oxide film 301, the silicon nitride film 302, and the second silicon oxide film 303 are sequentially deposited to form the charge trapping layer 304 composed of these three films. Thereafter, the first gate electrode film 305 of polycrystalline silicon or the like, a buffer layer 306 of a TEOS film or the like, a bit line formation film 307 of SiN or the like, and a fifth mask 308 provided with a groove extending in the column direction are sequentially formed on the charge trapping layer 304.

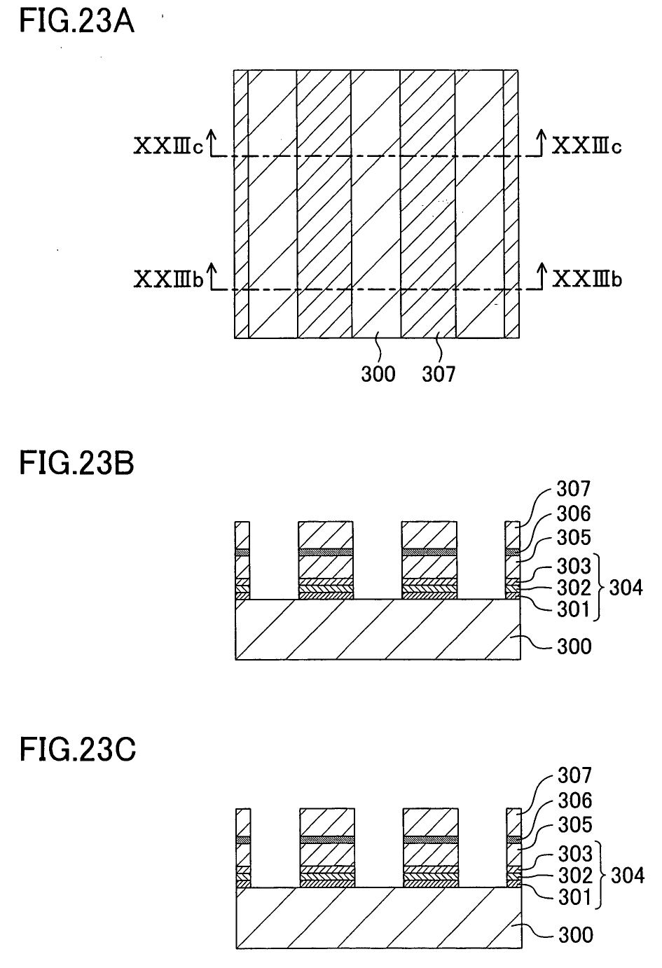

Next, as shown in FIGS. 23A to 23C, using the fifth mask 308, the bit line formation film 307, the buffer layer 306, the first gate electrode film 305, and the charge trapping layer 304 are selectively etched away to form an opening extending in the column direction and reaching the semiconductor substrate 300. Thereafter, the fifth mask 308 is removed by ashing or the like.

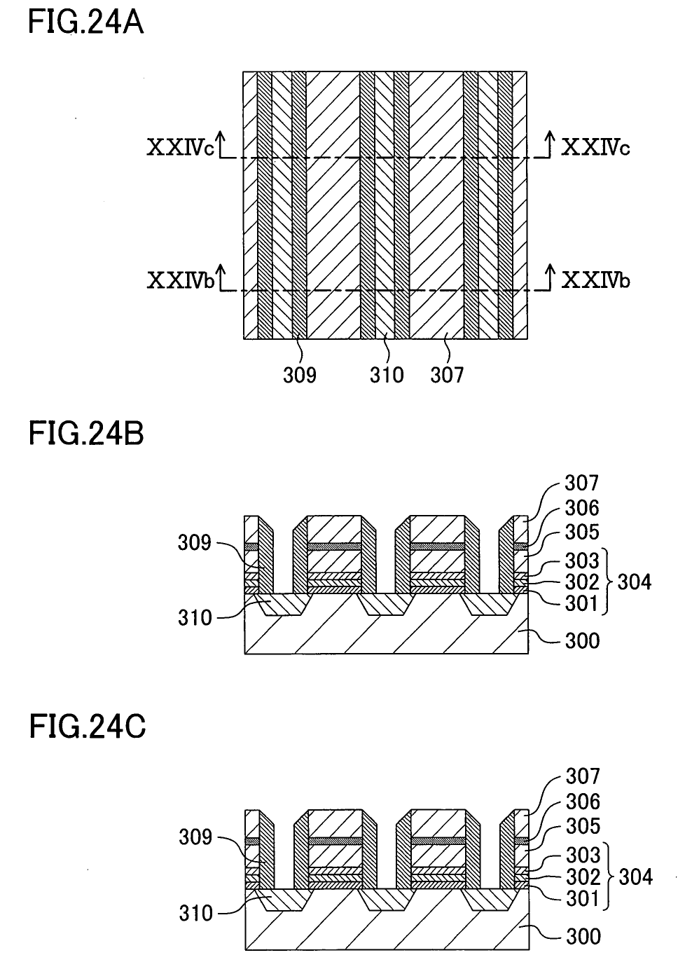

Subsequently, as shown in FIGS. 24A to 24C, the implantation offset film 309 is formed on an inner side surface of the opening. Then, from the opening into a predetermined region of the semiconductor substrate 300, boron ions are implanted as a pocket implantation, and arsenic ions are implanted as a source/drain implantation. Thereafter, for example, a thermal treatment at 900° C. for 60 minutes is performed thereon in a nitrogen atmosphere to form the diffusion-layer bit line 310 functioning as source and drain regions of the memory cell transistor.

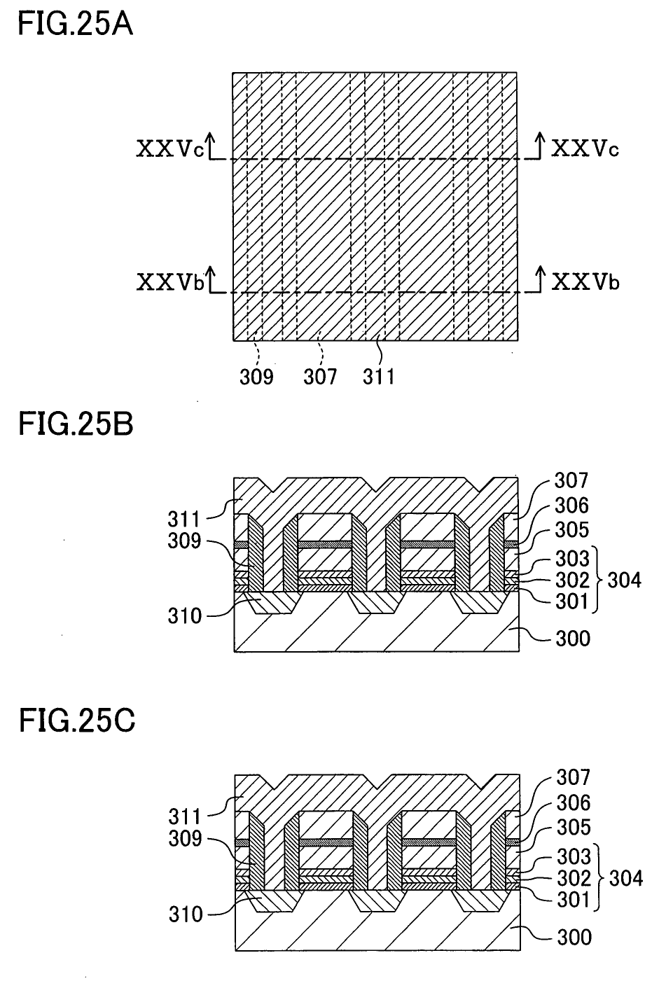

Next, as shown in FIGS. 25A to 25C, the buried oxide film 311 of, for example, HDP is deposited over the entire surface of the semiconductor substrate 300 to fill the opening with the buried oxide film 311.

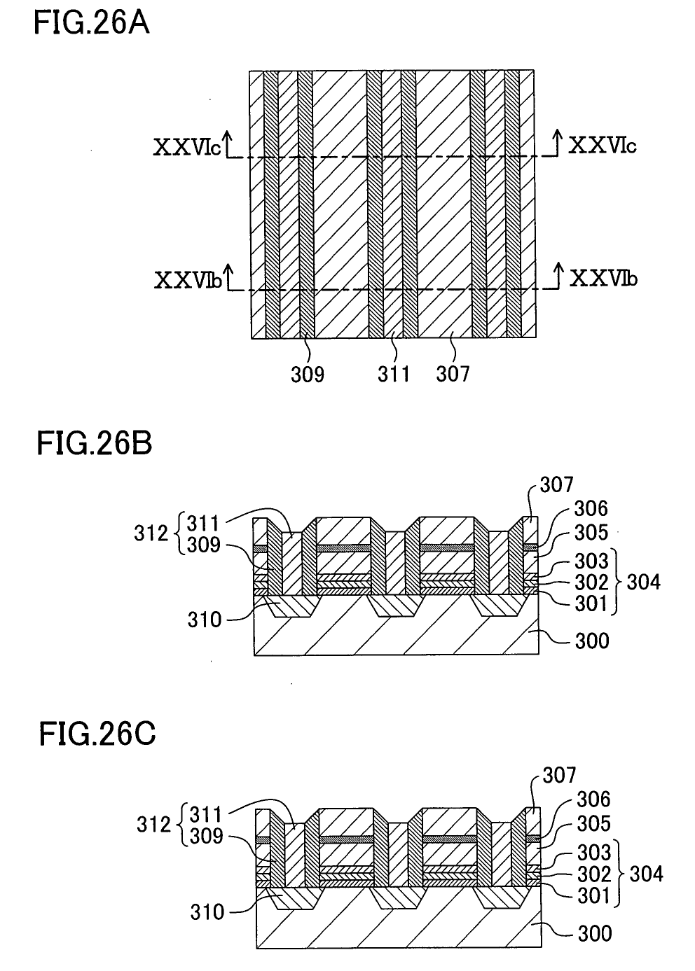

As shown in FIGS. 26A to 26C, the buried oxide film 311 is polished by CMP to expose the bit line formation film 307. Thereby, the insulating film 312 on the bit line is formed which is composed of the implantation offset film 309 and the buried oxide film 311.

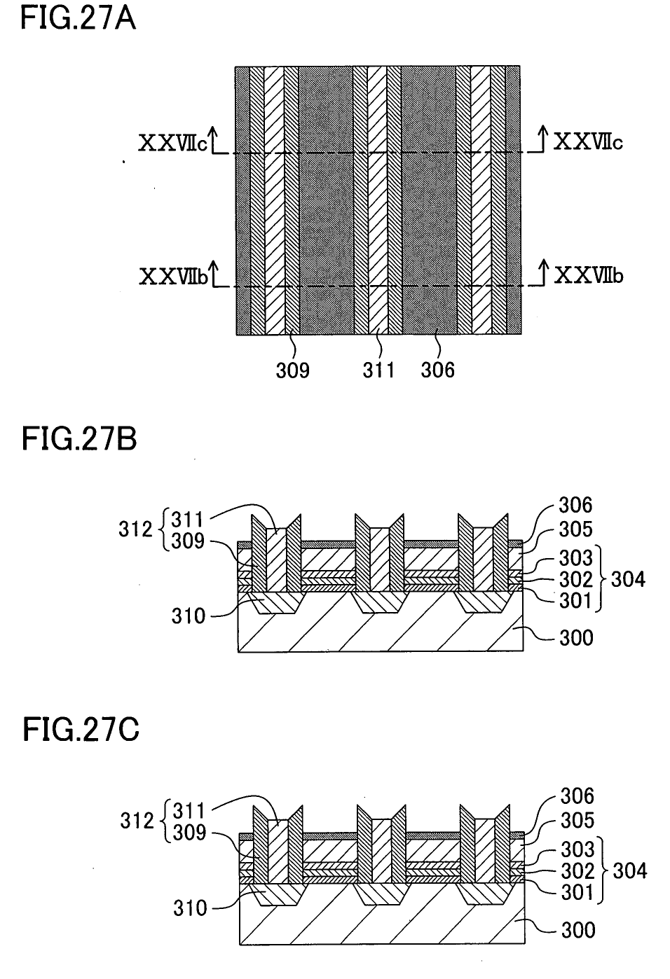

Next, as shown in FIGS. 27A to 27C, the bit line formation film 307 is removed.

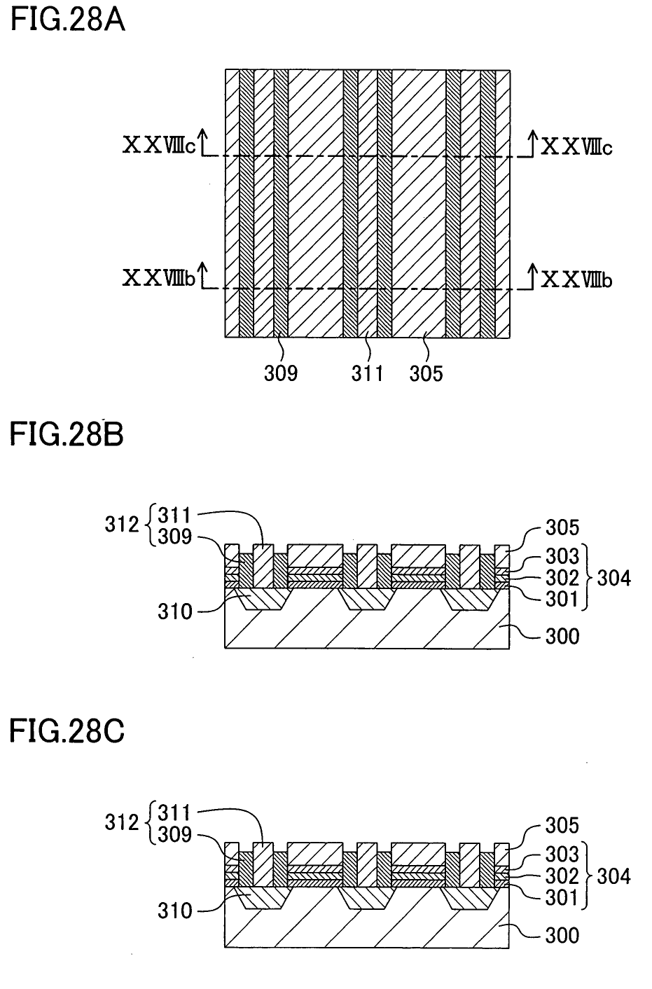

Subsequently, as shown in FIGS. 28A to 28C, by performing wet etching with, for example, a BHF solution, the buffer layer 306 is removed to expose the first gate electrode film 305. During this process, the implantation offset film 309 and the buried oxide film 311 are also etched to form the convex-shaped insulating film 312 on the bit line.

In this process, in the case of employing a BHF solution, the etching rate of the implantation offset film 309 is greater than that of the buried oxide film 311, and the etching rate ratio thereof to the buried oxide film 311 is 3.5. Thereby, in the step shown in FIG. 28, the implantation offset film 309 is etched significantly, while the buried oxide film 311 resists being etched. Therefore, the thickness difference between the implantation offset film 309 and the buried oxide film 311 becomes wide, and thus the convex-shaped insulating film 312 on the bit line can be formed. Note that either of isotropic etching and anisotropic etching may be used in the fabrication method of the second embodiment. In addition, dry etching may be used instead of wet etching, and alternatively wet etching and dry etching may be used in combination.

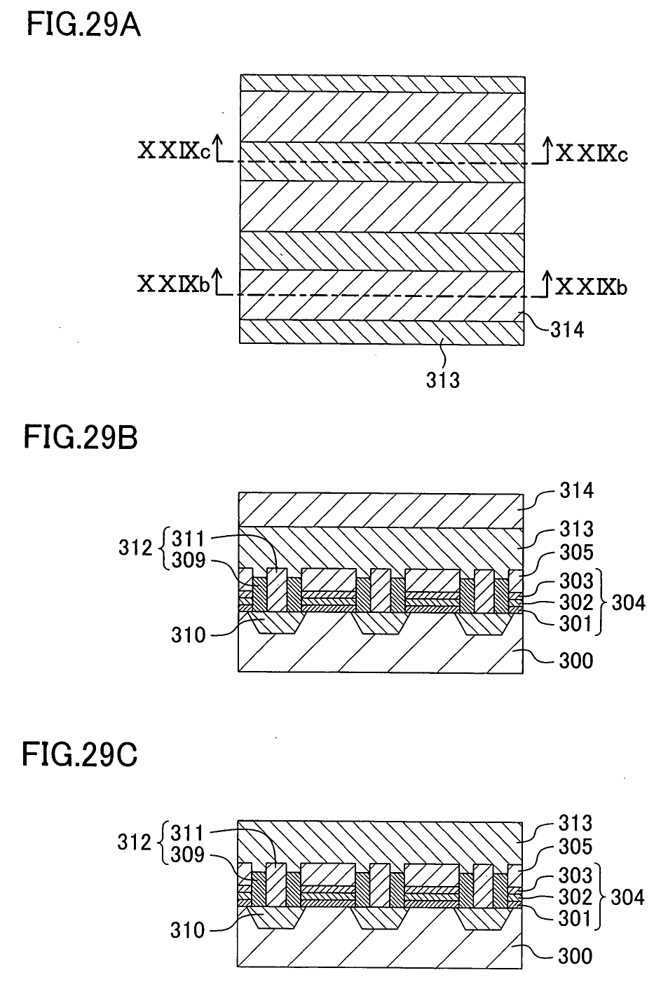

Subsequently, as shown in FIGS. 29A to 29C, the second gate electrode film 313 made of polycrystalline silicon or the like is deposited over the entire surface of the semiconductor substrate 300. Thereafter, on the second gate electrode film 313, a sixth mask 314 provided with a groove extending in the row direction is formed by a lithography technique.

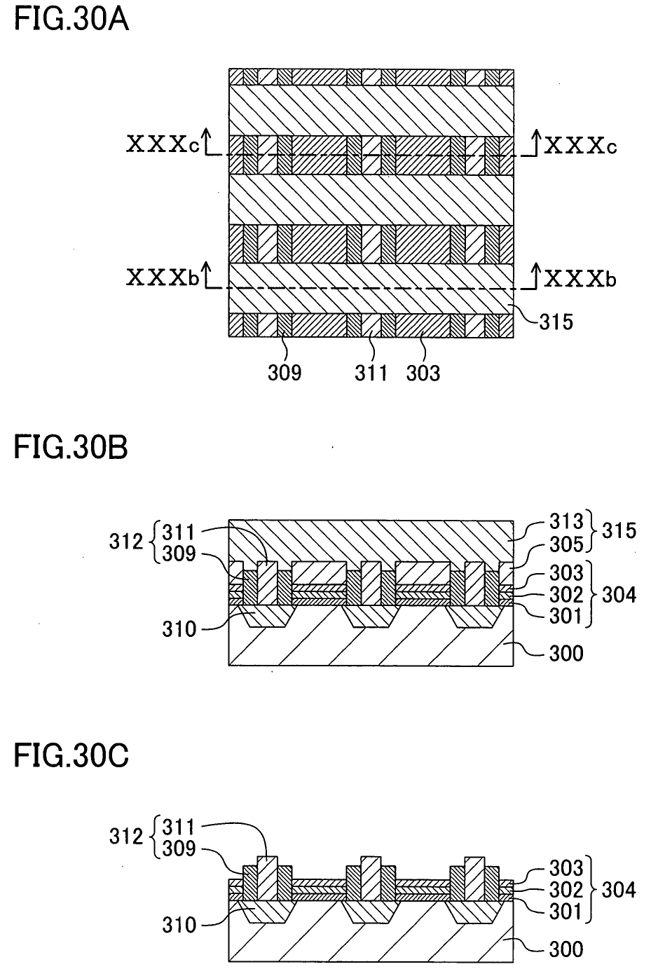

Finally, as shown in FIGS. 30A to 30C, portions of the first gate electrode film 305 and the second gate electrode film 313 are etched away using the sixth mask 314 to form the word line 315 composed of the first gate electrode film 305 and the second gate electrode film 313. Then, the sixth mask 314 is removed by ashing or the like.

In this structure, since the insulating film 312 on the bit line is formed in a convex shape in the step shown in FIG. 28, the level difference is reduced between the both ends of the insulating film 312 in the row direction and the top surface of the charge trapping layer 304. Thus, the first gate electrode film 305 can be etched away relatively easily, and a residue of the first gate electrode film 305 can be prevented from appearing after the etching.

Thereafter, a metal interconnect formation process, a protective film formation process, and a bonding pad formation process are carried out. However, their description is omitted herein. By the process steps described above, the nonvolatile semiconductor memory device according to the second embodiment can be fabricated.

As described above, in the method for fabricating a nonvolatile semiconductor memory device according to the second embodiment, the insulating film 312 on the bit line is formed in a convex shape as shown in FIG. 28. Therefore, appearance of a residue of the first gate electrode film 305 can be prevented. This enables fabrication of the nonvolatile semiconductor memory device which is designed to suppress leakage between the word lines. Moreover, since the difference in etching rate is remarkably wide between the implantation offset film 309 and the buried oxide film 311 both constituting the insulating film 312 on the bit line, the etching condition can be derived relatively easily in the etching step shown in FIG. 28.

### Third Embodiment

Hereinafter, a nonvolatile semiconductor memory device and its fabrication method according to a third embodiment of the present invention will be described with reference to the accompanying drawings.

### —Structure of Nonvolatile Semiconductor Memory Device—

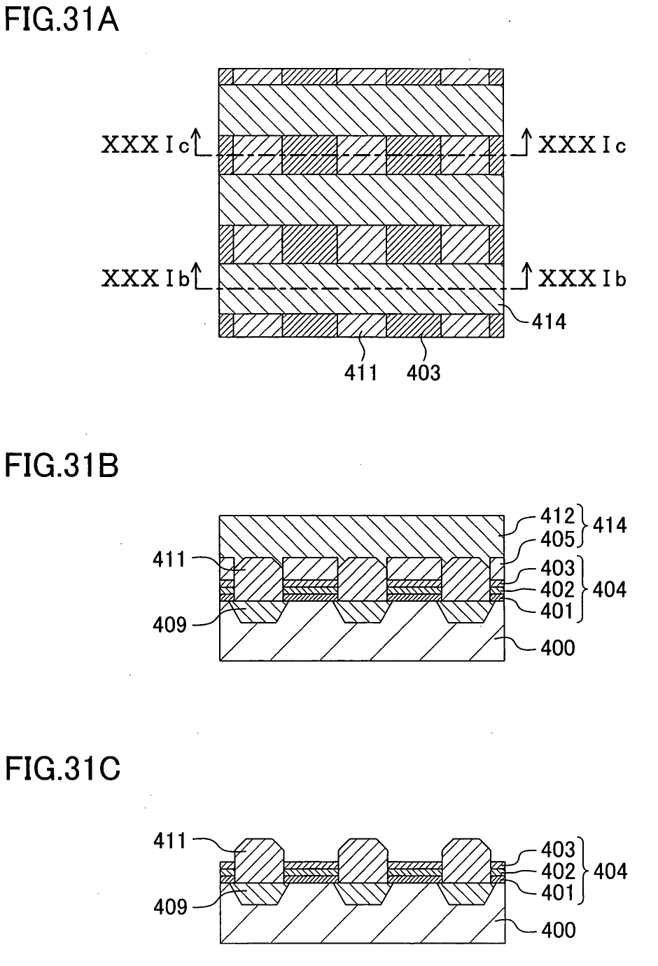

First, the structure of the nonvolatile semiconductor memory device according to the third embodiment will be described in detail using FIGS. 31A to 31C. FIG. 31A is a top view showing the structure of the nonvolatile semiconductor memory device according to the third embodiment. FIG. 31B is a sectional view taken along the line XXXIb-XXXIb shown in FIG. 31A, and FIG. 31C is a sectional view taken along the line XXXIc-XXXIc shown in FIG. 31A.

Referring to FIGS. 31A to 31C, the nonvolatile semiconductor memory device according to the third embodiment includes: a semiconductor substrate 400; a plurality of diffusion-layer bit lines 409; an insulating film 411 on the bit line; a charge trapping layer 404; a first gate electrode film 405; and a second gate electrode film 412. The diffusion-layer bit lines 409 extend in the column direction in the semiconductor substrate 400. The insulating film 411 on the bit line is formed on each of the diffusion-layer bit lines 409, and extends in the column direction. The charge trapping layer 404 is formed on a region of the semiconductor substrate 400 positioned between the diffusion-layer bit lines 409 as seen from a horizontal plane. The first gate electrode film 405 is formed on the charge trapping layer 404. The second gate electrode film 412 is formed on the first gate electrode film 405 and the insulating film 411 on the bit line, and extends in the row direction. The charge trapping layer 404 has a multilayer structure made by sequentially stacking, from bottom to top, a first silicon oxide film 401, a silicon nitride film 402, and a second silicon oxide film 403.

In this structure, the insulating film 411 on the bit line is made of a single oxide film of HDP or the like, and has a tapered shape in which both ends thereof have a smaller thickness than the center portion. The first gate electrode film 405 and the second gate electrode film 412 constitute a word line 414. Note that since operations of each memory of the nonvolatile memory device according to the third embodiment are identical to those of the nonvolatile semiconductor memory device of the first embodiment, their description is omitted herein.

### —Method for Fabricating Nonvolatile Semiconductor Memory Device—

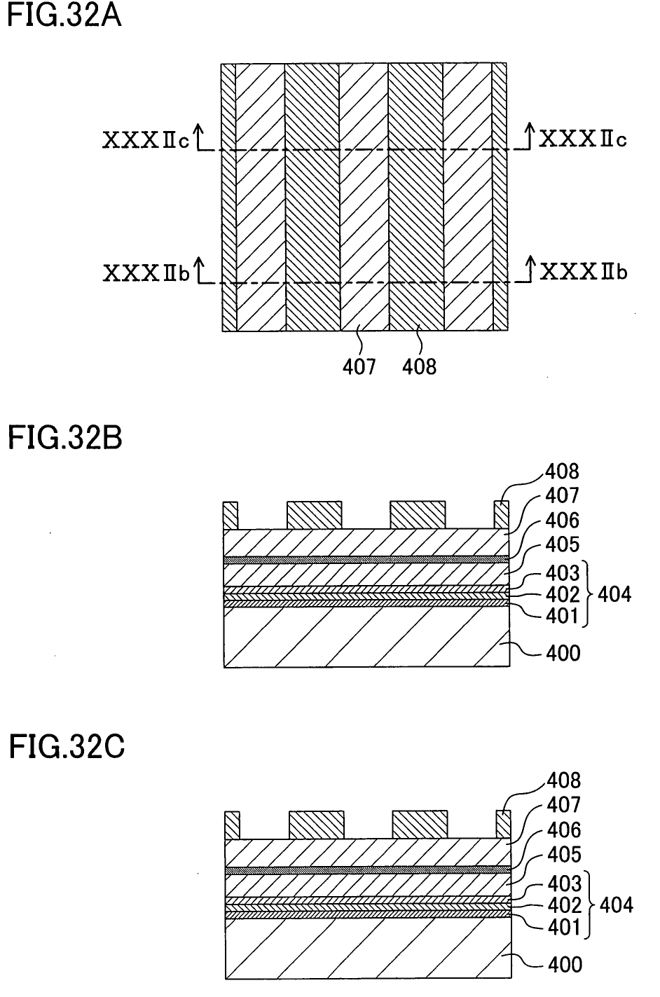

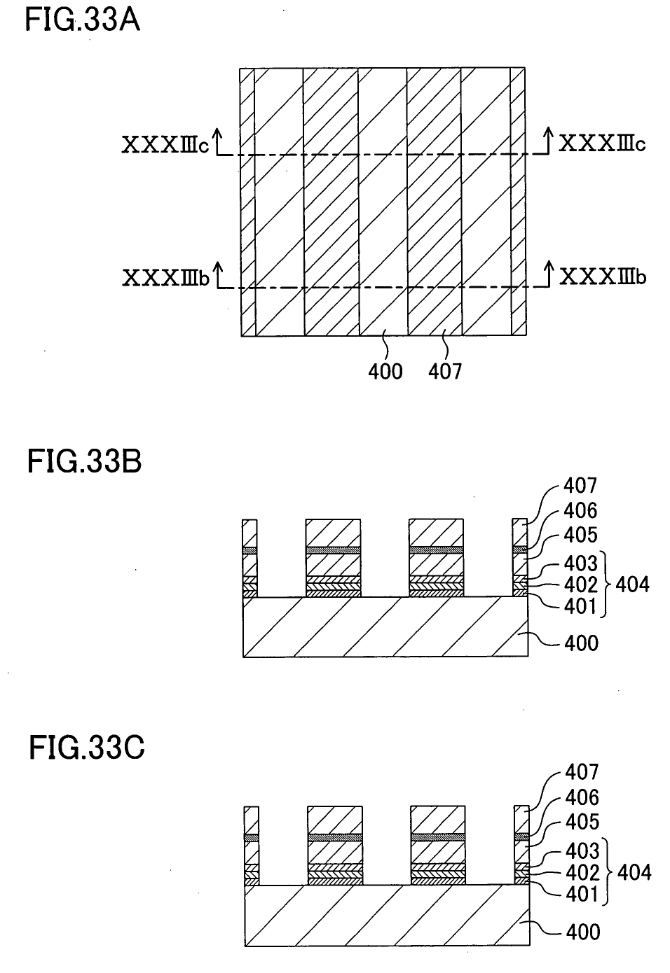

First, a method for fabricating a nonvolatile semiconductor memory device according to the third embodiment will be described with reference to FIGS. 32 to 41. In this description, the following figures accompanied with the reference character “A” are top views showing the fabrication method of the third embodiment, and the following figures accompanied with the reference character “B” or “C” are sectional views showing the fabrication method of the third embodiment. Since the process steps shown in FIGS. 32 and 33 are carried out in the same manner as the process steps of the above-mentioned fabrication method of the first embodiment (FIGS. 2 and 3), their description will be simplified.

Referring to FIGS. 32A to 32C, first, the charge trapping layer 404 composed of the first silicon oxide film 401, the silicon nitride film 402, and the second silicon oxide film 403, the first gate electrode film 405 of polycrystalline silicon or the like, a buffer layer 406 made of a TEOS film or the like, a bit line formation film 407 made of SiN or the like, and a seventh mask 408 provided with a groove extending in the column direction are sequentially formed on the semiconductor substrate 400. As the formation method of the respective layers, the same method as the fabrication method of the first embodiment can be employed.

Next, as shown in FIGS. 33A to 33C, using the seventh mask 408, the bit line formation film 407, the buffer layer 406, the first gate electrode film 405, and the charge trapping layer 404 are selectively etched away to form an opening extending in the column direction and reaching the semiconductor substrate 400. Thereafter, the seventh mask 408 is removed by ashing or the like.

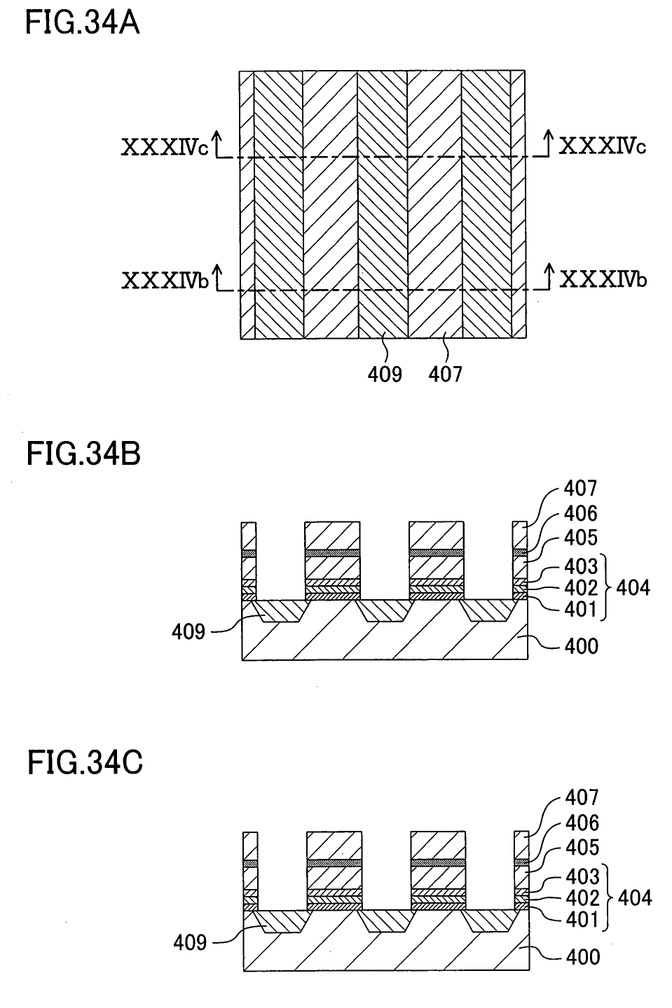

Subsequently, as shown in FIGS. 34A to 34C, from the opening into a predetermined region of the semiconductor substrate 400, boron ions are implanted as a pocket implantation, and arsenic ions are implanted as a source/drain implantation. Thereafter, for example, a thermal treatment at 900° C. for 60 minutes is performed thereon in a nitrogen atmosphere to form the diffusion-layer bit line 409 functioning as source and drain regions of the memory cell transistor.

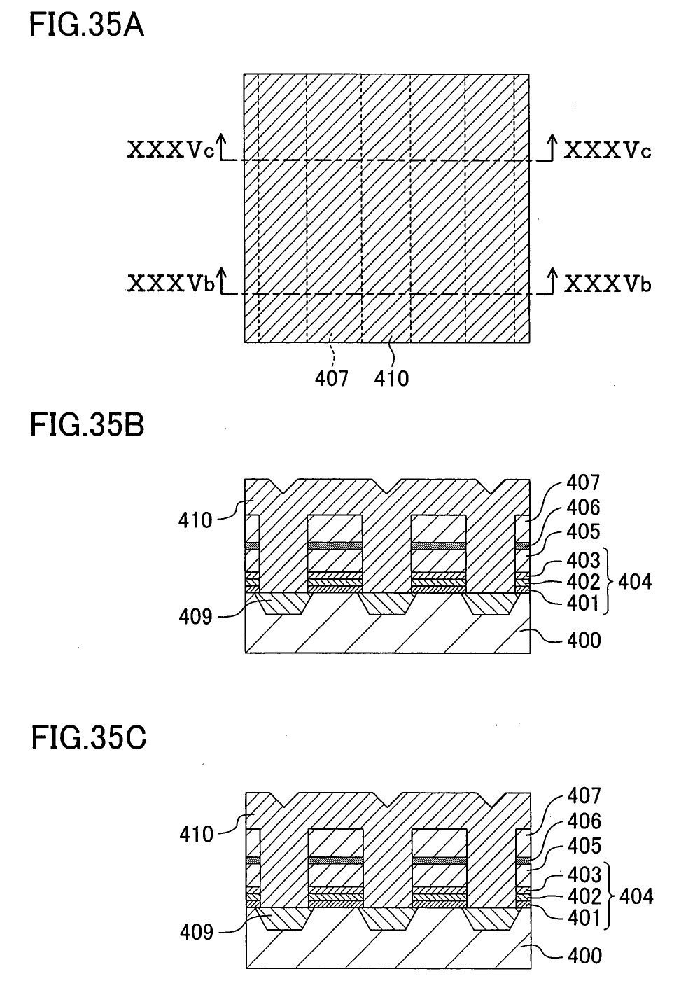

Next, as shown in FIGS. 35A to 35C, a buried oxide film 410 of, for example, HDP is deposited over the entire surface of the semiconductor substrate 400 to fill the opening with the buried oxide film 410.

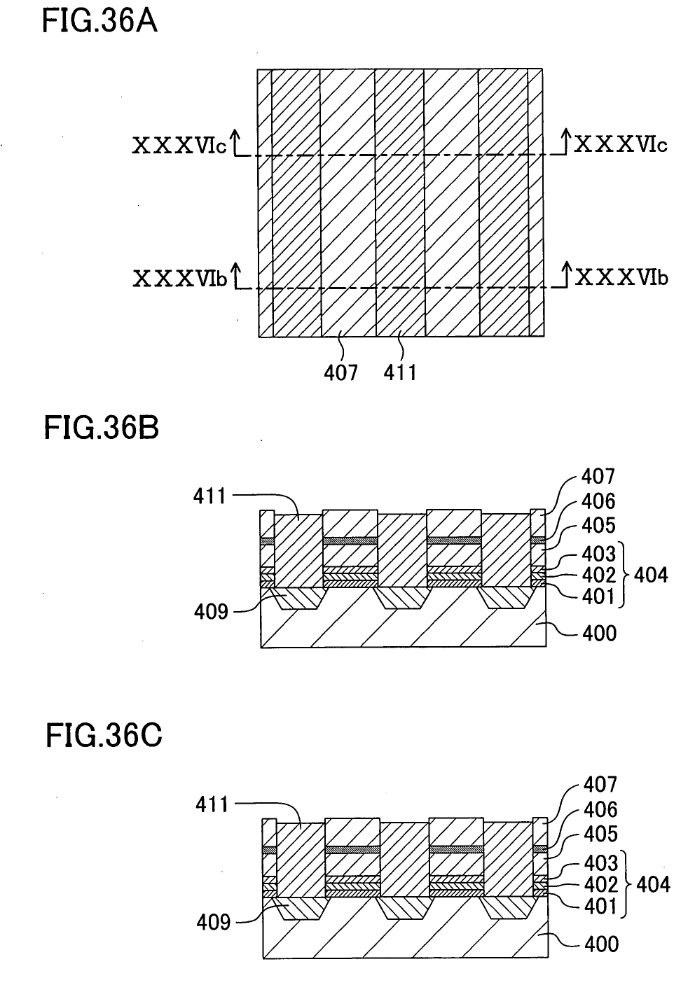

As shown in FIGS. 36A to 36C, the buried oxide film 410 is polished by CMP to expose the bit line formation film 407. Thereby, the insulating film 411 on the bit line is formed.

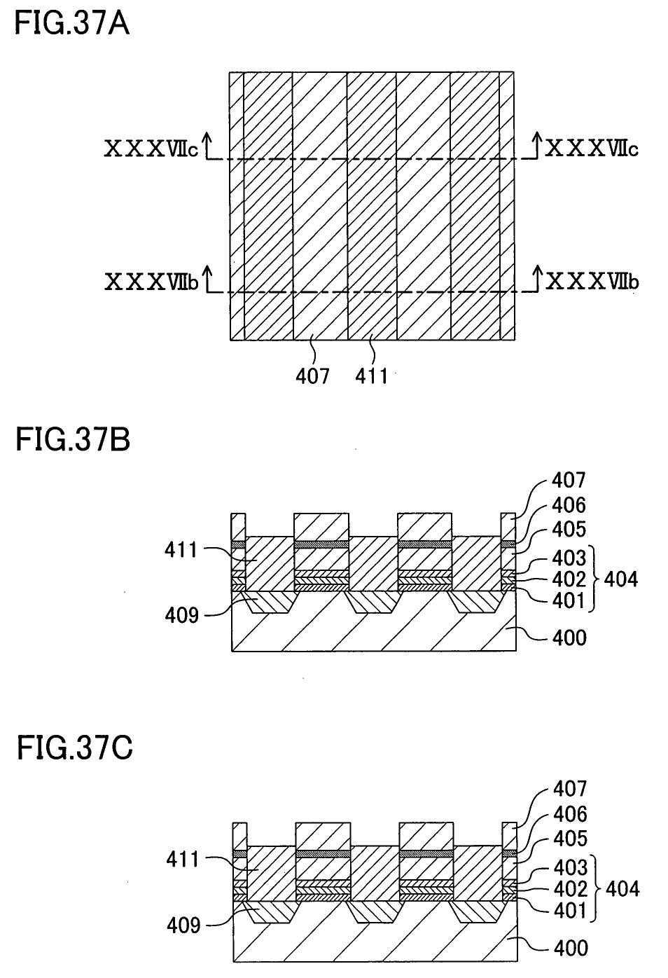

Next, as shown in FIGS. 37A to 37C, by performing wet etching with a BHF solution or the like, the insulating film 411 on the bit line is etched for level adjustment so that the top surface of the insulating film 411 on the bit line has a higher level than the top surface of the buffer layer 406 by, for example, 5 to 20 nm inclusive. In this etching, a publicly-known dry etching may be employed instead of the wet etching, and alternatively wet etching and dry etching may be employed in combination. Note that this level adjustment step is not essential, and it is also acceptable to eliminate this step.

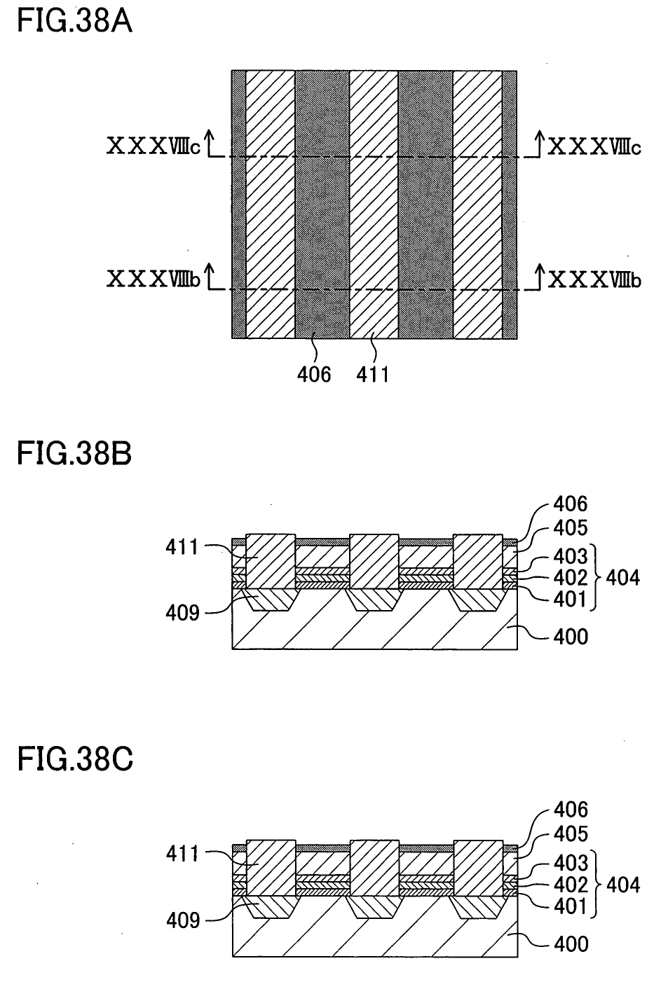

Then, as shown in FIGS. 38A to 38C, the bit line formation film 407 is removed.

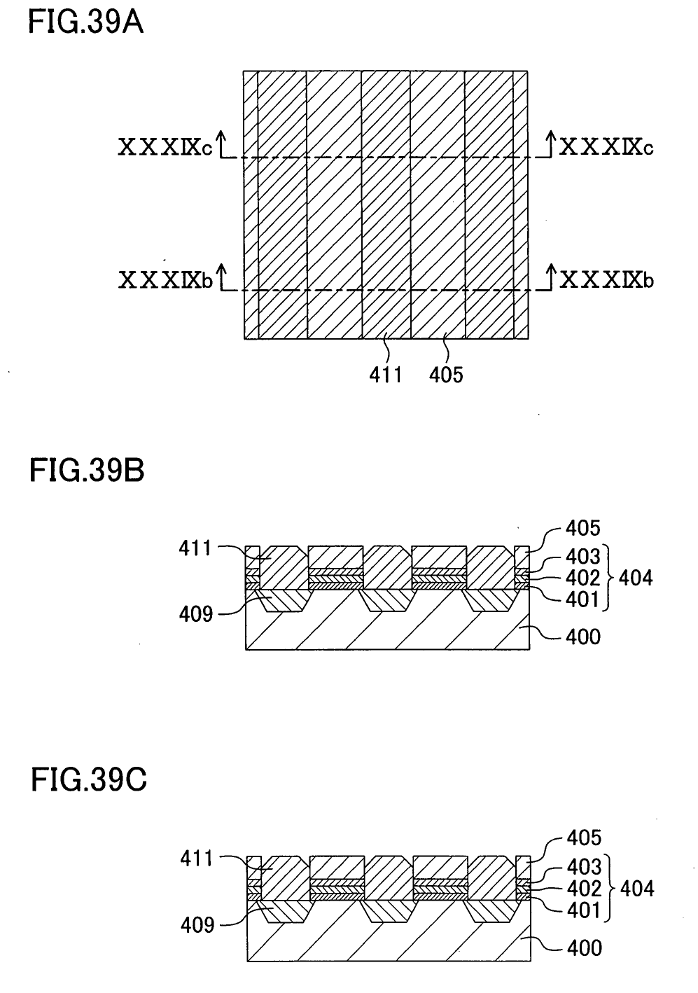

Subsequently, as shown in FIGS. 39A to 39C, by performing isotropic wet etching with, for example, a BHF solution, the buffer layer 406 is removed to expose the first gate electrode film 405. During this process, the insulating film 411 on the bit line is also etched into a tapered shape. Furthermore, by the level adjustment step (FIG. 37) having carried out, the top surfaces of the first gate electrode film 405 and the insulating film 411 on the bit line have almost the same level.

Preferably, isotropic etching is performed in the step shown in FIG. 39. If the etching employed is isotropic etching, dry etching may be used instead of wet etching and alternatively these etchings may be used in combination. As shown above, by performing isotropic etching, the insulating film 411 on the bit line is etched not only from the top surface but also from the side surface. Thus, the tapered insulating film 411 on the bit line can be formed whose thickness is smaller at the both ends than at the center portion.

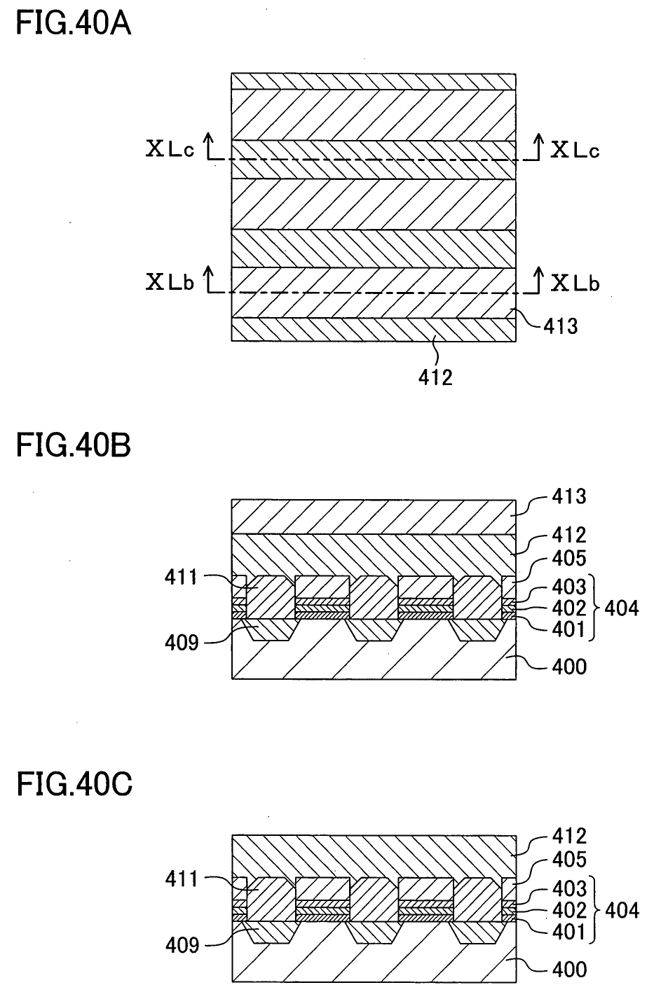

Subsequently, as shown in FIGS. 40A to 40C, the second gate electrode film 412 made of polycrystalline silicon or the like is deposited over the entire surface of the semiconductor substrate 400. Thereafter, on the second gate electrode film 412, an eighth mask 413 provided with a groove extending in the row direction is formed by a lithography technique.

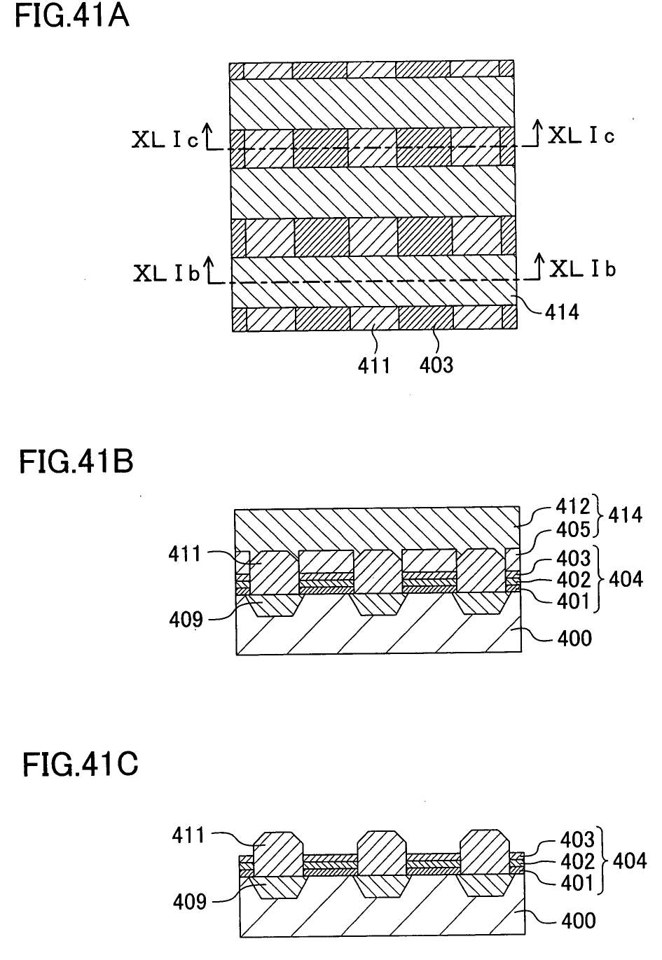

Finally, as shown in FIGS. 41A to 41C, portions of the first gate electrode film 405 and the second gate electrode film 412 are etched away using the eighth mask 413 to form the word line 414 composed of the first gate electrode film 405 and the second gate electrode film 412. Then, the eighth mask 413 is removed by ashing or the like.

In this structure, since the insulating film 411 on the bit line is formed in a tapered shape in the step shown in FIG. 39, the level difference is reduced between the both ends of the insulating film 411 on the bit line in the row direction and the top surface of the charge trapping layer 404. Thus, the first gate electrode film 405 can be etched away relatively easily, and a residue of the first gate electrode film 405 can be prevented from appearing after the etching.

Thereafter, a metal interconnect formation process, a protective film formation process, and a bonding pad formation process are carried out. However, their description is omitted herein. By the process steps described above, the nonvolatile semiconductor memory device according to the third embodiment can be fabricated.

As described above, in the method for fabricating a nonvolatile semiconductor memory device according to the third embodiment, the insulating film 411 on the bit line is formed in a tapered shape as shown in FIG. 39. Therefore, appearance of a residue of the first gate electrode film 405 can be prevented. This enables fabrication of the nonvolatile semiconductor memory device which is designed to suppress leakage between the word lines.

Moreover, in the nonvolatile semiconductor memory device according to the third embodiment, the insulating film 411 on the bit line is made of a single film. Therefore, it is sufficient that in the step shown in FIG. 35, the opening having a smaller aspect ratio than that in the above-mentioned fabrication method of the first embodiment is filled with the buried oxide film 410. This provides the insulating film 411 on the bit line having a good gap-filling capability even for a miniaturized nonvolatile semiconductor memory device. In addition, an insulating film on a bit line made of multiple films may cause, at the interface between the films, a decrease in breakdown voltage or degradation of the films, but the insulating film 411 on the bit line made of a single film can prevent this trouble. Thus, the insulating film 411 on the bit line can be formed which has an excellent breakdown voltage for insulating the word line 414 and the diffusion-layer bit line 409.

### Fourth Embodiment

Hereinafter, a nonvolatile semiconductor memory device and its fabrication method according to a fourth embodiment of the present invention will be described with reference to the accompanying drawings.

### —Structure of Nonvolatile Semiconductor Memory Device—

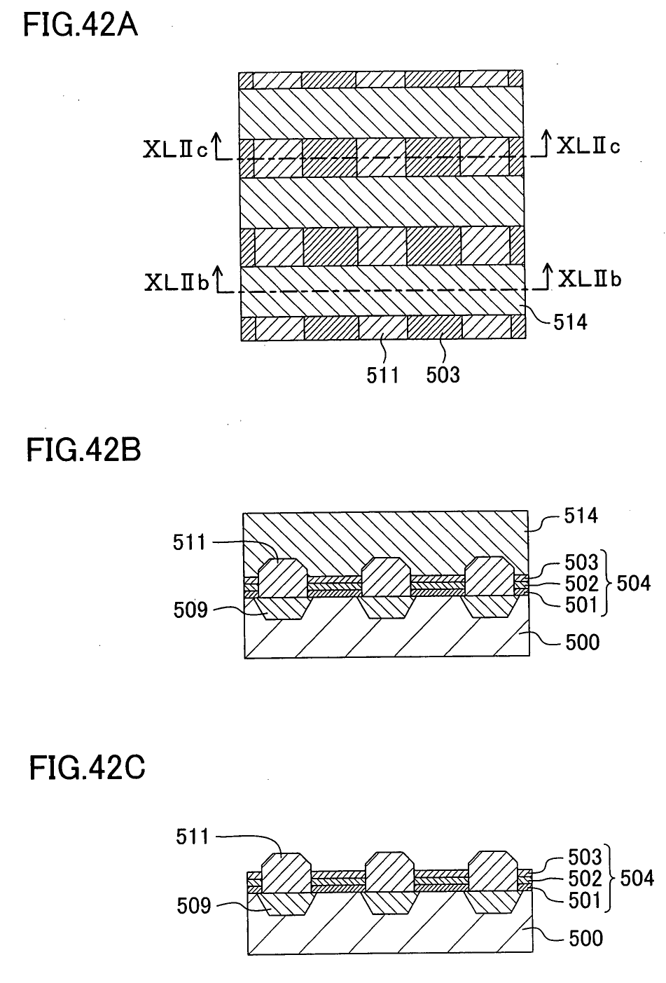

First, the structure of the nonvolatile semiconductor memory device according to the fourth embodiment will be described in detail using FIGS. 42A to 42C. FIG. 42A is a top view showing the structure of the nonvolatile semiconductor memory device according to the fourth embodiment. FIG. 42B is a sectional view taken along the line XLIIb-XLIIb shown in FIG. 42A, and FIG. 42C is a sectional view taken along the line XLIIc-XLIIc shown in FIG. 42A.

Referring to FIGS. 42A to 42C, the nonvolatile semiconductor memory device according to the fourth embodiment includes: a semiconductor substrate 500; a plurality of diffusion-layer bit lines 509; an insulating film 511 on the bit line; a charge trapping layer 504; and a word line 514. The diffusion-layer bit lines 509 extend in the column direction in the semiconductor substrate 500. The insulating film 511 on the bit line is formed on each of the diffusion-layer bit lines 509, and extends in the column direction. The charge trapping layer 504 is formed on a region of the semiconductor substrate 500 positioned between the diffusion-layer bit lines 509 as seen from a horizontal plane. The word line 514 is formed on the charge trapping layer 504 and the insulating film 511 on the bit line, and extends in the row direction. The charge trapping layer 504 has a multilayer structure made by sequentially stacking, from bottom to top, a first silicon oxide film 501, a silicon nitride film 502, and a second silicon oxide film 503.

In this structure, the insulating film 511 on the bit line is made of a single oxide film of HDP or the like, and has a tapered shape in which both ends thereof have a smaller thickness than the center portion.

Also, in this structure, the word line 514 is made of a single-layer film, and three-dimensionally intersects with the diffusion-layer bit line 509. Note that since operations of each memory of the nonvolatile memory device according to the fourth embodiment are identical to those of the nonvolatile semiconductor memory device of the first embodiment, their description is omitted herein.

### —Method for Fabricating Nonvolatile Semiconductor Memory Device—

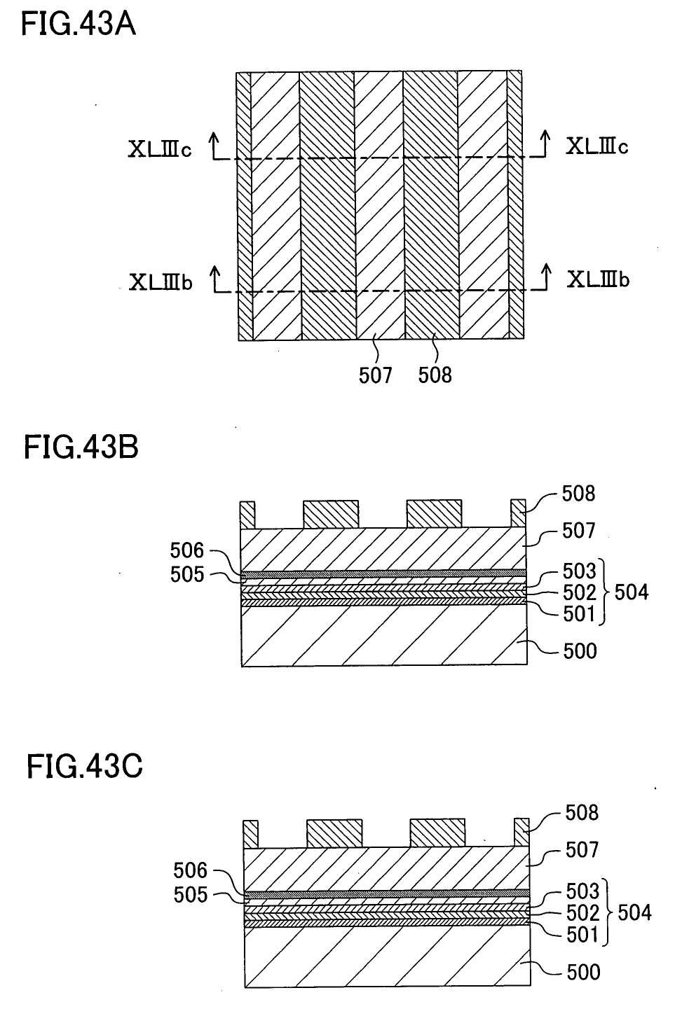

First, a first method for fabricating a nonvolatile semiconductor memory device according to the fourth embodiment will be described with reference to FIGS. 43 to 53. In this description, the following figures accompanied with the reference character “A” are top views showing the first fabrication method of the fourth embodiment, and the following figures accompanied with the reference character “B” or “C” are sectional views showing the first fabrication method of the fourth embodiment.

Referring to FIGS. 43A to 43C, first, the charge trapping layer 504 composed of the first silicon oxide film 501, the silicon nitride film 502, and the second silicon oxide film 503 is formed on the semiconductor substrate 500. Thereafter, a sacrifice silicon nitride film 505, a sacrifice silicon oxide film 506, and a bit line formation film 507 made of polycrystalline silicon or the like are sequentially formed on the charge trapping layer 504. The sacrifice silicon nitride film 505 is formed by a low pressure CVD method to have a thickness of, for example, 10 nm, and the sacrifice silicon oxide film 506 is formed by a CVD method to have a thickness of, for example, 10 nm. The bit line formation film 507 is formed by a low pressure CVD method to have a thickness of, for example, 100 nm. After formation of the bit line formation film 507, by a lithography technique, a ninth mask 508 provided with a groove extending in the column direction is formed on the bit line formation film 507.

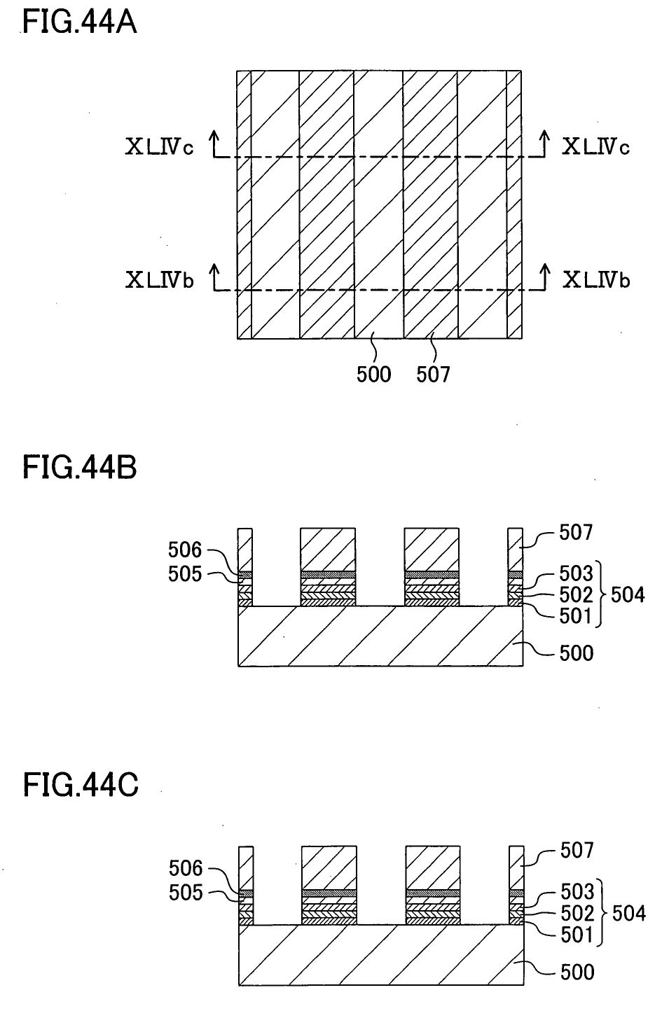

Next, as shown in FIGS. 44A to 44C, using the ninth mask 508, the bit line formation film 507, the sacrifice silicon oxide film 506, the sacrifice silicon nitride film 505, and the charge trapping layer 504 are selectively etched away to form an opening extending in the column direction and reaching the semiconductor substrate 500. Thereafter, the ninth mask 508 is removed by ashing or the like.

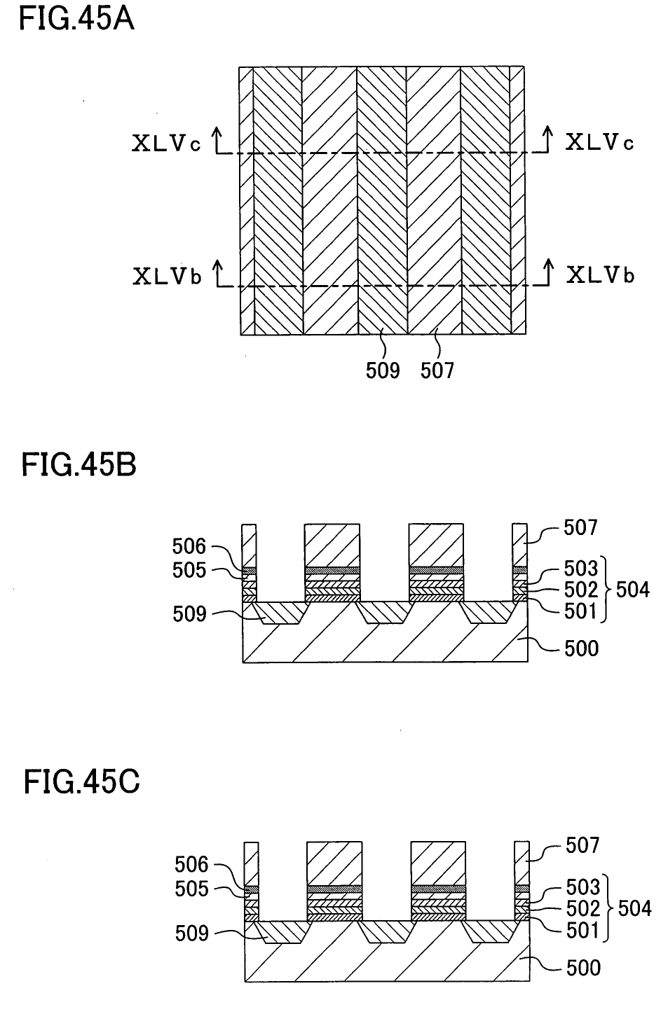

Subsequently, as shown in FIGS. 45A to 45C, from the opening into a predetermined region of the semiconductor substrate 500, boron ions are implanted as a pocket implantation on the condition of an acceleration voltage of 50 keV and a dose of 3×10¹³/cm², and arsenic ions are implanted as a source/drain implantation on the condition of an acceleration voltage of 20 keV and a dose of 2×10¹⁵/cm². Thereafter, for example, a thermal treatment at 900° C. for 60 minutes is performed thereon in a nitrogen atmosphere to form the diffusion-layer bit line 509 functioning as source and drain regions of the memory cell transistor.

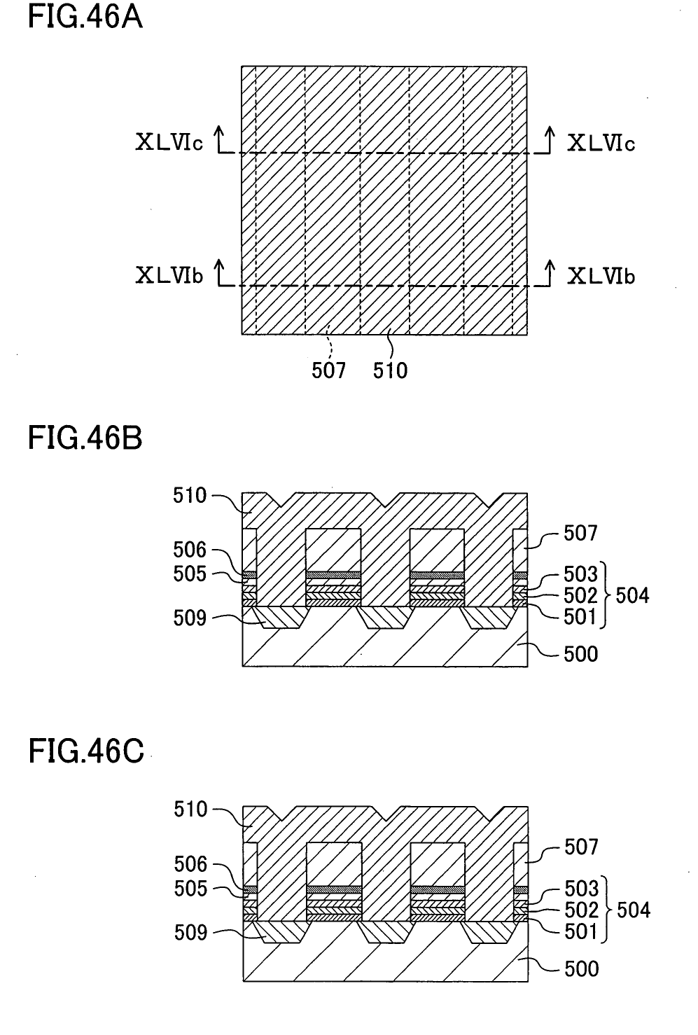

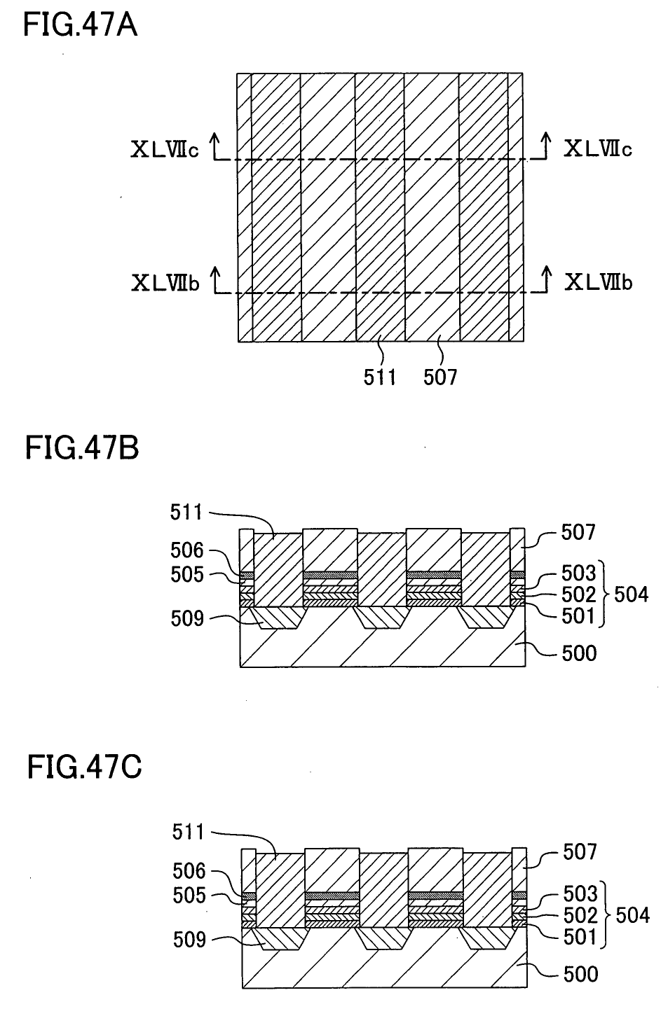

Next, as shown in FIGS. 46A to 46C, a buried oxide film 510 of, for example, HDP is deposited over the entire surface of the semiconductor substrate 500 to fill the opening with the buried oxide film 510. Then, as shown in FIGS. 47A to 47C, the buried oxide film 510 is polished by CMP to expose the bit line formation film 507. Thereby, the insulating film 511 on the bit line is formed.

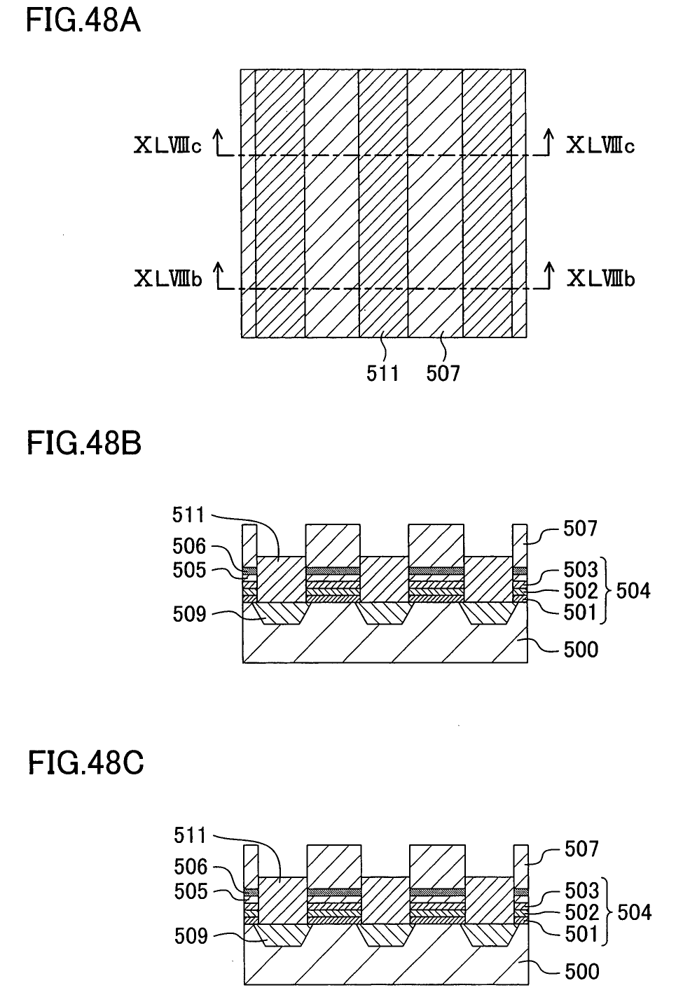

As shown in FIGS. 48A to 48C, by performing wet etching with a BHF solution or the like, the insulating film 511 on the bit line is etched so that the top surface of the insulating film 511 on the bit line has a higher level than the top surface of the sacrifice silicon oxide film 506 by, for example, 5 to 20 nm inclusive. In this etching, a publicly-known dry etching may be employed instead of the wet etching, and alternatively wet etching and dry etching may be employed in combination. Note that this level adjustment step is not essential, and it is also acceptable to eliminate this step.

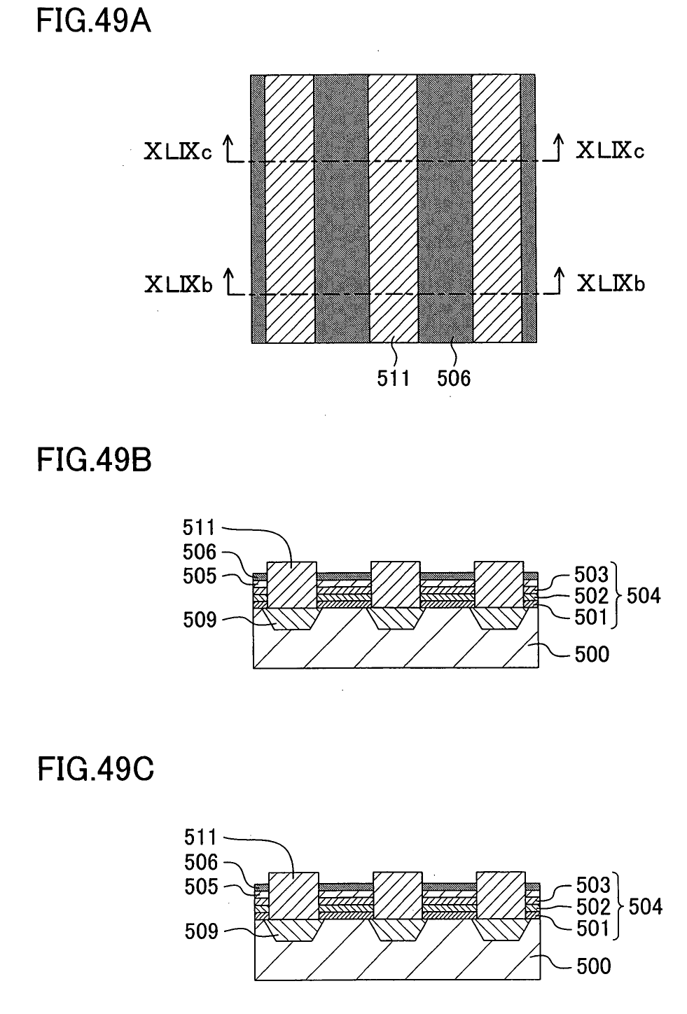

Then, as shown in FIGS. 49A to 49C, the bit line formation film 507 is removed.

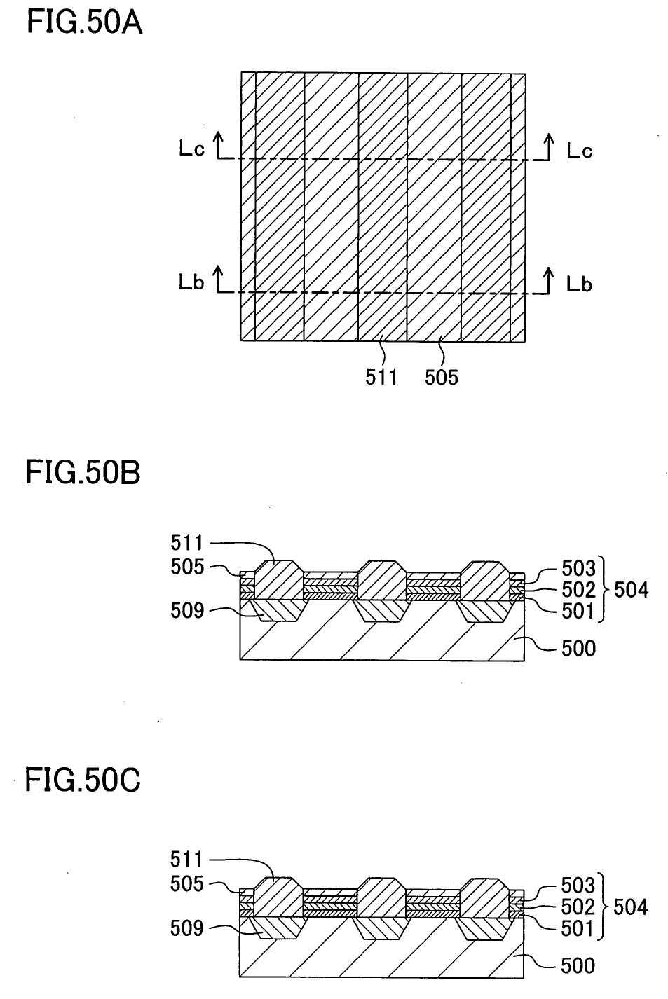

Subsequently, as shown in FIGS. 50A to 50C, by performing isotropic wet etching with, for example, a BHF solution, the sacrifice silicon oxide film 506 is removed to expose the sacrifice silicon nitride film 505. During this process, the insulating film 511 on the bit line is also etched into a tapered shape.

Preferably, isotropic etching is performed in the step shown in FIG. 50. If the etching employed is isotropic etching, dry etching may be used instead of wet etching and alternatively these etchings may be used in combination. As shown above, by performing isotropic etching, the insulating film 511 on the bit line is etched not only from the top surface but also from the side surface. Thus, the tapered insulating film 511 on the bit line can be formed whose thickness is smaller at the both ends than at the center portion.

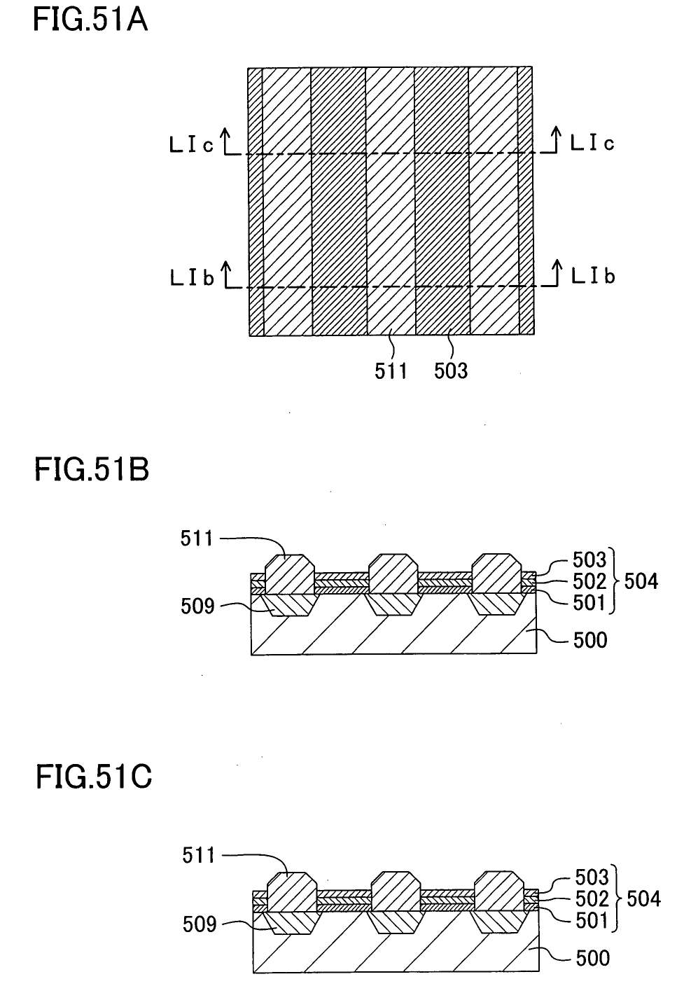

Next, as shown in FIGS. 51A to 51C, the sacrifice silicon nitride film 505 is removed.

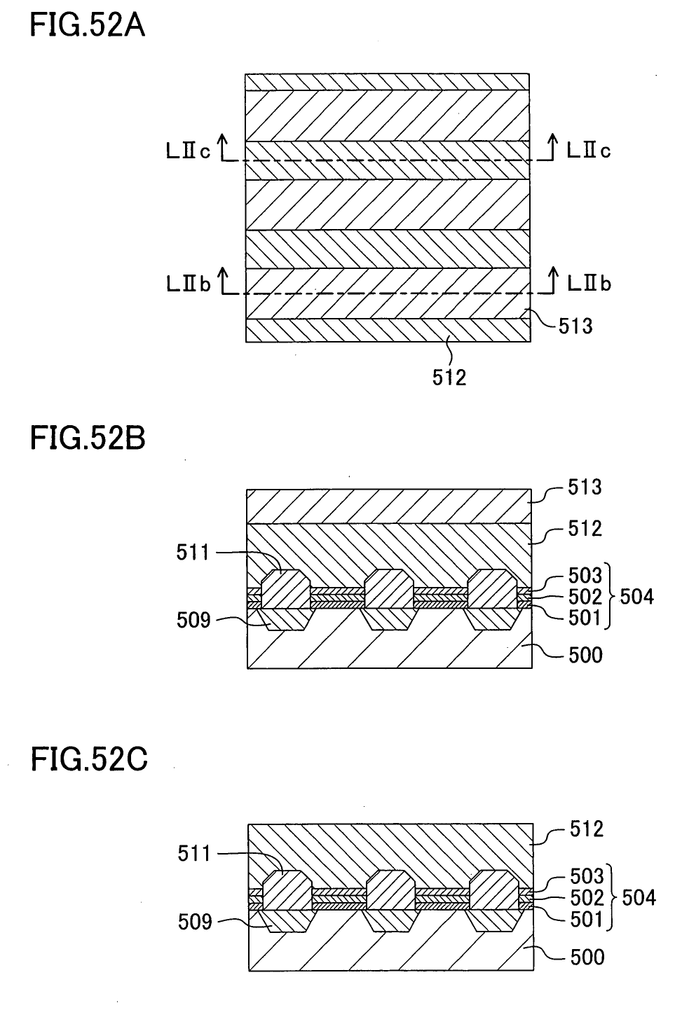

Subsequently, as shown in FIGS. 52A to 52C, a gate electrode film 512 made of polycrystalline silicon or the like is deposited over the entire surface of the semiconductor substrate 500. Thereafter, on the gate electrode film 512, a tenth mask 513 provided with a groove extending in the row direction is formed by a lithography technique.

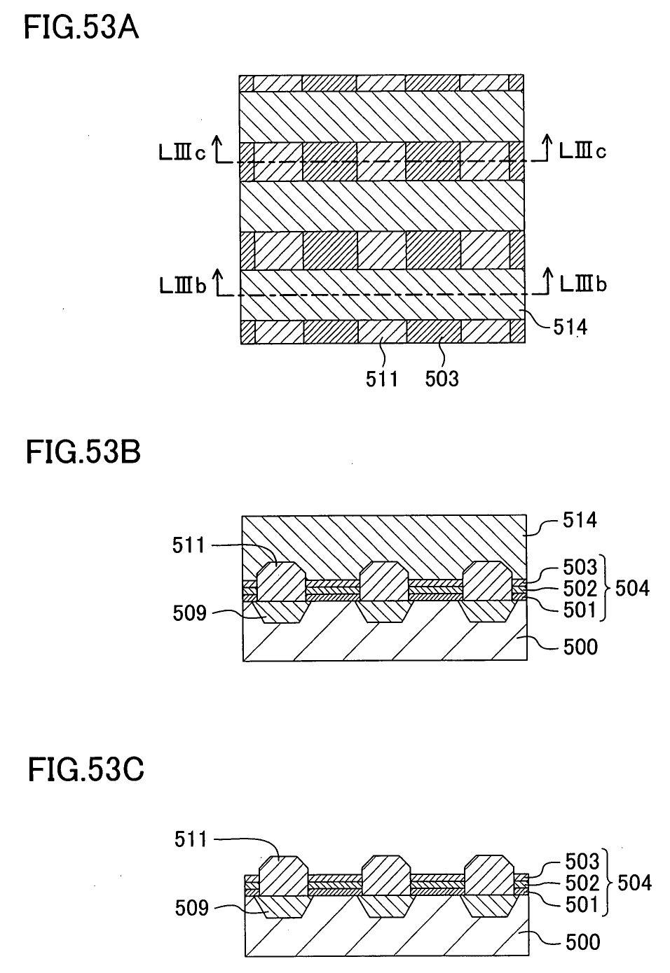

Finally, as shown in FIGS. 53A to 53C, a portion of the gate electrode film 512 is selectively etched away using the tenth mask 513 to form the word line 514 extending in the row direction. Then, the tenth mask 513 is removed by ashing or the like.

In this structure, since the insulating film 511 on the bit line is formed in a tapered shape in the step shown in FIG. 50, the level difference is reduced between the both ends of the insulating film 511 on the bit line in the row direction and the top surface of the charge trapping layer 504. Thus, the gate electrode film 512 can be etched away relatively easily, and a residue of the gate electrode film 512 can be prevented from appearing after the etching.

Thereafter, a metal interconnect formation process, a protective film formation process, and a bonding pad formation process are carried out. However, their description is omitted herein. By the process steps described above, the nonvolatile semiconductor memory device according to the fourth embodiment can be fabricated.

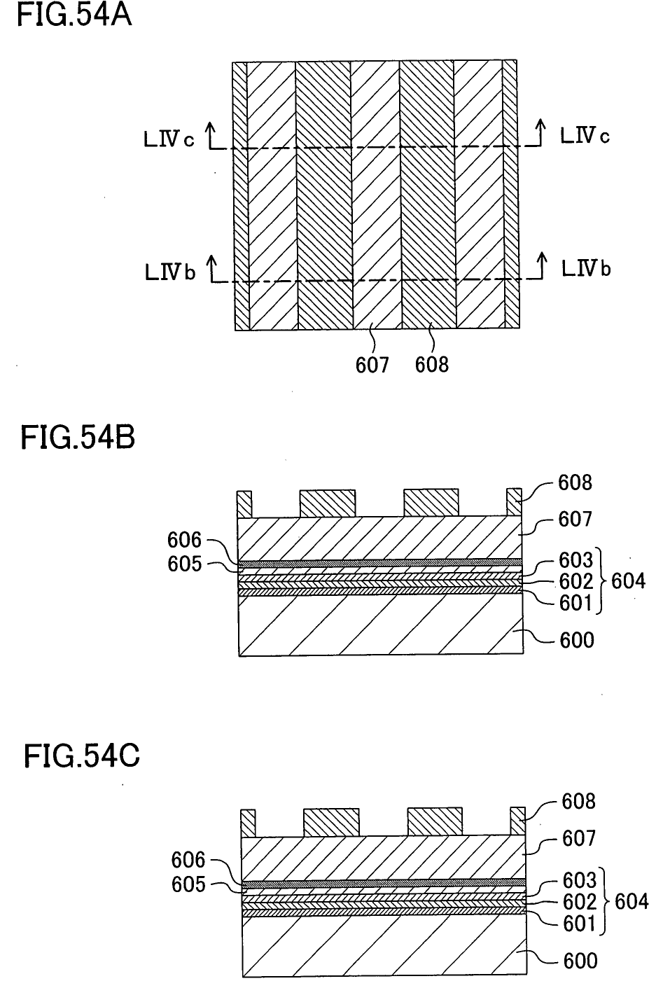

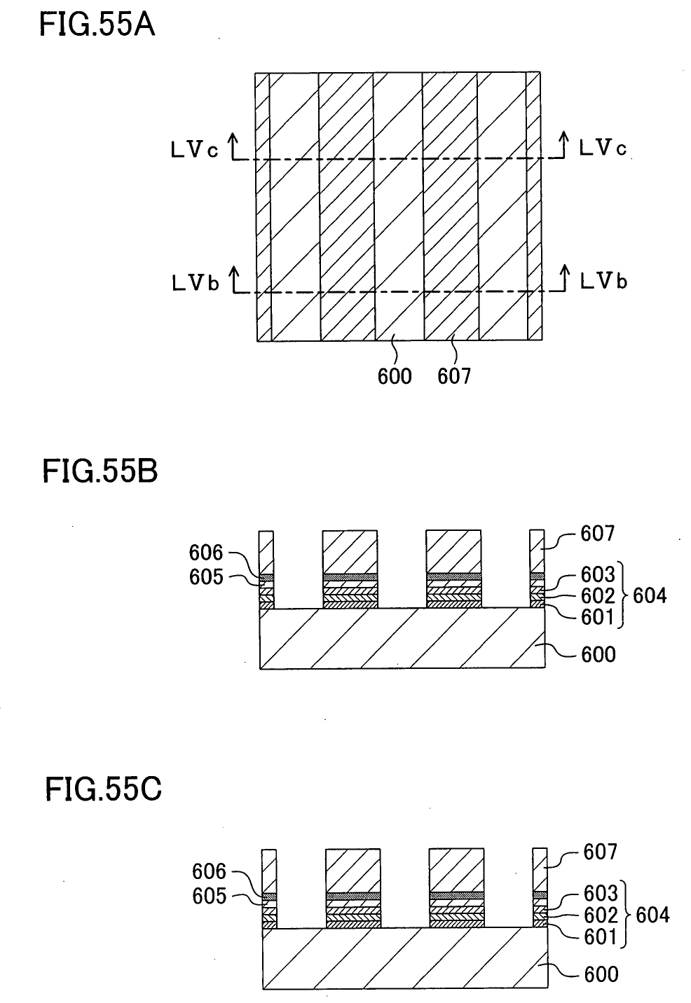

Next, a second method for fabricating a nonvolatile semiconductor memory device according to the fourth embodiment will be described with reference to FIGS. 54 to 64. In this description, the following figures accompanied with the reference character “A” are top views showing the second fabrication method of the fourth embodiment, and the following figures accompanied with the reference character “B” or “C” are sectional views showing the second fabrication method of the fourth embodiment. Note that the process steps shown in FIGS. 54 and 55 are carried out in the same manner as the process steps of the above-mentioned first fabrication method of the fourth embodiment shown in FIGS. 43 and 44.

Referring to FIGS. 54A to 54C, first, on a semiconductor substrate 600, a first silicon oxide film 601, a silicon nitride film 602, and a second silicon oxide film 603 are sequentially deposited to form a charge trapping layer 604 composed of these three films. Thereafter, a sacrifice silicon nitride film 605, a sacrifice silicon oxide film 606, and a bit line formation film 607 made of polycrystalline silicon or the like are sequentially formed on the charge trapping layer 604. As the formation method of the respective layers, the same method as the first fabrication method of the fourth embodiment is employed. After formation of the bit line formation film 607, by a lithography technique, an eleventh mask 608 provided with a groove extending in the column direction is formed on the bit line formation film 607.

Next, as shown in FIGS. 55A to 55C, using the eleventh mask 608, the bit line formation film 607, the sacrifice silicon oxide film 606, the sacrifice silicon nitride film 605, and the charge trapping layer 604 are selectively etched away to form an opening extending in the column direction and reaching the semiconductor substrate 600. Thereafter, the eleventh mask 608 is removed by ashing or the like.

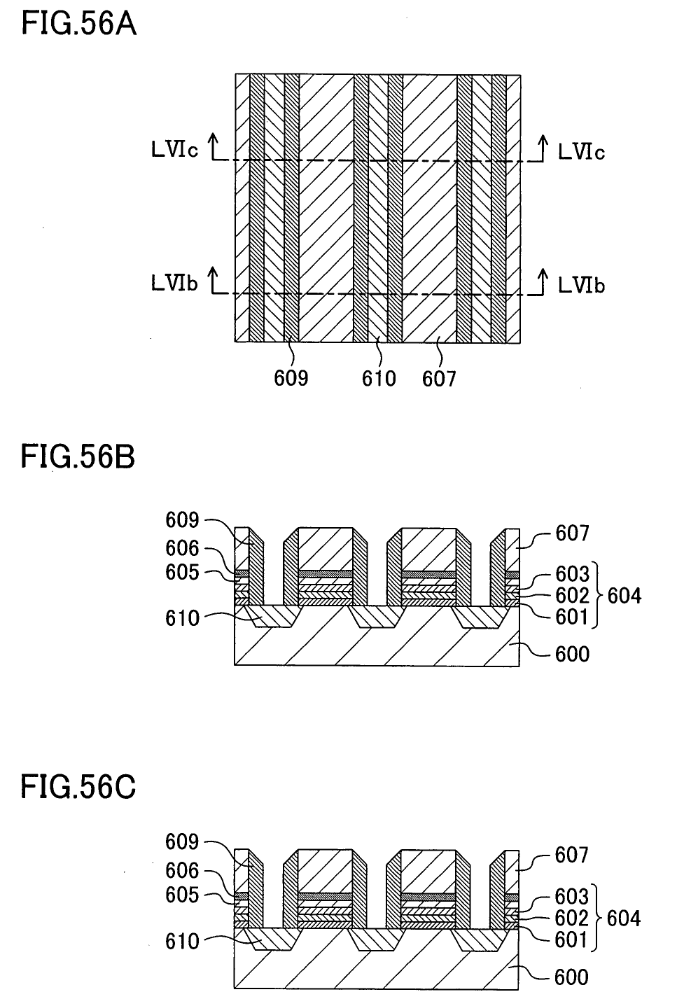

Subsequently, as shown in FIGS. 56A to 56C, by a CVD method, an implantation offset film 609 of silicon nitride (SiN) or the like having a thickness of, for example, 15 nm is formed on an inner side surface of the opening. Then, from the opening into a predetermined region of the semiconductor substrate 600, boron ions are implanted as a pocket implantation on the condition of an acceleration voltage of 50 keV and a dose of 3×10¹³/cm², and arsenic ions are implanted as a source/drain implantation on the condition of an acceleration voltage of 20 keV and a dose of 2×10¹⁵/cm². Thereafter, for example, a thermal treatment at 900° C. for 60 minutes is performed thereon in a nitrogen atmosphere to form a diffusion-layer bit line 610 functioning as source and drain regions of the memory cell transistor.

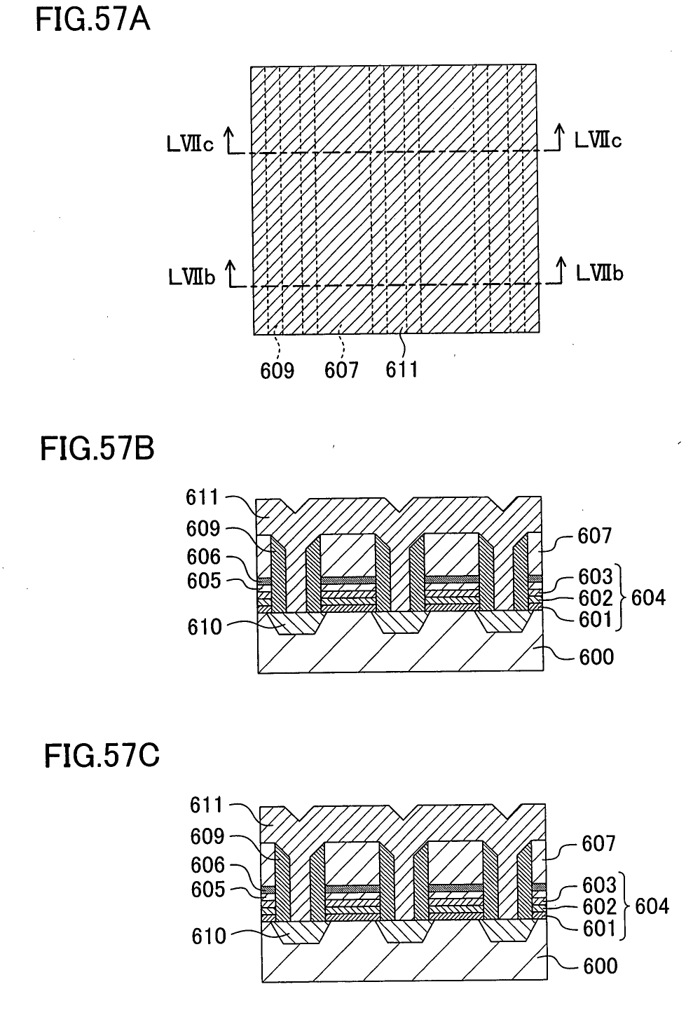

Next, as shown in FIGS. 57A to 57C, a buried oxide film 611 of, for example, HDP is deposited over the entire surface of the semiconductor substrate 600 to fill the opening with the buried oxide film 611.

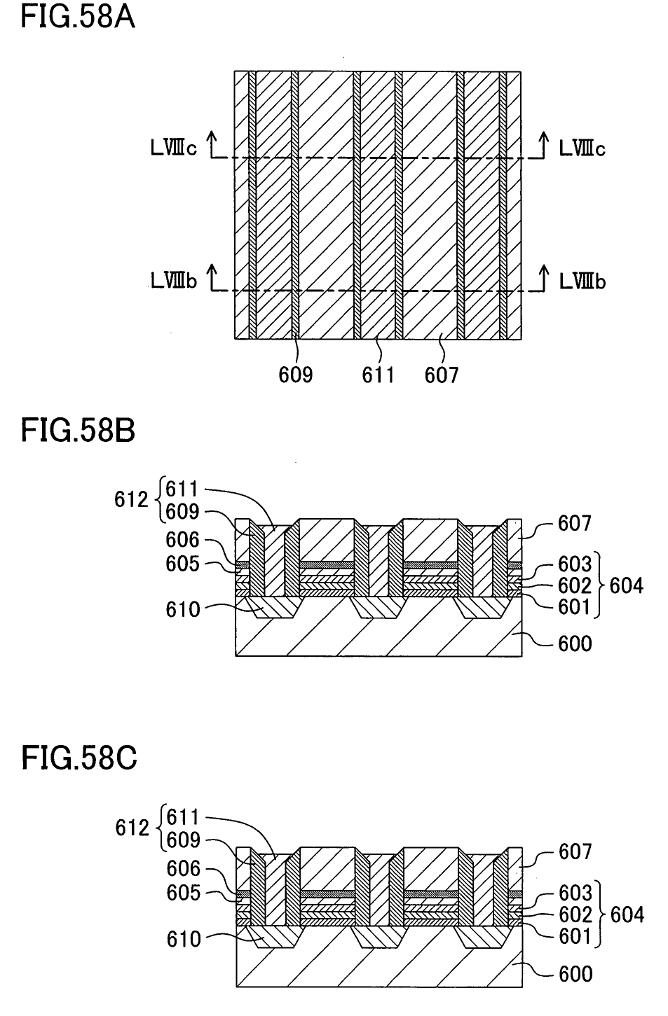

As shown in FIGS. 58A to 58C, the buried oxide film 611 is polished by CMP to expose the bit line formation film 607. Thereby, an insulating film 612 on the bit line is formed which is composed of the implantation offset film 609 and the buried oxide film 611.

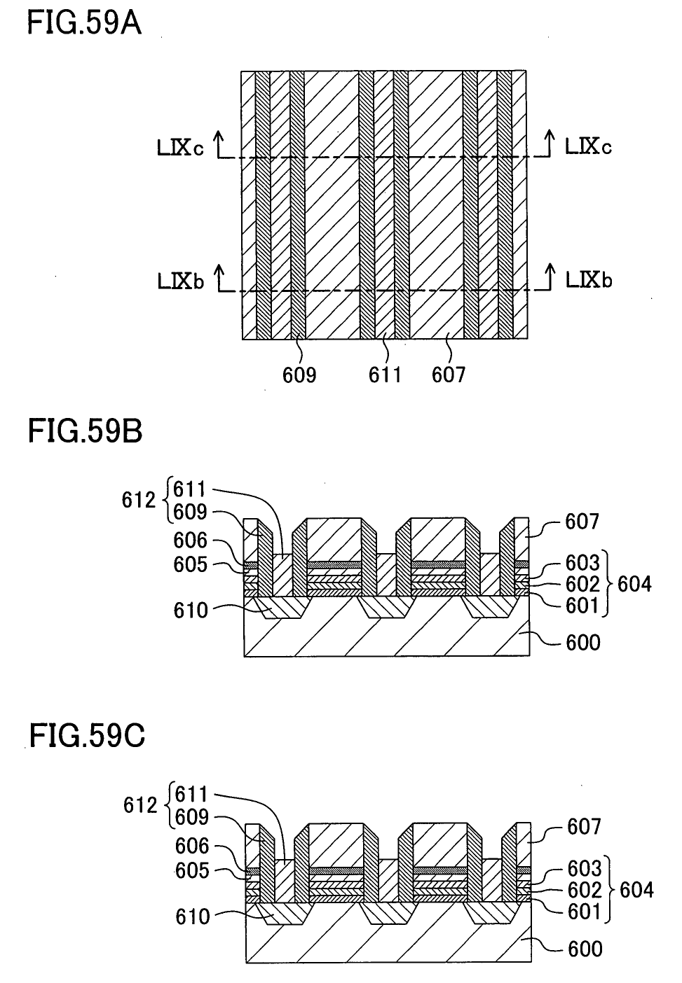

Next, as shown in FIGS. 59A to 59C, by performing wet etching with, for example, a BHF solution, the buried oxide film 611 is etched so that the top surface thereof has a higher level than the top surface of the sacrifice silicon oxide film 606 by, for example, 5 to 20 nm inclusive. In this etching, if the implantation offset film 609 is made of a film resistant to (resisting being etched with) a BHF solution, such as SiN, the implantation offset film 609 and the buried oxide film 611 are not etched simultaneously. Note that a publicly-known dry etching may be employed instead of the wet etching, and alternatively wet etching and dry etching may be employed in combination. In addition, this level adjustment step is not essential, and it is also acceptable to eliminate this step.

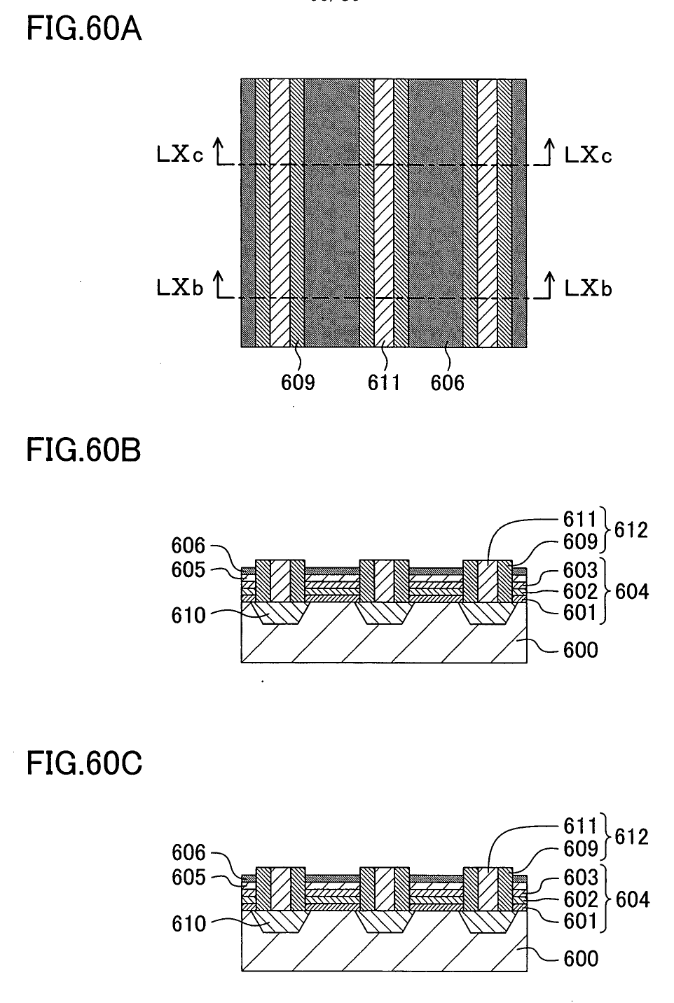

Subsequently, as shown in FIGS. 60A to 60C, the upper portion of the implantation offset film 609 and the bit line formation film 607 are removed. In this step, the implantation offset film 609 is etched so that the top surface thereof has almost the same level as the top surface of the buried oxide film 611.

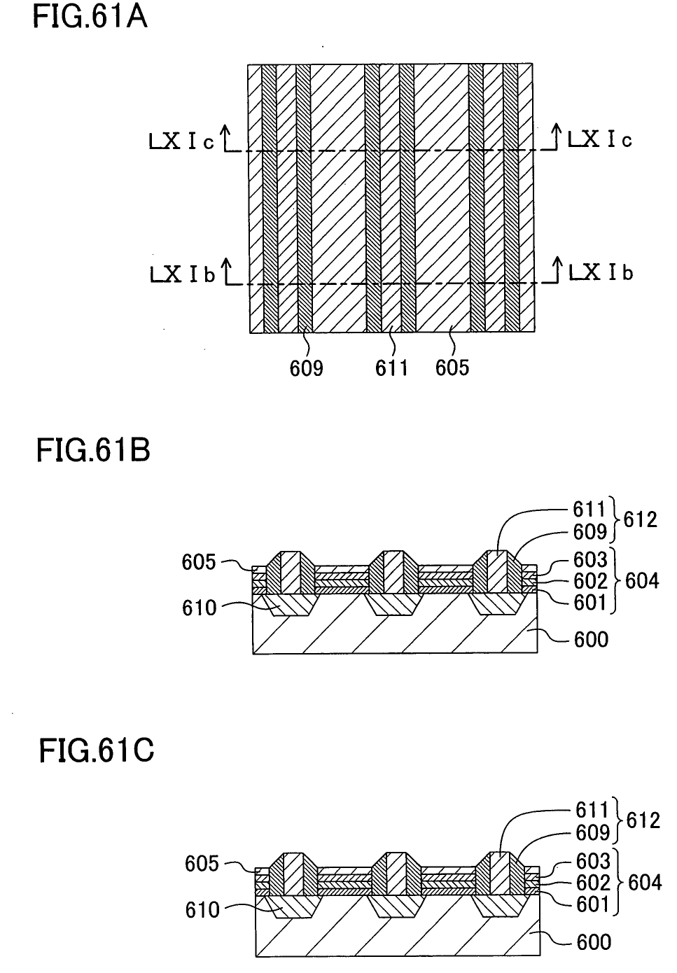

As shown in FIGS. 61A to 61C, by performing isotropic wet etching with, for example, a BHF solution, the sacrifice silicon oxide film 606 is removed to expose the sacrifice silicon nitride film 605. During this process, the implantation offset film 609 and the buried oxide film 611 are also etched to form the tapered insulating film 612.

Preferably, isotropic etching is performed in the step shown in FIG. 61. If the etching employed is isotropic etching, dry etching may be used instead of wet etching and alternatively these etchings may be used in combination. As shown above, by performing isotropic etching, the insulating film 612 on the bit line is etched not only from the top surface but also from the side surface. Thus, the tapered insulating film 612 on the bit line can be formed whose thickness is smaller at the both ends than at the center portion.

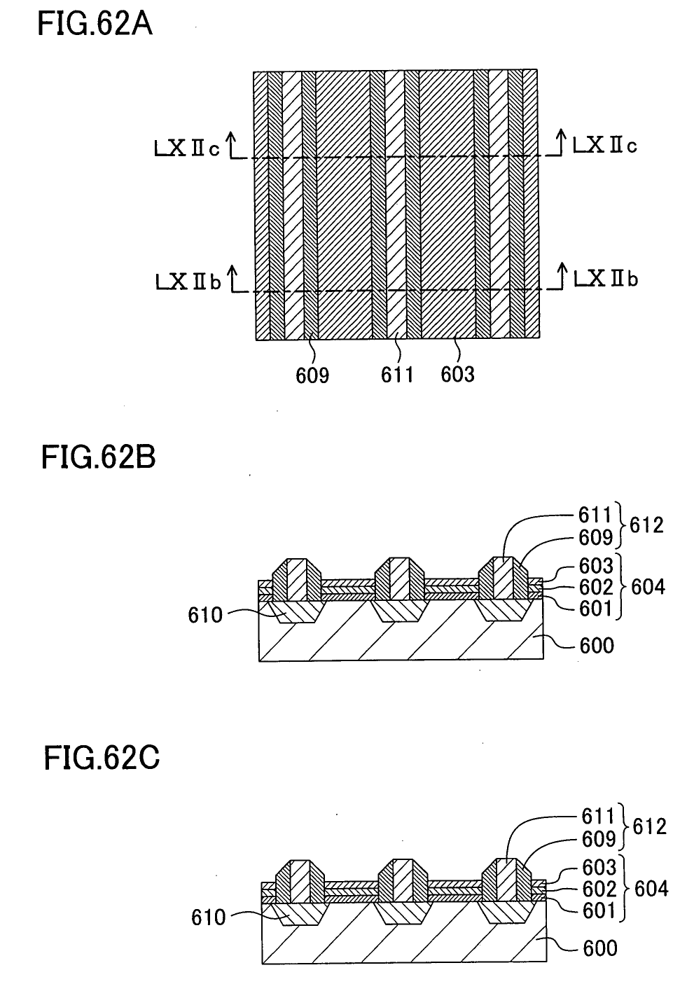

Next, as shown in FIGS. 62A to 62C, the sacrifice silicon nitride film 605 is removed.

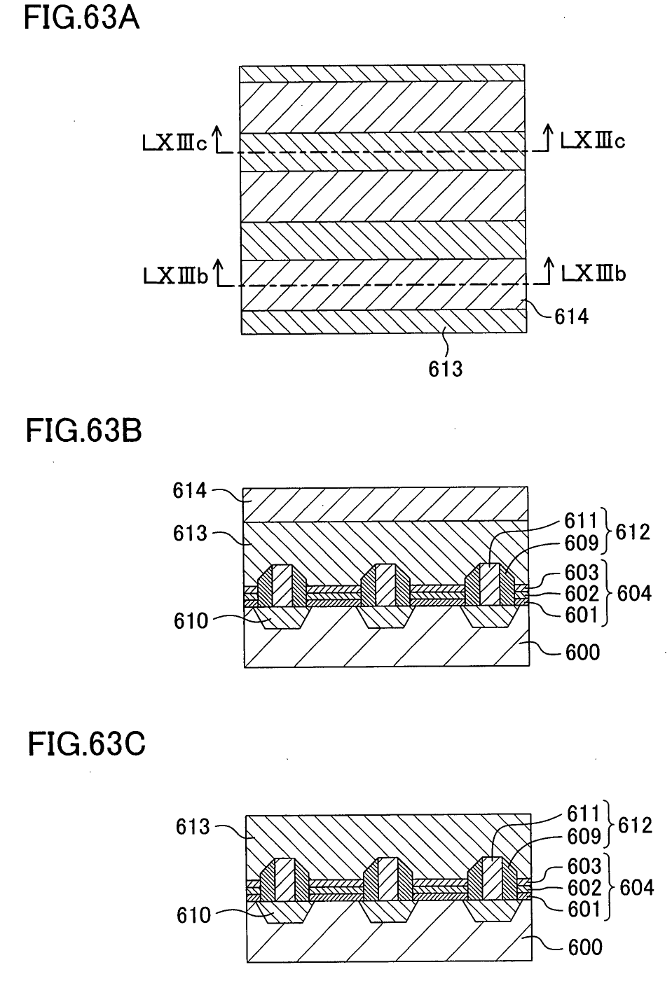

Subsequently, as shown in FIGS. 63A to 63C, a gate electrode film 613 made of polycrystalline silicon or the like is deposited over the entire surface of the semiconductor substrate 600. Thereafter, on the gate electrode film 613, a twelfth mask 614 provided with a groove extending in the row direction is formed by a lithography technique.

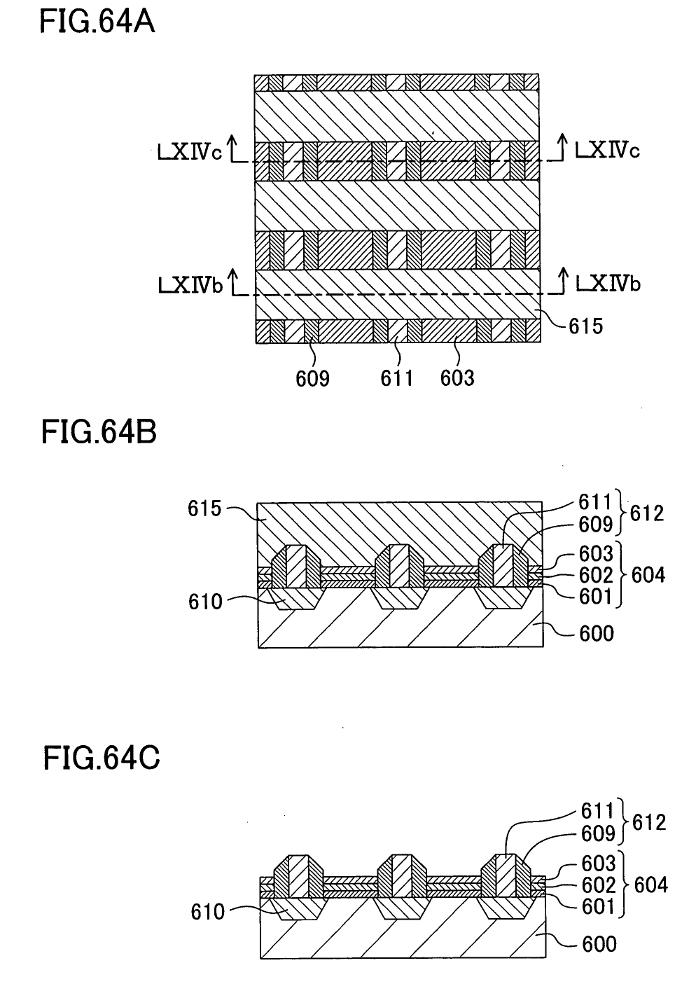

Finally, as shown in FIGS. 64A to 64C, a portion of the gate electrode film 613 is etched away using the twelfth mask 614 to form a word line 615 composed of the gate electrode film 613. Then, the twelfth mask 614 is removed by ashing or the like.

In this structure, since the insulating film 612 on the bit line is formed in a tapered shape in the step shown in FIG. 61, the level difference is reduced between the both ends of the insulating film 612 on the bit line in the row direction and the top surface of the charge trapping layer 604. Thus, the gate electrode film 613 can be etched away relatively easily, and a residue of the gate electrode film 613 can be prevented from appearing after the etching.

Thereafter, a metal interconnect formation process, a protective film formation process, and a bonding pad formation process are carried out. However, their description is omitted herein. By the process steps described above, the nonvolatile semiconductor memory device according to the fourth embodiment can be fabricated.

As described above, in the first and second methods for fabricating a nonvolatile semiconductor memory device according to the fourth embodiment, the insulating films 511 and 612 on the corresponding bit lines are formed in tapered shapes. Therefore, the associated gate electrode film can be etched relatively easily, and thus appearance of a residue of the gate electrode film can be prevented. This enables fabrication of the nonvolatile semiconductor memory device which is designed to suppress leakage between the word lines.

Moreover, the word lines are each made of a single gate electrode film. If the word line is made of multiple gate electrode films, the interface between the gate electrode films may be naturally oxidized to increase the resistance of the resulting word line. However, with the method for fabricating a nonvolatile semiconductor memory device with the above-described structure, the word line with a relatively low resistance can be formed.

Furthermore, the structure of the word line made of a single film eliminates the necessity to consider the influence of the naturally oxidized film mentioned above. Therefore, in performing selective etching on the gate electrode films shown in FIGS. 53 and 64, an etching condition can be used which can provide a relatively high etching rate as compared with the etching rate of the second silicon oxide film. As a result, the gate electrode film can be adequately etched to further prevent appearance of a residue.

### Fifth Embodiment

Hereinafter, a nonvolatile semiconductor memory device and its fabrication method according to a fifth embodiment of the present invention will be described with reference to the accompanying drawings.

### —Structure of Nonvolatile Semiconductor Memory Device—

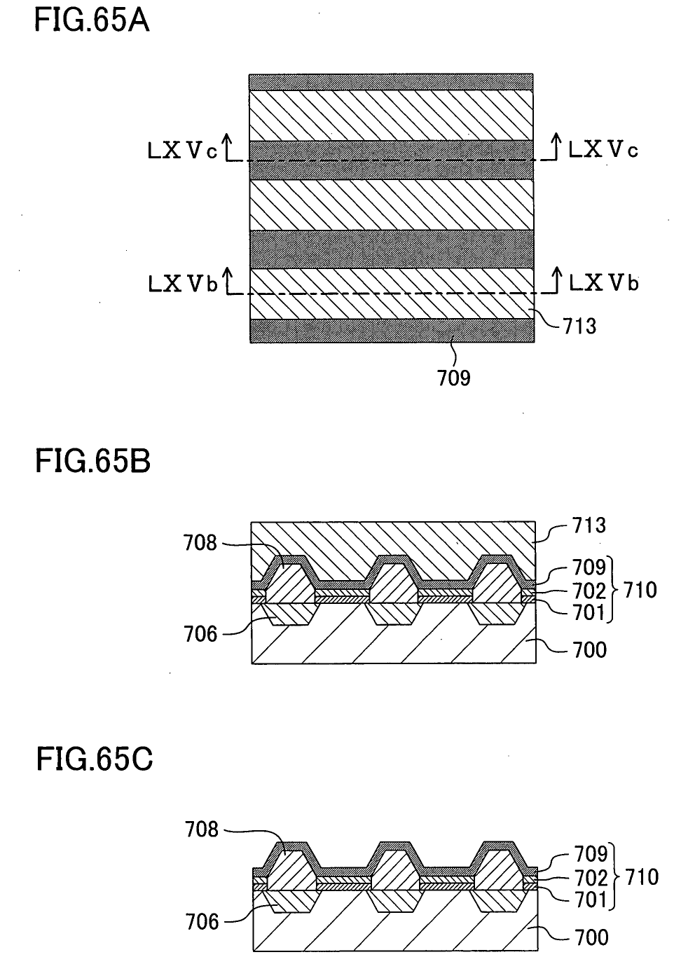

First, the structure of the nonvolatile semiconductor memory device according to the fifth embodiment will be described in detail using FIGS. 65A to 65C. FIG. 65A is a top view showing the structure of the nonvolatile semiconductor memory device according to the fifth embodiment. FIG. 65B is a sectional view taken along the line LXVb-LXVb shown in FIG. 65A, and FIG. 65C is a sectional view taken along the line LXVc-LXVc shown in FIG. 65A.

Referring to FIGS. 65A to 65C, the nonvolatile semiconductor memory device according to the fifth embodiment includes: a semiconductor substrate 700; a plurality of diffusion-layer bit lines 706; an insulating film 708 on the bit line; a first silicon oxide film 701 and a silicon nitride film 702; a second silicon oxide film 709; and a word line 713. The diffusion-layer bit lines 706 extend in the column direction in the semiconductor substrate 700. The insulating film 708 on the bit line is formed on the diffusion-layer bit line 706, and extends in the column direction. The first silicon oxide film 701 and the silicon nitride film 702 are formed, in this order from bottom to top, on a region of the semiconductor substrate 700 positioned between the diffusion-layer bit lines 706 as seen from a horizontal plane. The second silicon oxide film 709 is formed to extend over the top of the silicon nitride film 702 and the top of each insulating film 708 on the bit line. The word line 713 extends over the second silicon oxide film in the row direction. The first silicon oxide film 701, the silicon nitride film 702, and the second silicon oxide film 709 constitute a charge trapping layer 710.

In this structure, the insulating film 708 on the bit line is made of a single oxide film of HDP or the like, and has a tapered shape in which both ends thereof in the row direction have a smaller thickness than the center portion. The word line 713 is made of a single-layer film, and three-dimensionally intersects with the diffusion-layer bit line 706.

As described above, in the nonvolatile semiconductor memory device of the fifth embodiment, each memory cell transistor has: a portion of the charge trapping layer 710 formed between the insulating films 708 on the bit lines in the column direction; respective portions of the diffusion-layer bit lines 706 located below the both sides of the portion of the charge trapping layer 710; and a portion of the word line 713 located on the portion of the charge trapping layer 710, and the memory cell transistors are arranged in rows and columns. Operations of each memory of the nonvolatile memory device according to the fifth embodiment are identical to those according to the first embodiment.

### —Method for Fabricating Nonvolatile Semiconductor Memory Device—

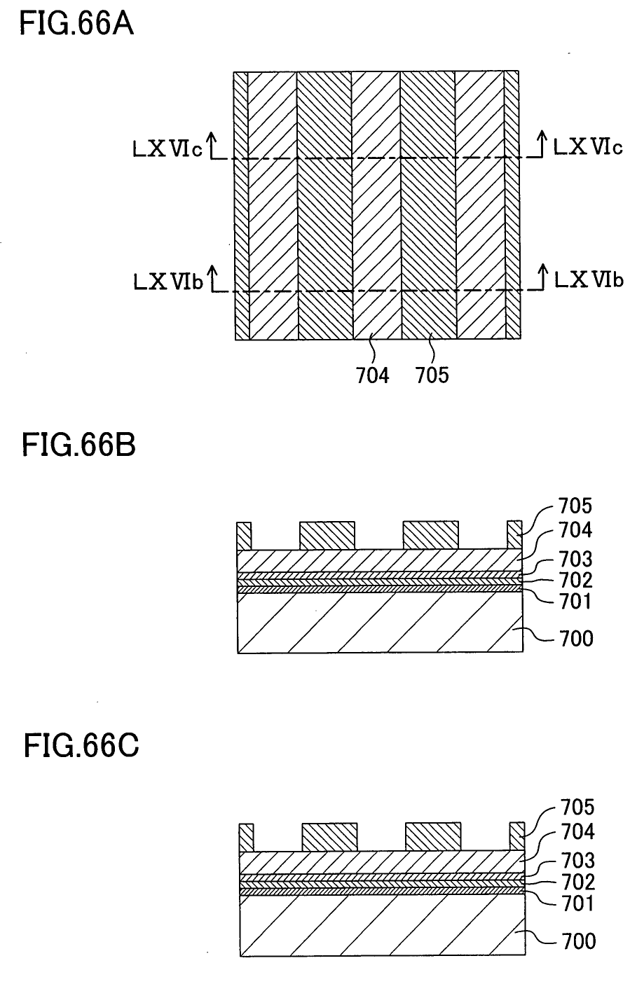

First, a method for fabricating a nonvolatile semiconductor memory device according to the fifth embodiment will be described with reference to FIGS. 66 to 74. In this description, the following figures accompanied with the reference character “A” are top views showing the fabrication method of the fifth embodiment, and the following figures accompanied with the reference character “B” or “C” are sectional views showing the fabrication method of the fifth embodiment.

Referring to FIGS. 66A to 66C, first, the first silicon oxide film 701, the silicon nitride film 702, a sacrifice silicon oxide film 703, and a bit line formation film 704 made of polycrystalline silicon or the like are sequentially deposited on the semiconductor substrate 700. The first silicon oxide film 701 is formed by a thermal oxidation method to have a thickness of, for example, 7 nm, and the silicon nitride film 702 and the sacrifice silicon oxide film 703 are formed by a low pressure CVD method to have a thickness of 10 nm, respectively. The bit line formation film 704 is formed by a low pressure CVD method to have a thickness of 50 nm. After formation of the bit line formation film 704, by a lithography technique, a thirteenth mask 705 provided with a groove extending in the column direction is formed on the bit line formation film 704.

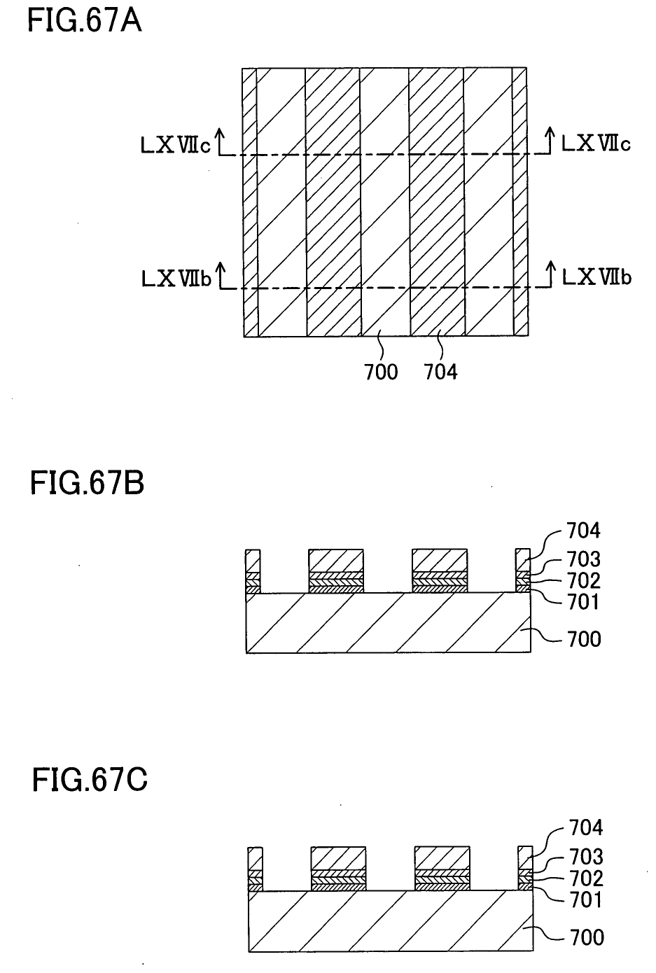

Next, as shown in FIGS. 67A to 67C, using the thirteenth mask 705, the bit line formation film 704, the sacrifice silicon oxide film 703, the silicon nitride film 702, and the first silicon oxide film 701 are selectively etched away to form an opening extending in the column direction and reaching the semiconductor substrate 700. Thereafter, the thirteenth mask 705 is removed by ashing or the like.

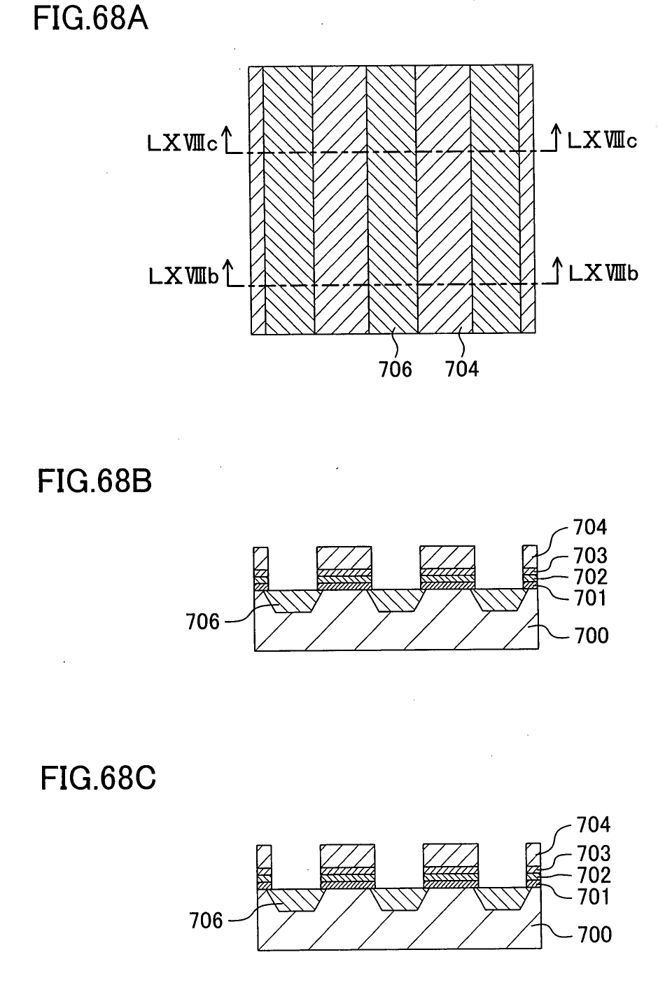

Subsequently, as shown in FIGS. 68A to 68C, from the opening into a predetermined region of the semiconductor substrate 700, boron ions are implanted as a pocket implantation on the condition of an acceleration voltage of 50 keV and a dose of 3×10¹³/cm², and arsenic ions are implanted as a source/drain implantation on the condition of an acceleration voltage of 20 keV and a dose of 2×10¹⁵/cm². Thereafter, for example, a thermal treatment at 900° C. for 60 minutes is performed thereon in a nitrogen atmosphere to form the diffusion-layer bit line 706 functioning as source and drain regions of the memory cell transistor.

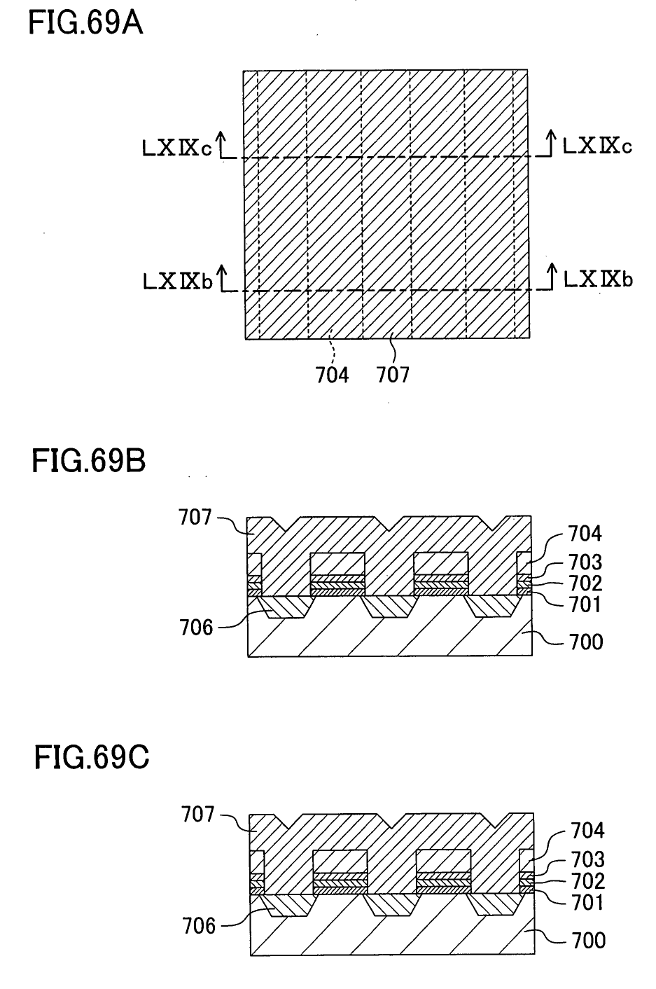

Next, as shown in FIGS. 69A to 69C, a buried oxide film 707 of, for example, HDP is deposited over the entire surface of the semiconductor substrate 700 to fill the opening with the buried oxide film 707.

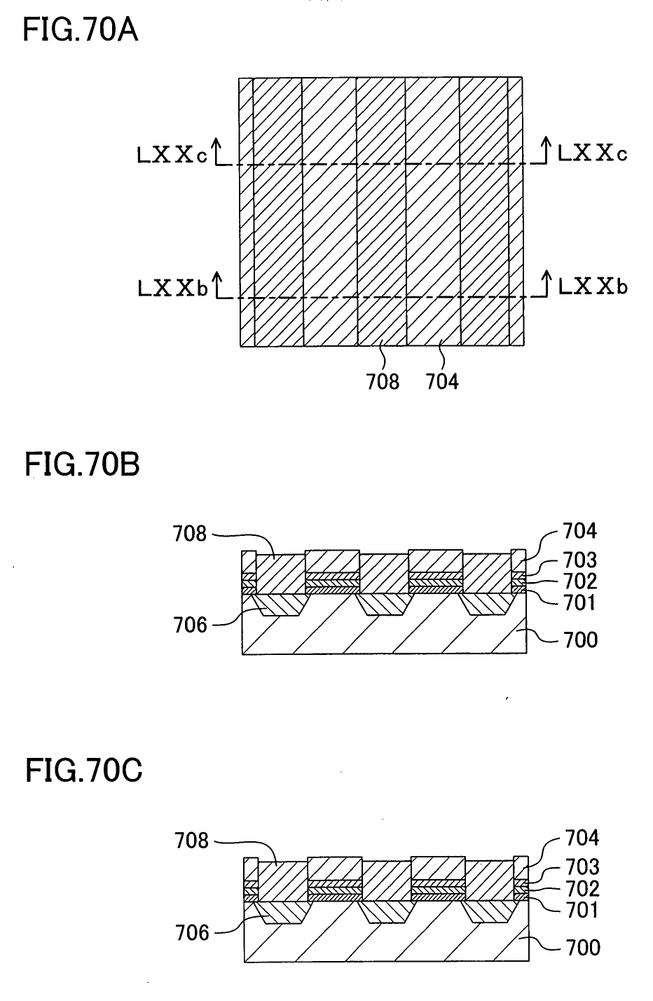

Subsequently, as shown in FIGS. 70A to 70C, the buried oxide film 707 is polished by CMP to expose the bit line formation film 704. Thereby, the insulating film 708 on the bit line is formed.

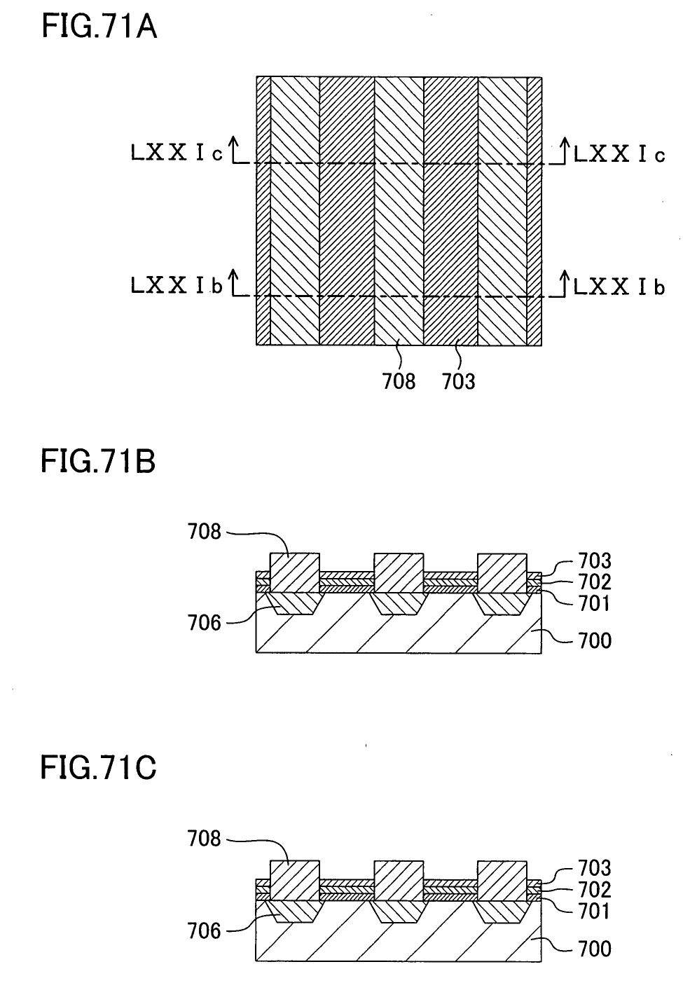

Then, as shown in FIGS. 71A to 71C, the bit line formation film 704 is removed.

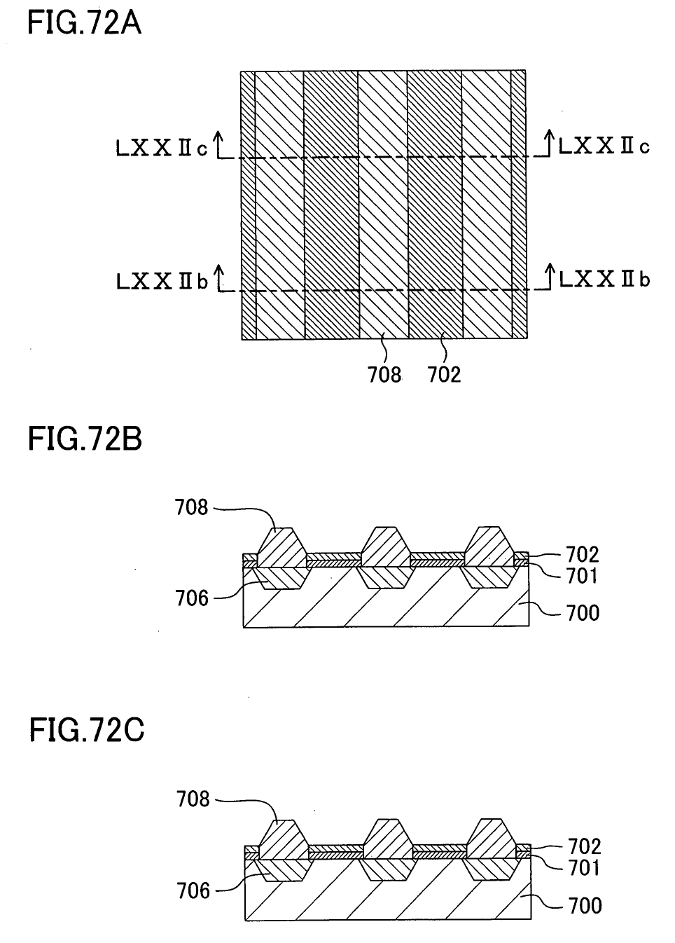

As shown in FIGS. 72A to 72C, by performing isotropic wet etching with, for example, a BHF solution, the sacrifice silicon oxide film 703 is removed to expose the silicon nitride film 702. During this process, the insulating film 708 on the bit line is also etched into a tapered shape.

Preferably, isotropic etching is performed in the step shown in FIG. 72. If the etching employed is isotropic etching, dry etching may be used instead of wet etching and alternatively these etchings may be used in combination. As shown above, by performing isotropic etching, the insulating film 708 on the bit line is etched not only from the top surface but also from the side surface. Thus, the tapered insulating film 708 on the bit line can be formed whose thickness is smaller at the both ends than at the center portion.

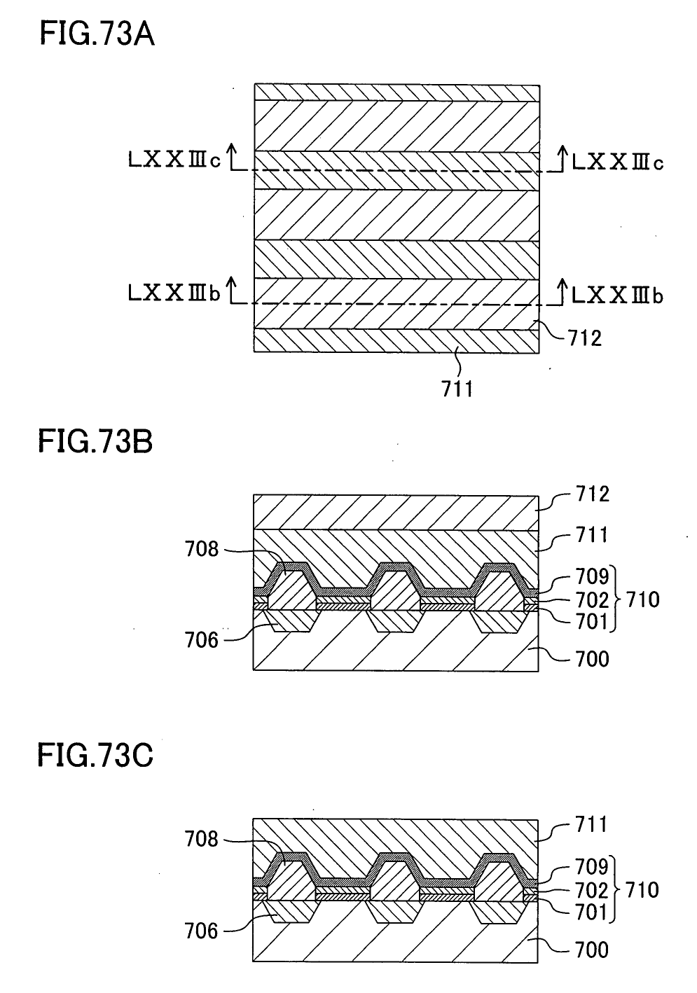

Next, as shown in FIGS. 73A to 73C, the second silicon oxide film 709 is formed over the entire surface of the semiconductor substrate 700 to provide the charge trapping layer 710 composed of the first silicon oxide film 701, the silicon nitride film 702, and the second silicon oxide film 709. Then, a gate electrode film 711 of polycrystalline silicon or the like is deposited on the second silicon oxide film 709. Thereafter, on the gate electrode film 711, a fourteenth mask 712 provided with a groove extending in the row direction is formed by a lithography technique.

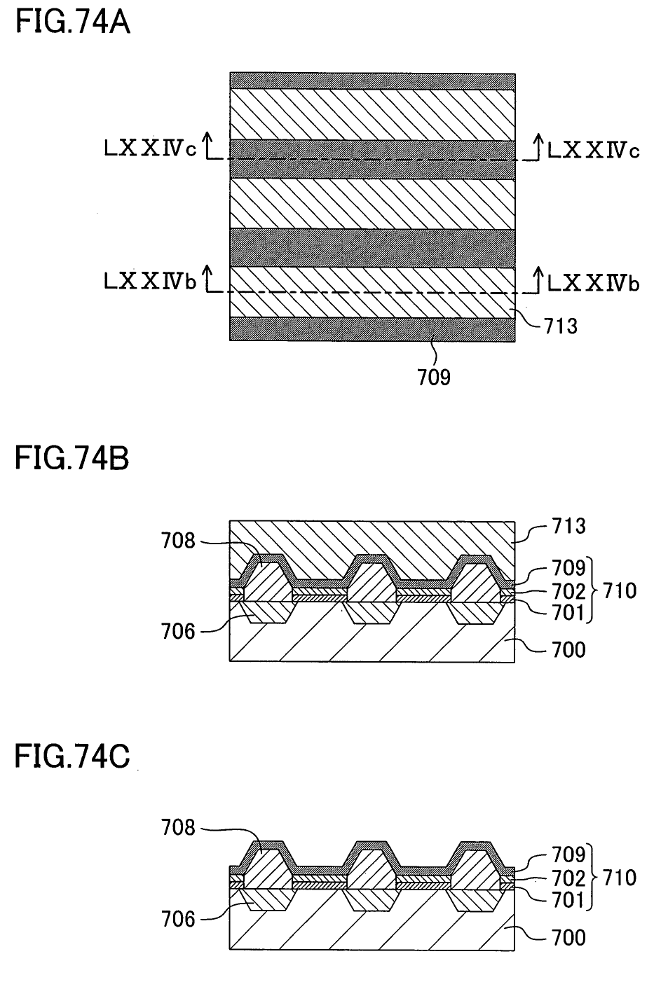

Finally, as shown in FIGS. 74A to 74C, a portion of the gate electrode film 711 is selectively etched away using the fourteenth mask 712 to form the word line 713 extending in the row direction. Then, the fourteenth mask 712 is removed by ashing or the like.

Subsequently to this, a metal interconnect formation process, a protective film formation process, and a bonding pad formation process are carried out. However, their description is omitted herein. By the process steps described above, the nonvolatile semiconductor memory device according to the fifth embodiment can be fabricated.

In the method for fabricating a nonvolatile semiconductor memory device according to the fifth embodiment, the insulating film 708 on the bit line is formed in a tapered shape. Thus, the second silicon oxide film 709 provided in the step shown in FIG. 73 to fit the contour of the insulating film 708 on the bit line is also formed to have a tapered shape, so that the formed second silicon oxide film 709 has a relatively small level difference. As a result of this, in etching away the gate electrode film 711, appearance of a residue of the gate electrode film 711 can be prevented, which enables fabrication of the nonvolatile semiconductor memory device which is designed to suppress leakage between the word lines.

Moreover, like the fourth embodiment described above, the word line 713 is composed of a single-layer film (the gate electrode film 711). This structure prevents formation of a naturally oxidized film in the word line 713, so that the word line 713 with a relatively low resistance can be provided.

Furthermore, in the method for fabricating a nonvolatile semiconductor memory device according to the fifth embodiment, neither an implantation offset film nor a buffer layer is formed unlike the above-mentioned fabrication method of the first embodiment. Therefore, the nonvolatile semiconductor memory device can be fabricated by an easier process.

What is claimed is:

1. A nonvolatile semiconductor memory device comprising:
a substrate;
a plurality of diffusion-layer bit lines extending in the column direction in the substrate;
a charge trapping layer formed on a region of the substrate positioned between the plurality of diffusion-layer bit lines as seen from a horizontal plane;
an insulating film on the bit line formed on each of the plurality of diffusion-layer bit lines, penetrating the charge trapping layer, and having a smaller thickness at both ends in the row direction than at a center portion; and
a gate electrode extending in the row direction over the charge trapping layer and the insulating film on the bit line and three-dimensionally intersecting with the plurality of diffusion-layer bit lines.

2. The device of claim 1,
wherein the insulating film on the bit line is composed of: a first insulating film formed at the center portion thereof in the row direction; and an implantation offset film formed at both ends thereof in the row direction.

3. The device of claim 1,
wherein the insulating film on the bit line is made of a single-layer insulating film.

4. The device of claim 1,
wherein the insulating film on the bit line has a tapered shape.

5. The device of claim 2,
wherein the insulating film on the bit line has a convex shape.

6. The device of claim 5,
wherein the etching rate of the implantation offset film is higher than the etching rate of the first insulating film.

7. The device of claim 1,
wherein the charge trapping layer has a multilayer structure made by sequentially stacking, from bottom to top, a first silicon oxide film, a silicon nitride film, and a second silicon oxide film.

8. The device of claim 7,
wherein the second silicon oxide film is formed to extend over the top of the silicon nitride film and the top of each said insulating film on the bit line, and the gate electrode extends in the row direction over the second silicon oxide film.

9. The device of claim 1,
wherein the gate electrode is composed of: a first gate electrode formed on the charge trapping layer; and a second gate electrode formed on the insulating film on the bit line and the first gate electrode.

10. The device of claim 1,
wherein each memory cell transistor has: a portion of the charge trapping layer; respective portions of the plurality of diffusion-layer bit lines located below the both sides of the portion of the charge trapping layer; and a portion of the gate electrode located on the portion of the charge trapping layer, and the memory cell transistors are arranged in rows and columns.

11. A method for fabricating a nonvolatile semiconductor memory device, comprising:
the step (a) of sequentially forming, on a substrate, a charge trapping layer having an insulating property, a first gate electrode formation film made of a conductor, a buffer layer having an insulating property, and a bit line formation film having an insulating property;
the step (b) of selectively etching away, using a first mask, the charge trapping layer, the first gate electrode formation film, the buffer layer, and the bit line formation film, thereby forming openings extending in the column direction and reaching the substrate;
the step (c) of introducing, after removal of the first mask, an impurity from the openings to form in the substrate a plurality of diffusion-layer bit lines extending in the column direction;
the step (d) of filling each of the openings with a first insulating film to form an insulating film on the bit line;
the step (e) of etching away, after removal of the bit line formation film, the buffer layer and the insulating film on the bit line to expose the first gate electrode formation film, thereby making the thickness of the insulating film on the bit line smaller at both ends in the row direction than at the center portion;
the step (f) of forming a second gate electrode formation film on the first gate electrode formation film and the insulating film on the bit line; and
the step (g) of etching away portions of the second and first gate electrode formation films using a second mask, thereby forming a gate electrode composed of the first and second gate electrode formation films and extending in the row direction.

12. The method of claim 11,
wherein the step (c) further includes, after removal of the first mask and before introduction of the impurity, the substep of forming an implantation offset film on an inner side surface of each of the openings, and
the insulating film on the bit line is composed of the first insulating film and the implantation offset film.

13. The method of claim 11,
wherein in the step (e), the buffer layer and the insulating film on the bit line are removed by isotropic etching to form the insulating film on the bit line having a tapered shape.

14. The method of claim 12,
wherein in the step (e), etching is performed on an etching condition that the etching rate of the first insulating film is lower than the etching rate of the implantation offset film, thereby forming the insulating film on the bit line having a convex shape.

15. The method of claim 11, further comprising, after the step (d) and before the step (e), the step (h) of etching away the insulating film on the bit line so that the top surface of the insulating film on the bit line has a higher level than the top surface of the buffer layer by within a predetermined range.

16. A method for fabricating a nonvolatile semiconductor memory device, comprising:
the step (a) of sequentially forming, on a substrate, a charge trapping layer, a sacrifice silicon nitride film, a sacrifice silicon oxide film, and a bit line formation film;
the step (b) of selectively etching away, using a first mask, the charge trapping layer, the sacrifice silicon nitride film, the sacrifice silicon oxide film, and the bit line formation film, thereby forming openings extending in the column direction and reaching the substrate;
the step (c) of introducing, after removal of the first mask, an impurity from the openings to form in the substrate a plurality of diffusion-layer bit lines extending in the column direction;
the step (d) of filling each of the openings with a first insulating film to form an insulating film on the bit line;
the step (e) of etching away, after removal of the bit line formation film, the sacrifice silicon oxide film and the insulating film on the bit line to expose the sacrifice silicon nitride film, thereby making the thickness of the insulating film on the bit line smaller at both ends in the row direction than at the center portion;
the step (f) of forming, after removal of the sacrifice silicon nitride film, a gate electrode formation film on the charge trapping layer and the insulating film on the bit line; and
the step (g) of selectively etching away the gate electrode formation film using a second mask to form, on the charge trapping layer and the insulating film on the bit line, a gate electrode extending in the row direction.

17. The method of claim 16,
wherein the step (c) further includes, after removal of the first mask and before introduction of the impurity, the substep of forming an implantation offset film on an inner side surface of each of the openings, and
the insulating film on the bit line is composed of the first insulating film and the implantation offset film.

18. The method of claim 16,
wherein in the step (e), the sacrifice silicon oxide film and the insulating film on the bit line are removed by isotropic etching to form the insulating film on the bit line having a tapered shape.

19. The method of claim 17,
wherein in the step (e), etching is performed on an etching condition that the etching rate of the first insulating film is lower than the etching rate of the implantation offset film, thereby forming the insulating film on the bit line having a convex shape.

20. The method of claim 17, further comprising, after the step (d) and before the step (e), the step (i) of etching away the insulating film on the bit line so that the top surface of the insulating film on the bit line has a higher level than the top surface of the sacrifice silicon oxide film by within a predetermined range.

21. A method for fabricating a nonvolatile semiconductor memory device, comprising:
the step (a) of sequentially forming a charge trapping layer and a bit line formation film on a substrate, the charge trapping layer being made by sequentially stacking, from bottom to top, a first silicon oxide film, a silicon nitride film, and a sacrifice silicon oxide film;
the step (b) of selectively etching away, using a first mask, the charge trapping layer and the bit line formation film to form openings extending in the column direction and reaching the substrate;
the step (c) of introducing, after removal of the first mask, an impurity from the openings to form in the substrate a plurality of diffusion-layer bit lines extending in the column direction;
the step (d) of filling each of the openings with a first insulating film to form an insulating film on the bit line;
the step (e) of etching away, after removal of the bit line formation film, the sacrifice silicon oxide film and the insulating film on the bit line to expose the silicon nitride film, thereby making the thickness of the insulating film on the bit line smaller at both ends in the row direction than at the center portion;
the step (f) of forming a second silicon oxide film extending over the top of the silicon nitride film and the top of each said insulating film on the bit line;
the step (g) of forming a gate electrode formation film on the second silicon oxide film; and
the step (h) of selectively etching the gate electrode formation film using a second mask to form, on the second silicon oxide film, a gate electrode extending in the row direction.

22. The method of claim 21,
wherein in the step (e), the sacrifice silicon oxide film and the insulating film on the bit line are removed by isotropic etching to form the insulating film on the bit line having a tapered shape.
